(19) United States
(12) Patent Application Publication
(10) Pub. No.: US 2009/0160684 A1
(43) Pub. Date: Jun. 25, 2009

(54) METHOD FOR ENCODING AND DECODING DATA

(76) Inventor: Sarukkai R. Narayanan, Oklahoma City, OK (US)

Correspondence Address: DUNLAP CODDING, P.C., PO BOX 16370, OKLAHOMA CITY, OK, 73113, US

(21) Appl. No.: 12/234,170

(22) Filed: Sep. 19, 2008

Related U.S. Application Data
(60) Provisional application No. 61/016,002, filed on Dec. 21, 2007.
(60) Provisional application No. 61/038,527, filed on Mar. 21, 2008.
(60) Provisional application No. 61/057,648, filed on May 30, 2008.

(51) Int. Cl. H03M 7/34; G06G 7/48

(52) U.S. Cl. 341/51; 703/6

(57) ABSTRACT

Methods for the compression and decompression of data using a super cooling process are described wherein an input stream is manipulated, encoded and summarized to form entities containing precedential relationships representing the input stream in a different form. The super cooled sets may be used in the transmission and/or storage of information within the input stream. Additionally, methods for decompressing the data using a super heating process are described. Generally, the super heating process expands and re-orders information contained in super cooled sets to produce at least one reconstructed ordered source stream and/or reverse stream from which the original input stream can be reconstructed.

### CROSS-REFERENCE TO RELATED APPLICATIONS

The present application claims priority to the provisional applications identified by U.S. Ser. No. 61/016,002, filed on Dec. 21, 2007; U.S. Ser. No. 61/038,527 filed on Mar. 21, 2008; and U.S. Ser. No. 61/057,648, filed on May 30, 2008, the entire contents of which are hereby expressly incorporated herein by reference. The present application also claims priority to the currently pending application identified by U.S. Ser. No. 11/866,137, filed on Oct. 2, 2007, which is a continuation of U.S. Pat. No. 7,298,293, filed May 18, 2006, which claims priority to the provisional application identified by U.S. Ser. No. 60/687,604, filed on Jun. 3, 2005, the entire contents of which are hereby expressly incorporated herein by reference.

### STATEMENT REGARDING FEDERALLY SPONSORED RESEARCH OR DEVELOPMENT

Not applicable.

### NAMES OF PARTIES TO A JOINT RESEARCH AGREEMENT

Not applicable.

### REFERENCE TO A “SEQUENCE LISTING,” A TABLE, OR A COMPUTER PROGRAM LISTING APPENDIX SUBMITTED ON A COMPACT DISC AND AN INCORPORATION BY REFERENCE OF THE MATERIAL ON THE COMPACT DISC

Not applicable.

### BACKGROUND

1. Field of the Invention

The present invention relates generally to the encoding and summarizing (compression) of ordered data and re-expanding the summarized data and decoding it to obtain the original data in its correct order.

2. Brief Description of Related Art

In general, data encoding involves the process of representing information using fewer data units or bits than a more direct representation would require. Data decoding involves the process of expanding the encoded data to obtain the original data in the correct order. While various algorithms and techniques have been developed for encoding and decoding data, there is a continuing need for an effective and readily implemented encoding and decoding method. It is to such methods, and systems for implementing the same, that the present invention is directed.

### BRIEF SUMMARY OF THE EMBODIMENTS

The present embodiments relate to methods for encoding and summarizing (referred to herein as “compression”) and re-expanding and decoding (referred to herein as “decompression”) of data using a process are described wherein an ordered input stream of “1”s and “0”s is manipulated, encoded and summarized to form entities referred to herein as “super cooled sets” representing the input stream in a different form. The super cooled sets may be used in the transmission and/or storage of information within the input stream. Additionally, methods for decompressing the data using a process referred to herein as a “super heating process” are described. Generally, the super heating process expands and re-orders information contained in super cooled sets to produce at least one reconstructed ordered source stream and/or reverse stream from which the original input stream can be reconstructed.

### BRIEF DESCRIPTION OF THE SEVERAL VIEWS OF THE DRAWINGS

So that the above recited features and advantages of the present invention can be understood in detail, a more particular description of the invention, briefly summarized above, may be had by reference to the embodiments thereof that are illustrated in the appended drawings. It is to be noted, however, that the appended drawings illustrate only typical embodiments of the invention, and are therefore not to be considered limiting to the scope, for the invention may admit to other equally effective embodiments.

FIG. 1 shows a block diagram of a system for encoding data, which is constructed in accordance with the present invention.

FIG. 2 shows a flow chart illustrating a general method for encoding and decoding data in accordance with the present invention.

FIG. 3 is a flow chart illustrating one embodiment of a method for encoding data in accordance with the present invention.

FIGS. 4A-4Z cooperate to illustrate the method for encoding data for an exemplary input stream, referred to as stream 1 more particularly;

FIG. 4A shows an exemplary input stream.

FIG. 4B shows an exemplary rippled input stream.

FIG. 4C shows an exemplary rotated rippled input stream generated in the formation of an exemplary source stream.

FIG. 4D shows the rotated rippled input stream of FIG. 4C with an added end droplet so as to form the exemplary source stream.

FIG. 4E shows a formation of an exemplary encoded source stream from the source stream of FIG. 4D.

FIG. 4F shows a formation of an exemplary series of source pucks from the exemplary encoded source stream of FIG. 4E.

FIG. 4G shows the series of source pucks from FIG. 4F.

FIG. 4H shows an exemplary rotated duplicate rippled stream generated in the formation of an exemplary reverse stream.

FIG. 4I shows an exemplary reversed, rotated duplicate rippled stream generated in the formation of the exemplary reverse stream.

FIG. 4J shows the reversed, rotated duplicate rippled stream of FIG. 4I with an added end droplet so as to form the exemplary reverse stream.

FIG. 4K shows a formation of an exemplary encoded reverse stream from the reverse stream of FIG. 4J.

FIG. 4L shows a formation of an exemplary series of reverse pucks from the exemplary encoded reverse stream of FIG. 4K.

FIG. 4M shows the series of reverse pucks from FIG. 4L.

FIG. 4N shows an exemplary first group formed from a portion of the series of source pucks of FIG. 4G and a portion of the series of reverse pucks of FIG. 4M.

FIG. 4O shows an exemplary second group formed from a portion of the series of source pucks of FIG. 4G and a portion of the series of reverse pucks of FIG. 4M.

FIG. 4P shows an exemplary first group bubble formed from the first group of FIG. 4N.

FIG. 4Q shows an exemplary set of gum drop pairs formed from the first group bubble of FIG. 4P.

FIG. 4R shows an exemplary set of gum drop pair types and counts for odd and even gum drop pairs of FIG. 4Q.

FIG. 4S shows an exemplary set of adjacent gum drop pairs formed from the first group of gum drop pairs of FIG. 4Q, and an exemplary set of adjacent gum drop pairs types and counts for the adjacent gum drop pairs.

FIG. 4T shows an exemplary super cooled set for the first group of FIG. 4N.

FIG. 4U shows an exemplary second group bubble formed from the second group of FIG. 4O.

FIG. 4V shows an exemplary set of gum drop pairs formed from the second group bubble of FIG. 4U.

FIG. 4W shows an exemplary set of gum drop pair types and counts for odd and even gum drop pairs of FIG. 4V.

FIG. 4X shows an exemplary set of adjacent gum drop pairs formed from the second group of gum drop pairs of FIG. 4V, and an exemplary set of adjacent gum drop pairs types and counts for the adjacent gum drop pairs.

FIG. 4Y shows an exemplary super cooled set for the second group of FIG. 4O.

FIG. 4Z shows an exemplary reconstructed series of source pucks formed in accordance with the present invention.

FIG. 5 shows a flow chart illustrating one embodiment of an encoding subroutine for forming the series of source pucks in accordance with the present invention.

FIG. 6 shows one embodiment of a two tier encoding scheme.

FIG. 7 shows a flow chart illustrating one embodiment of an encoding subroutine for forming the series of reverse pucks in accordance with the present invention.

FIG. 8 shows an exemplary first group and an exemplary second group having two inversion duets.

FIG. 9 shows a flow chart illustrating one embodiment of a grouping subroutine for forming the first group and second group in accordance with the present invention.

FIG. 10 shows a summarization subroutine for the gum drop pairs of the first group.

FIG. 11 shows a summarization subroutine for the gum drop pairs of the second group.

FIG. 12A shows a formation of an exemplary lock component and an exemplary key component for the first group in accordance with the present invention.

FIG. 12B shows an exemplary combination applied to the lock component and the key component of FIG. 12A, and the resulting set of adjacent gum drop pair types and count for the first group.

FIG. 13 shows a block diagram illustrating a frame constructed in accordance with the present invention.

FIG. 14 shows an exemplary first group and second group having mirrored pucks.

FIG. 15 shows a double helix structure associated with an exemplary subset of duets of the present invention.

FIG. 16A-16B cooperate to show application of one embodiment of a transformation process to the subset of duets of FIG. 15, more particularly:

FIG. 16A shows the transformation of the subset of duets into DNA pairs.

FIG. 16B shows a flow chart illustrating the transformation process and the transformation of an exemplary first duet as the transformation process is applied.

FIG. 17A shows exemplary consecutive adjacent gum drop pairs in alphabetic notation.

FIG. 17B shows the consecutive adjacent gum drop pairs of FIG. 17A wherein the alphabetic notation is replaced by a data equivalent.

FIG. 17C shows the consecutive adjacent gum drop pairs of 17B wherein the rippling and data droplets are shown separated indicative of the precedential relationship between data droplets.

FIG. 17D shows the rippling and data droplets of FIG. 17C in a folded relationship.

FIG. 17E shows the folded adjacent gum drop pairs of FIG. 17D transformation to double helix pairs.

FIGS. 17F-1 and 17F-2 show transformation of adjacent gum drop pairs of group 1 to double helix pairs.

FIGS. 17G-1 and 17-G-2 show transformation of adjacent gum drop pairs of group 2 to double helix pairs.

FIG. 17H shows transformation of double helix pairs in Spin 0, Spin 1, Spin 2, and Spin 3 formats.

FIGS. 17I-1 and 17I-2 show group 1 double helix pairs of FIGS. 17F-1 and 17F-2 in Spin 0 and Spin 2 formats, and group 2 double helix pairs of FIG. 17G-1 and 17G-2 in Spin 0 and Spin 2 formats.

FIG. 17J shows group 1 super cooled data expressed as odd/even double helix pair pairings with associated counts.

FIG. 17K shows group 2 super cooled data expressed as odd/even double helix pair pairings with their associated counts.

FIG. 18 shows steps involved in devolving a super cooled set to a super heated set.

FIGS. 19A-19B show flow charts illustrating one exemplary embodiment of a devolving subroutine for reconstructing a series of source pucks in accordance with the present invention.

FIG. 20 shows exemplary loop sequences in accordance with the present invention.

FIGS. 21, 21A, 21B and 21C show devolution tables for even pairing for reference AGDP CB-BA*AC-AB.

FIGS. 22, 22A, 22B and 22C show devolution tables for even pairing for reference AGDP CA-BA*AC-AB.

FIGS. 23, 23A, 23B and 23C show devolution tables for odd pairing for reference AGDP AC-AB*CA-BC.

FIGS. 24, 24A, 24B and 24C show devolution tables for odd pairing for reference AGDP AD-AB*CA-BC.

FIG. 25 shows steps involved in the evaluation of alternatives for a reference adjacent gum drop pair.

FIGS. 26, 26A, 26B and 26C show steps in selecting next adjacent gum drop pairs for Group 2 and sequence 2.

FIGS. 27, 27A, 27B and 27C show steps in selecting next adjacent gum drop pairs for Group 1 and sequence 4.

FIGS. 28, 28A, 28B and 28C show steps in selecting next adjacent gum drop pairs for Group 2 and sequence 3.

FIGS. 29, 29A, 29B and 29C show steps in selecting next adjacent gum drop pairs for Group 2 and sequence 15.

FIG. 30 shows an exemplary mutation at the loop level.

### DETAILED DESCRIPTION OF THE EMBODIMENTS

Present embodiments of the invention are shown in the above-identified figures and described in detail below. In describing the embodiments, like or identical reference numerals are used to identify common or similar elements. The figures are not necessarily to scale and certain features in certain views of the figures may be shown exaggerated in scale or in schematic in the interest of clarity and/or conciseness.

The terms “encoding and summarizing” (“compression”), and derivations thereof, as used herein generally refers to the process by which a set of data units are represented in a different form, for example for the purpose of storing or transmitting the data units; and the terms “re-expanding and decoding” (“decompression”) and derivations thereof, as used herein generally refers to the process of restoring encoded and summarized sets of data units to the normal and/or original form, for example for the purpose of processing, displaying or otherwise using the data units.

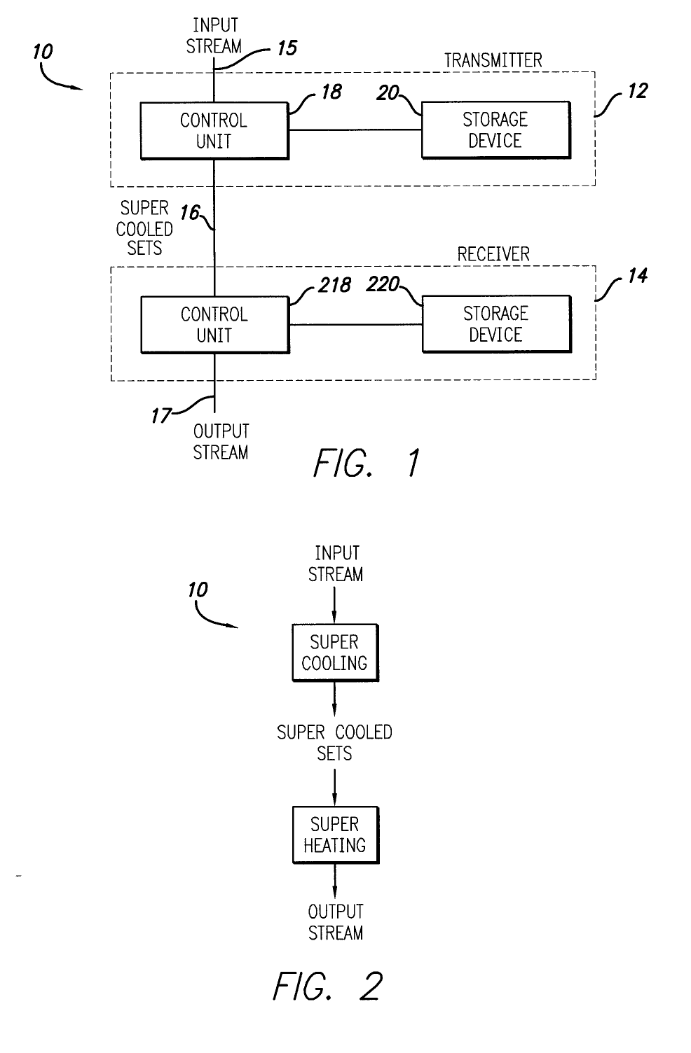

Referring now to the drawings, and in particular to FIGS. 1 and 2. Shown in FIG. 1 and designated therein by a reference numeral 10 is a system for data compression and decompression, and shown in FIG. 2 is a general method for data compression and decompression which is preformed by the system 10.

The novel compression process of the present invention is referred to herein by the Applicant by the term “super cooling”, and the novel decompression process of the present invention is referred to herein by the Applicant by the term “super heating”. In general, during the super cooling process, a stream of data units, which is referred to herein as an “input stream”, is manipulated, encoded and summarized to form entities that represent the input stream in a different form. This representative form of the original input stream is referred to herein as “super cooled sets”. The super cooled sets can be used for example for the transmission and/or storage of the information contained within the input stream. During the super heating process, the information contained within the super cooled sets is expanded, reordered and otherwise utilized to reconstruct the input stream so as to restore the input stream into its original form. The restored input stream is referred to herein as an “output stream.”

In one embodiment, the system 10 includes a transmitter 12 and a receiver 14. In general, the input stream is inputted into the transmitter 12 via a line 15. The transmitter 12 then performs the super cooling process to generate the super cooled sets representative of the input stream. The transmitter 12 then passes the super cooled sets to the receiver 14 via a line 16. Once the receiver 14 receives the super cooled set, the receiver 14 performs the super heating process on the super cooled set to generate the output stream (i.e., to restore the input stream to its original form). The output stream is outputted by the receiver 14 via a line 17. The lines 15, 16, and 17 can be any type of communication link, device or system that permits communications, such as electronic and/or optical communications. For example, the lines 15, 16, and 17 can include wires, cables, fiber-optic links, internal buses, local area networks, wide area networks, intranet networks, internet networks, point-to-point shared and dedicated communication links, radio links, microwave links, infrared links, satellite links, cable TV links, and/or telephone links.

While the transmitter 12 and the receiver 14 are generally discussed herein as separate components of the system 10, for purposes of illustration and clarity of understanding, it should be understood that the present invention contemplates that the functions of the transmitter 12 and the receiver 14, or portions thereof, can be performed by a common device.

In one embodiment, the transmitter 12 of the system 10 includes a control unit 18. The control unit 18 can be any computational device capable of executing the super cooling process or logic. In one embodiment, the control unit 18 executes a super cooling program contained in a storage device 20. The storage device 20, which can be for example a read-only memory device, stores the program code and commands required for operation by the control unit 18 in performing the super cooling process on the input stream. Alternately, the super cooling process program code and commands may be incorporated into the control unit 18 itself.

Additionally, the receiver 14 of the system 10 may include a control unit 218. The control unit 218, similar to the control unit 18 of the transmitter, can be any computational device capable of executing the super heating process or logic. In one embodiment, the control unit 218 executes a super heating program contained in a storage device 220. The storage device 220, which can be for example a read-only memory device, stores the program code and commands required for operation by the control unit 218 in performing the super heating process on the super cooled sets. Alternately, the super heating process program code and commands may be incorporated into the control unit 218 itself.

1. Super Cooling Process

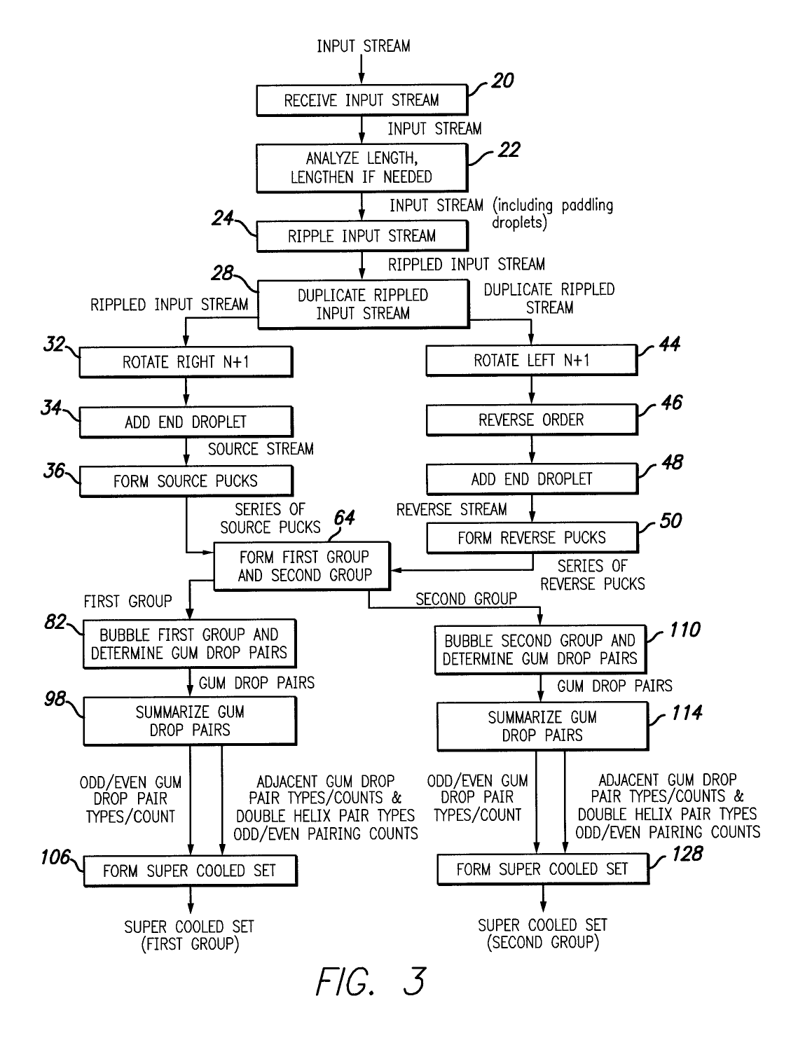

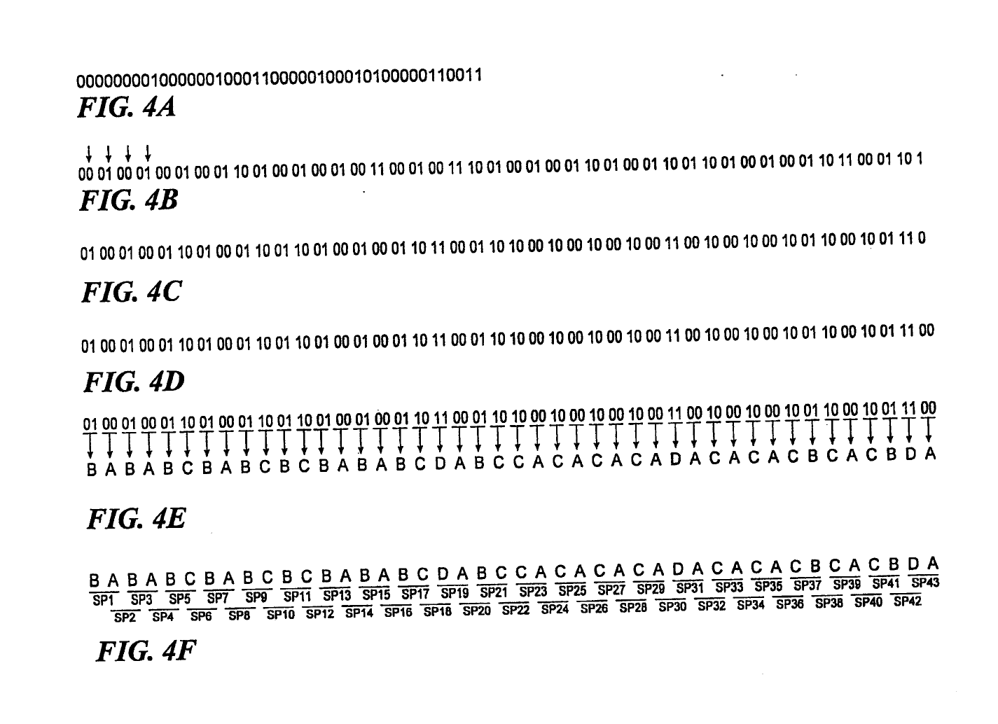

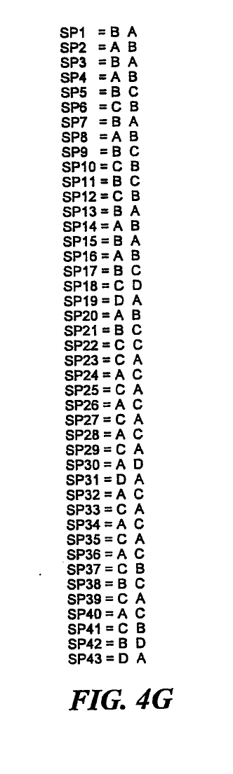

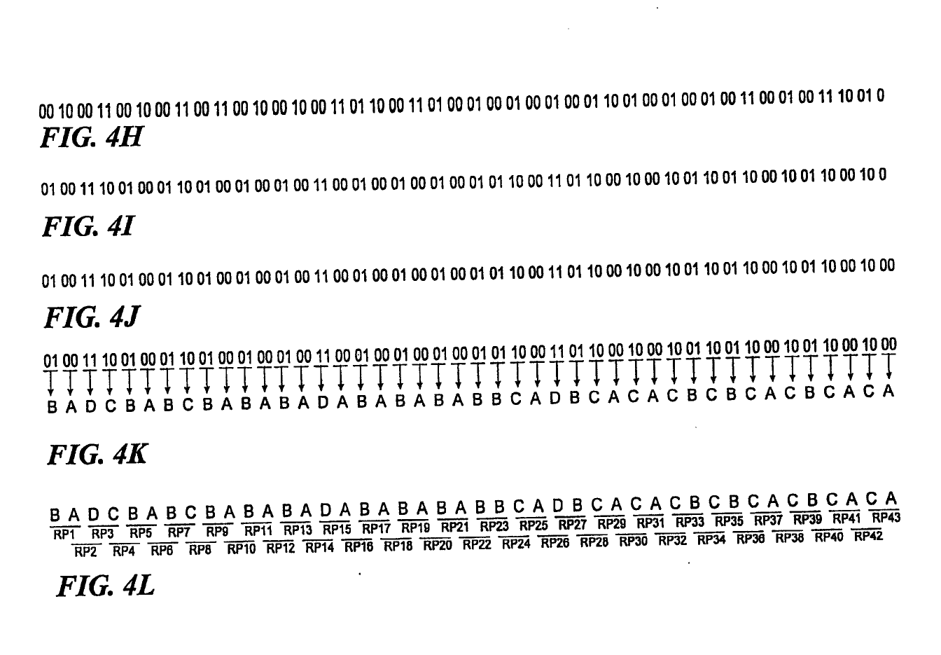

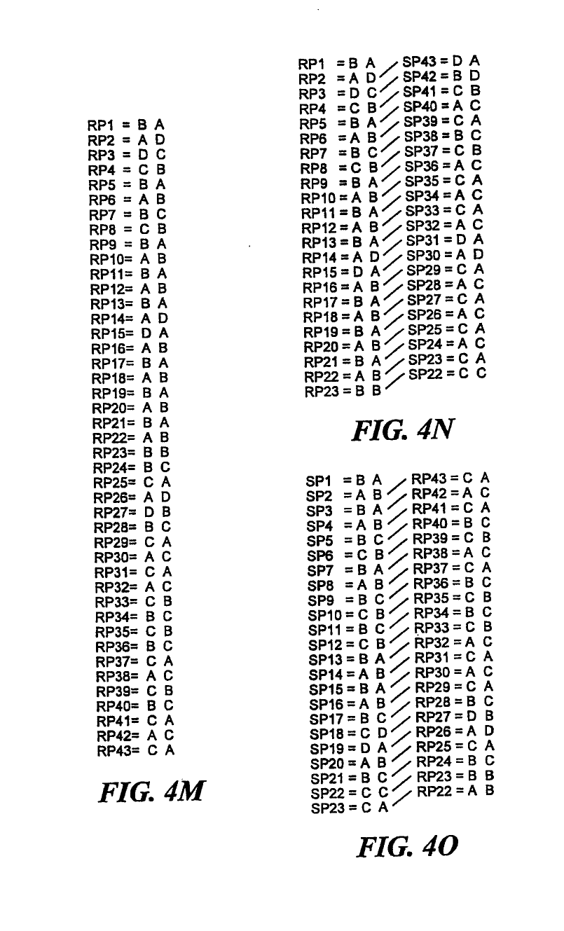

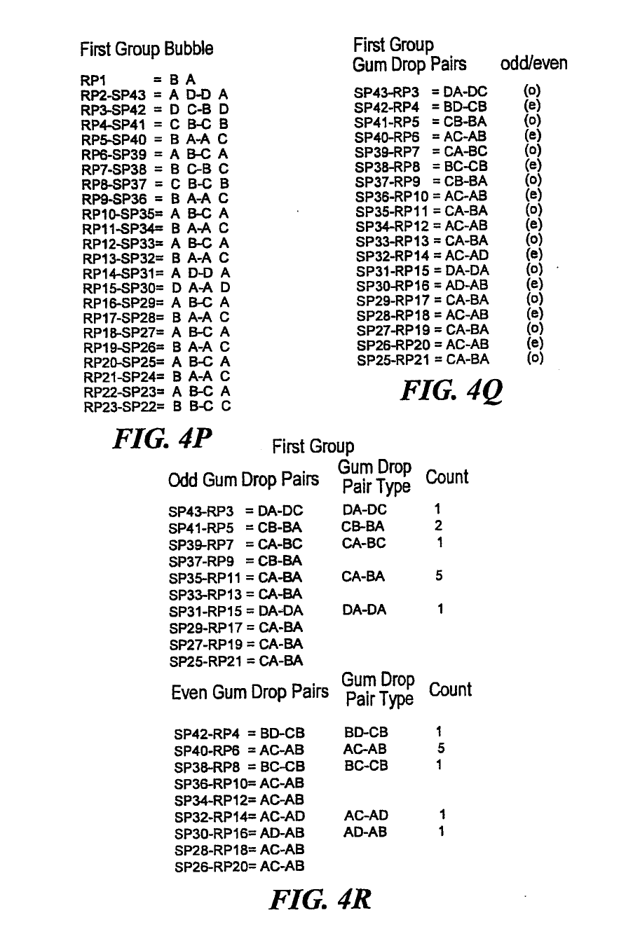

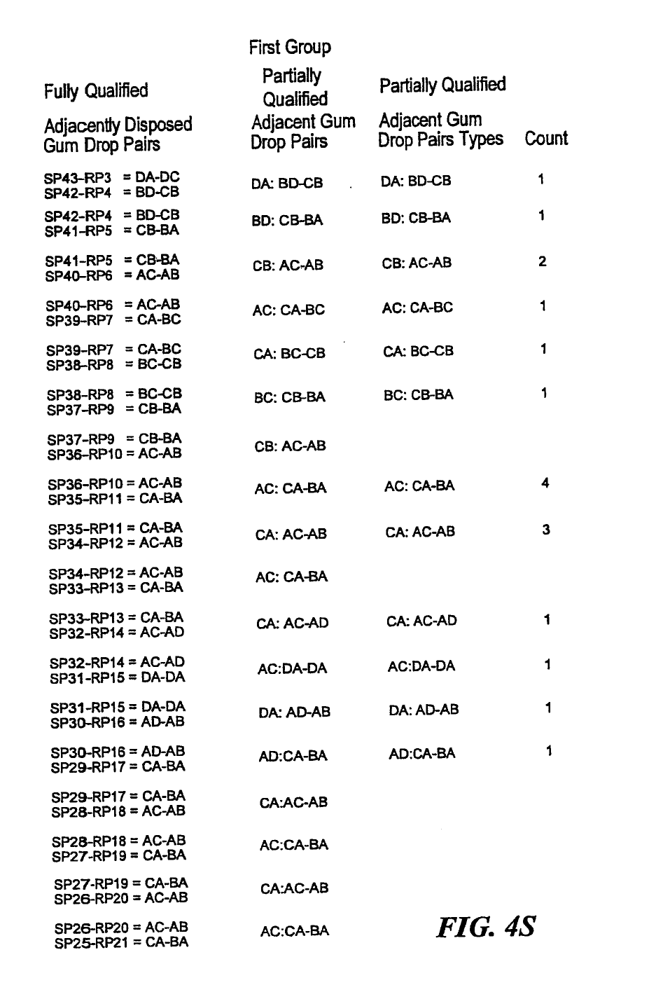

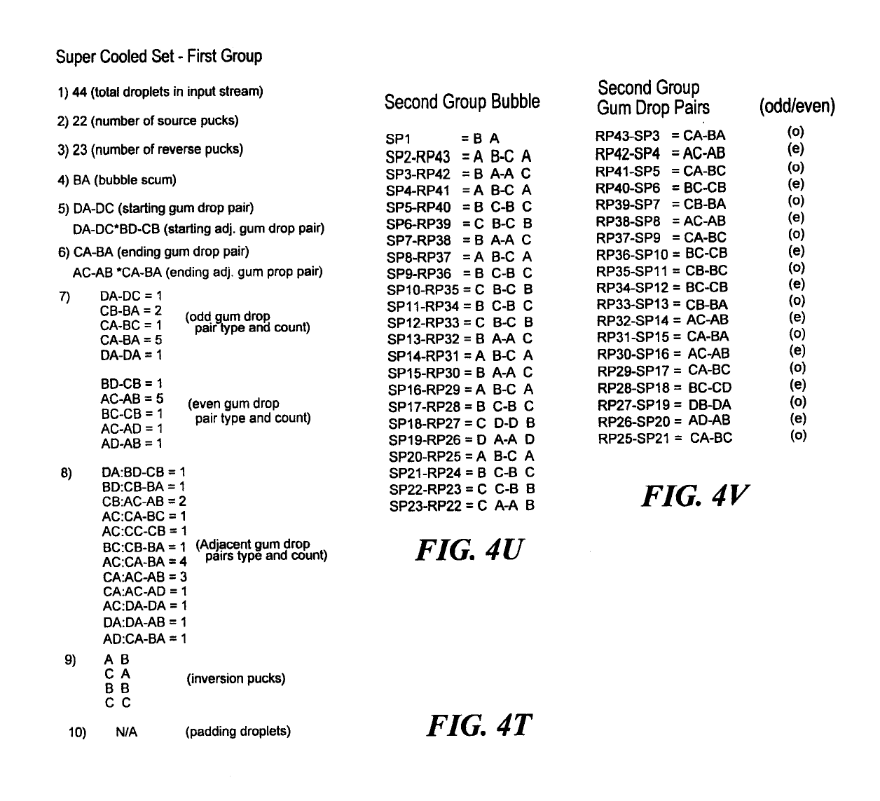

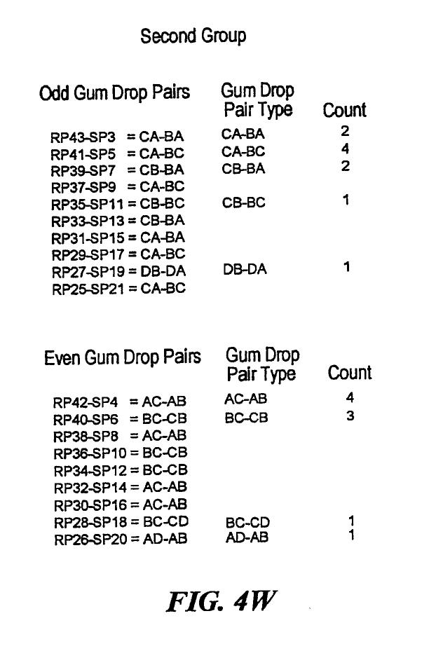

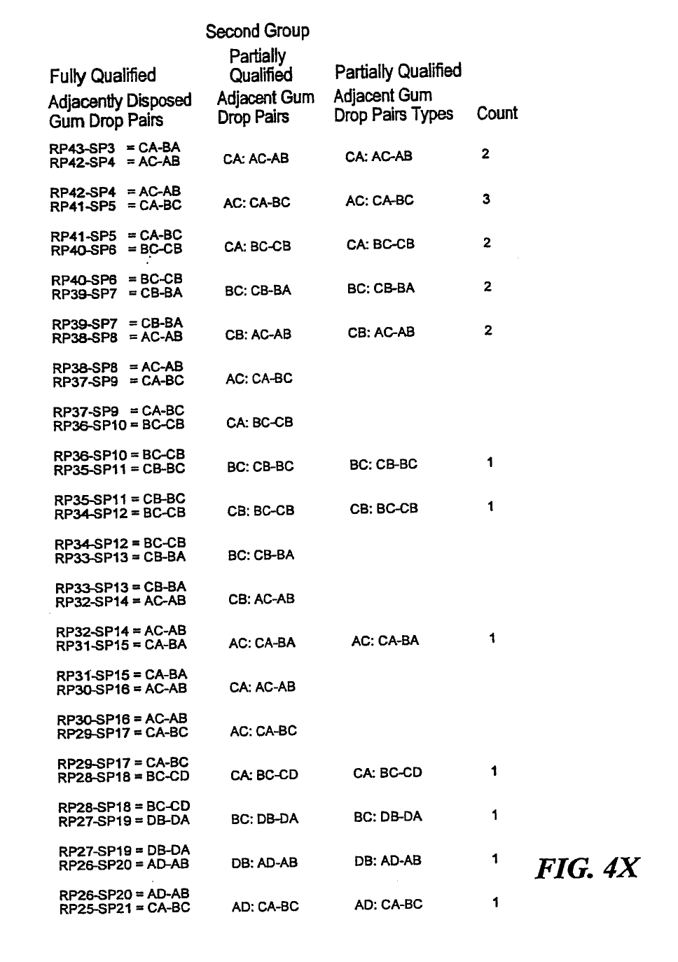

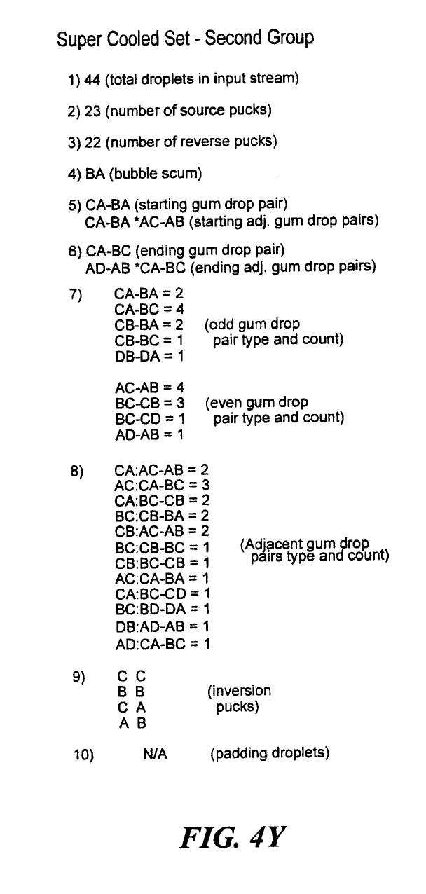

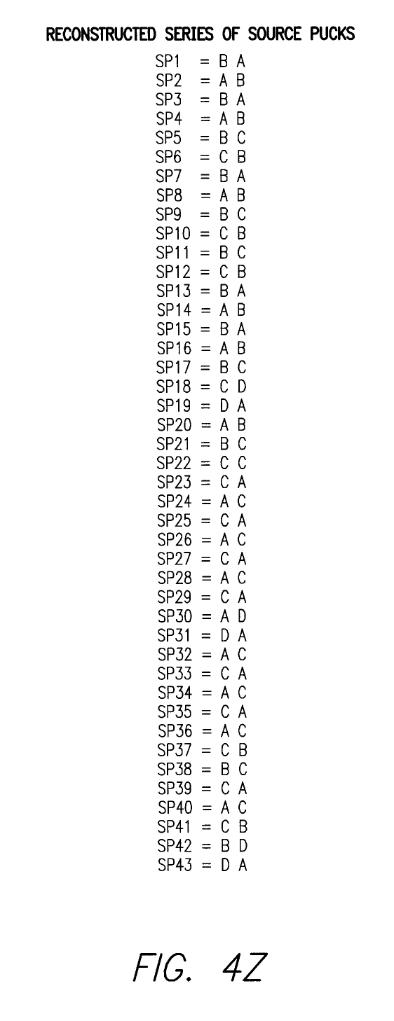

With reference to FIG. 3, the operation of the control unit 18, i.e., the performing of the super cooling process, is described. At a step 20, the control unit 18 receives or reads the input stream. The input stream comprises a plurality of sequential binary data units or bits, i.e. 1's and 0's. The individual data units of the input stream are generally referred to herein by the Applicant by the term “droplets,” “data units,” or “bits.” For example, shown in FIG. 4A is an exemplary input stream which is used herein for purposes of discussion and clarity of understanding, and to illustrate the various steps of the super cooling process to achieve the final super cooled sets (as shown in FIGS. 4B-4Y). For the exemplary input stream of FIG. 4A, there are forty-four droplets.

Once the input stream is received, the control unit 18 branches to a step 22 where the length of the input stream is analyzed, and lengthened if needed. To perform the super cooling process of the present invention, though not mandatory, it is advantageous for the total number of droplets or length of the input stream to be a multiple of the number four. In the preferred embodiment, the total number of droplets or length of the input stream is an odd multiple of the number four (e.g., 3×4=12, 5×4=20, 11×4=44, etc.). Therefore, if the input stream does not have a length that is an odd multiple of the number four, in the step 22 one or more data units or binary streams which Applicant refers to herein as “padding droplets,” “padding data units,” or collectively as “after spray,” are concatenated or added to the end of the input stream to meet this requirement. The values of the padding droplets are arbitrary, however the padding droplets have to be identified as being extraneous to the input stream. For purposes of discussion and clarity of understanding, any padding droplets that are added to the input stream are considered as part of the input stream in the discussion that follows. (Note that in the example shown in FIG. 4A, the exemplary input stream contains forty-four droplets which is an odd multiple of four, and thus no padding droplets are required.)

Within the input stream, there is the possibility that there will be a sequence of consecutive droplets which are repeated, i.e., which have the same value. When there is a sequence of greater than three droplets of the same value, the sequence is referred to herein as a “run.” Runs can negatively affect the super cooling and super heating processes of the present invention by causing ambiguities and anomalies. As such, it is desirable to break up any runs that may exist in the input stream. Therefore, after the step 22, the control unit 18 branches to a step 24, wherein additional droplets are introduced into the input stream in a pre-determined sequence. This step 24 is referred to herein by the Applicant as “rippling” (or derivations thereof) and the additional droplets are referred to herein as “ripple droplets,” “modified droplets,” or “modified data units.” Rippling of the input stream forms what is referred to herein as a “rippled input stream” or a “modified input stream.”

There are different ways to perform the rippling step 24. In one embodiment, the rippling step 24 comprises introducing a ripple droplet after each consecutive input stream droplet, except the last droplet, wherein the ripple droplets are alternated in value as each ripple droplet is inserted into the input stream. In such an embodiment, the rippling can be either “0-1 rippling” or “1-0 rippling.” For 0-1 rippling, the first ripple droplet introduced is a zero, the second ripple droplet is a one, the third ripple droplet is a zero, and so on. For 1-0 rippling, the first ripple droplet introduced into the input stream is a one, the second ripple droplet is a zero, the third ripple droplet is a one, and so on.

For example, shown in FIG. 4B is the exemplary input stream of FIG. 4A with 0-1 rippling, which results in eighty-seven droplets. The first four ripple droplets in the rippled input stream of FIG. 4B are indicated by a downward arrow over each ripple droplet for purposes of illustration.

Once the rippled input stream is achieved, as illustrated in FIG. 3, the control unit 18 branches to a step 28, wherein a duplicate of the rippled input stream is generated, which is referred to herein by the Applicant by the term “duplicate rippled stream”.

Rippled Input Stream

At this point, the rippled input stream and the duplicate rippled stream are each provided as an input to different sets of logic. The rippled input stream will be discussed first for purposes of clarity of understanding. However, it should be understood that the logic for the rippled input stream and the logic for the duplicate rippled stream can be performed in any order or simultaneously. In other words, it should be understood that various steps of the super cooling process that lend themselves to be performed in other orders or in parallel can be implemented as such to shorten the execution time of the present invention.

For the rippled input stream, the control unit 18 branches to a step 32 wherein the rippled input stream is “rotated to the right” such that each of the droplets in the rippled input stream is shifted a position to the right, and the right-most droplet is looped to or deposited in the left-most position which is vacated. In one preferred embodiment, the rippled input stream is rotated to the right by N+1 droplets, where N is the total number of droplets in the input stream (including any padding droplets). As such, it can be seen that the relative ordering of the droplets is generally preserved, however the start (or first) droplet and the end (or last) droplet in the stream are different. For example, shown in FIG. 4C is the exemplary rippled input stream of FIG. 4B rotated to the right by 44+1 or 45 droplets.

Referring again to FIG. 3, the control unit 18 then branches to a step 34, wherein a final end droplet is added to the end of the rotated rippled input stream so as to form an even number of droplets. In one embodiment, the final end droplet is set equal to the first droplet of the rotated rippled input stream to make the total count of droplets even. For example, shown in FIG. 4D is the rotated rippled input stream of FIG. 4C with the final end droplet having a value of “0” added at the end. The resulting stream of the steps 32 and 34 is referred to herein as a “source stream.”

It should be understood that while the super cooling process is described in one embodiment as “rotating” droplets when forming the source stream, the source stream can be equivalently generated by defining a starting offset at which to begin forming the source stream from the droplets of the rippled input stream. If the first droplet in the rippled input stream is considered to have an offset of zero, then the starting offset should be defined to be N−2, where N is the length of the input stream (including any padding droplets). For example, for the rippled input stream of FIG. 4B, the starting offset would be defined as 44−2 or 42. Therefore, the droplet at offset 42 (with the first droplet of the rippled input stream being at offset zero) would be the first droplet of the source stream. Then the succeeding droplets of the rippled input stream would be put in the source stream until the end of the rippled input stream is reached, and then continue on to the beginning of the rippled input stream until the droplet at offset 41 is reached. Then the final end droplet can be added to the end so as to form an even number of droplets in the source stream.

Once the source stream is generated in the steps 32 and 34, the control unit 18 branches to an encoding subroutine, which shown in FIG. 3 as a step 36, wherein the droplets of the source stream are formed into representative entities referred to herein by the Applicant by the term “pucks,” “entities,” or “drop pairs”. Because the pucks are formed from the source stream at this point, the pucks are more specifically referred to herein by the Applicant by the term “source pucks.”

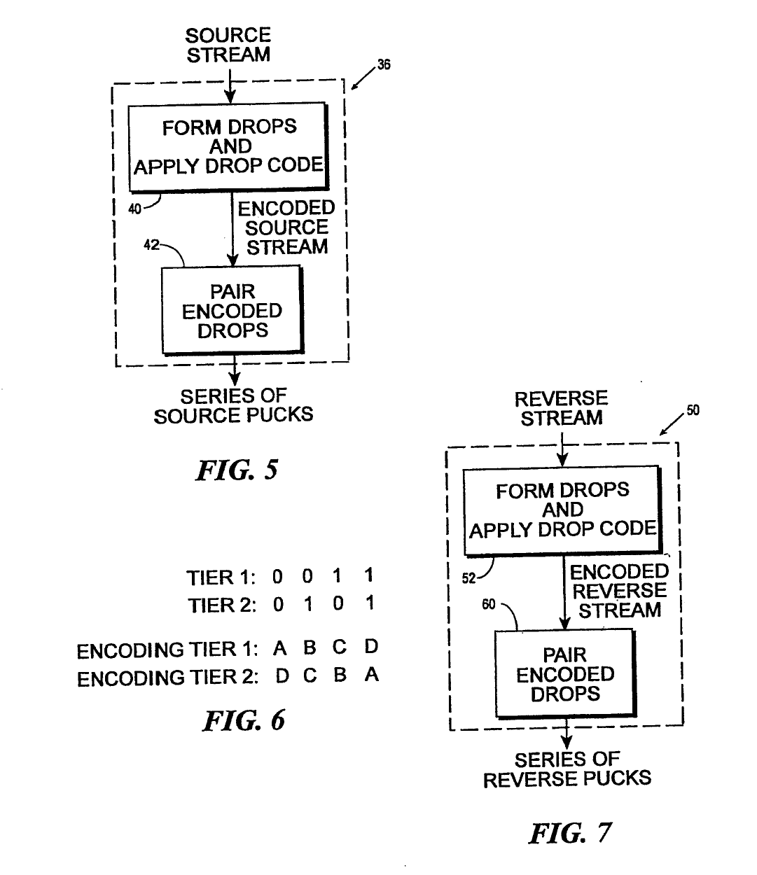

For purposes of clarity of understanding the scheme for formation of the pucks, an interim step is gone through in the encoding subroutine 36. The encoding subroutine 36 is shown in more detail in FIG. 5. In a step 40 of the encoding subroutine 36, the control unit 18 takes two consecutive (side-by-side) and unique droplets in the source stream to form a pairing which is referred to herein as a “drop”, and then assigns to each drop a predetermined symbol according to the values of the droplets in the drop. The plurality of encoded drops collectively form an encoded source stream comprising a plurality of symbols which represent the droplets of the source stream.

The collective group of predetermined symbols used to encode the drops of the source stream are referred to herein as a “drop code.” Since the drops are formed from two consecutive droplets and the droplets are binary in nature, there are four possible drop combinations: 00, 01, 10, and 11. In one embodiment, the first four letters of the alphabet are the predetermined symbols, wherein the letter “A” is assigned to a drop having the value 00; the letter “B” is assigned to a drop having the value 01; the letter “C” is assigned to a drop having the value 10; and the letter “D” is assigned to a drop having the value 11.

For example, shown in FIG. 4E is the source stream of FIG. 4D wherein the droplets of the source stream have been paired in groups of two to form drops (as indicated by a horizontal line under each drop) and then the encoded source stream resulting from application of the drop code to each of the drops (wherein each resulting encoded drop is indicated by a vertical down arrow under its corresponding drop). The source stream is thereby converted from a binary stream to a quad stream.

While the predetermined symbols of the drop code have been described herein as being A, B, C, and D by way of illustration, it should be understood by those skilled in the art that this particular designation is arbitrary and that any distinct letter or other symbol may be chosen to represent one of the four drop combinations. For example, the letters W, X, Y, Z; the letters A, C, G, T; the letters P, M, C, Q; the letters G, K, A, R; etc., could be used to represent the four drop combinations.

Also, the present invention contemplates the utilization of two equivalent types of encoding: “single tier” encoding and “two tier” encoding. It can be seen that the droplets of the rippled input stream can be assigned as an “even” droplet or an “odd” droplet, depending on its position in the data stream. For example, if the first or leftmost droplet is considered an even droplet, the next consecutive droplet would be an odd droplet, and the next consecutive droplet would be an even droplet, and so on. When the rippled input stream's even and odd droplets are taken together in one sequential series, or in one tier, when applying the drop code, as generally discussed above, the encoding is termed herein by the Applicant as single tier encoding. However, when the rippled input stream's even and odd droplets are separated into two series or tiers before applying the drop code, the encoding process is termed herein by the Applicant as two tier encoding.

To encode the two tiers, the drops are still formed by taking one even droplet and one odd droplet (from the first and second tiers, respectively). However, two letters are assigned to each possible combination of droplets, i.e., 00, 01, 10, and 11. Then which of the two letters to be assigned to a droplet is dependent on whether the encoding is being performed on the first tier or the second tier. For example, shown in FIG. 6 and taking the exemplary drop code discussed above of A, B, C and D, the possible combinations for two tier encoding is given. The first tier is encoded by assigning the value “00” (given by a “0” even droplet from the first tier and a “0” odd droplet from the second tier) the letter “A”; while for encoding the second tier, the value “00” is assigned the letter “D”. For encoding the first tier, the value “01” (given by a “0” even droplet from the first tier and a “1” odd droplet from the second tier) is assigned the letter “B”; while for encoding the second tier, the value “01” is assigned the letter “C”. For encoding the first tier, the value “10” (given by a “1” even droplet from the first tier and a “0” odd droplet from the second tier) is assigned the letter “C”; while for encoding the second tier, the value “10” is assigned the “B”. For encoding the first tier, the value “11” (given by a “1” even droplet from the first tier and a “1” odd droplet from the second tier) is assigned the letter “D”; while for encoding the second tier, the value “11” is assigned the letter “A”.

As shown in FIG. 5, once the source stream has been encoded, the control unit 18 branches to a step 42 of the encoding subroutine 36. In the step 42, the plurality of symbols of the encoded source stream are then paired to form a series of source pucks. As a result of the pairing, each source puck includes two consecutive symbols or drops of the encoded source stream. However, the symbols are not unique to only one source puck. The series of source pucks include overlapping symbols between adjacent source pucks in that a succeeding source puck in the series of source pucks will included as its first (or left) drop the second (or right) drop of a preceding source puck; and each preceding source puck will include as its second (or right) drop the first (or left) drop of a succeeding source puck. Thus, it can be seen that the first puck in the series of source pucks (which does not succeed another source puck) will only have one “overlapping” drop (its right drop) with one other source puck in the series of source pucks; and the last puck in the series of source pucks (which does not precede another source puck) will only have one “overlapping” drop (its left drop) with one other source puck in the series of source pucks.

For example, shown in FIG. 4F is the encoded source stream of FIG. 4E wherein the encoded drops of the encoded source stream have been paired to form source pucks (as indicated by alternating horizontal lines below the pairings of encoded drops). The source pucks are further identified in FIG. 4F by an alphanumeric identifier having the prefix “SP” located under each source puck. Also, for purposes of further discussion herein, each of the source pucks of FIG. 4F, and its corresponding alphanumeric identifier, is shown in series in FIG. 4G. As can be seen, the pairing step 42 of the encoding subroutine 36 should result in an odd number of source pucks.

Duplicate Rippled Stream

For the duplicate rippled stream discussed above, the control unit 18 branches to a step 44, as shown in FIG. 3. In step 44, the duplicate rippled stream is “rotated to the left” such that each of the droplets in the duplicate rippled stream is shifted a position to the left, and the left-most droplet is looped to the right-most position which is vacated. The duplicate rippled stream is rotated to the left to the same degree that the rippled input stream is rotated to the right during formation of the source stream (e.g., by N+1 droplets). For example, shown in FIG. 4H is the duplicate rippled stream (which is a duplicate of the rippled input stream shown in FIG. 4B) which is rotated to the left by 44+1 or 45 droplets.

The control unit then branches to a step 46, wherein the droplets of the rotated duplicate rippled stream are reversed in order. For example, shown in FIG. 4I is the rotated duplicate rippled stream of FIG. 4H which has been reversed in order. The droplets of the rotated duplicated rippled stream can be reversed in order by rotating the droplets or by defining a starting offset, in a similar manner as discussed above with reference to the source stream. The control unit 18 then branches to a step 48, wherein a final end droplet is added to the end of the rotated and reversed duplicate rippled stream. In one embodiment, the final end droplet is equal to the first droplet of the rotated and reversed duplicate rippled stream to make the total count of droplets even. The resulting stream of the steps 44, 46 and 48 is referred to herein as a “reverse stream.”

Similar to the source stream, it should be understood that while the super cooling process is described in one embodiment as “rotating” droplets to form the reverse stream, the reverse stream can be equivalently generated by defining a starting offset at which to begin forming a pre-reversal stream from which the reverse stream is generated. If the first droplet in the duplicate rippled stream is considered to have an offset of zero, then the starting offset should be defined to be N+1, where N is the length of the input stream (including any padding droplets). For example, for the duplicate rippled stream which is duplicated from the rippled input stream of FIG. 4B, the starting offset would be defined as 44+1 or 45. Therefore, the droplet at offset 45 (with the first droplet of the duplicate rippled stream being at offset zero) would be the first droplet of the pre-reversal stream. Then the succeeding droplets of the duplicate rippled stream would be taken in reverse order and put in the reversal stream until the beginning of the duplicate rippled stream is reached, and then continue on to the end of the duplicate rippled stream until the droplet at offset 45 is reached. This accomplishes the same end result to obtain the reverse stream without the need to from the duplicate rippled stream, rotating it left and then reversing it.

Once the reverse stream is generated in the steps 44, 46 and 48, the control unit 18 branches to an encoding subroutine, which is shown in FIG. 3 as a step 50. The encoding subroutine 50 for the reverse stream is similar to the encoding subroutine 36 discussed above with reference to the source stream. Therefore, for purposes of brevity, the encoding subroutine 50 for the reverse stream is discussed summarily below.

For purposes of clarity of understanding the scheme for formation of the pucks, an interim step is gone through in the encoding subroutine 50. The encoding subroutine 50 for the reverse stream is shown in more detail in FIG. 7. At a step 52, the plurality of droplets of the reverse stream are paired to form drops, and each drop is assigned a predetermined symbol according to the values of the droplets in the drop so as to form an encoded reverse stream comprising a plurality of symbols. Preferably, the drop code used to form the encoded reverse stream is the same as the drop code used to form the encoded source stream (e.g. A, B, C, and D). For example, shown in FIG. 4K is the reverse stream of FIG. 4J wherein the droplets of the reverse stream have been paired to form drops (as indicated by a horizontal line under each drop) and then the encoded reverse stream resulting from application of the drop code to each of the drops (wherein each resulting encoded drop is indicated by a vertical down arrow under its corresponding drop). The reverse stream is thereby converted from a binary stream to a quad stream.

Once the drops of the reverse stream are encoded, the control unit 18 branches to a step 60 of the encoding subroutine 50, wherein the plurality of drops or symbols of the encoded reverse stream are paired so as to form a series of pucks in a similar manner as discussed above for the formation of the source pucks. However, since the pucks are formed from the reverse stream in the steps 52 and 60, the pucks are specifically referred to herein by the Applicant by the term “reverse pucks,” “reverse entities,” or “reverse drop pairs.”

Each reverse puck includes two consecutive drops of the encoded reverse stream, wherein the series of reverse pucks include overlapping drops between adjacent reverse pucks in that a succeeding reverse puck in the series of reverse pucks will include as its first (or left) drop the second (or right) drop of a preceding reverse puck, and each preceding reverse puck will include as its second (or right) drop the first (or left) drop of a succeeding reverse puck. For example, shown in FIG. 4L is the encoded reverse stream of FIG. 4K wherein the encoded drops of the reverse stream have been paired to form reverse pucks (as indicated by alternating horizontal lines under the pairings of encoded drops). The reverse pucks are further identified in FIG. 4L by an alphanumeric identifier having the prefix “RP” located under each reverse puck. Also, for purposes of further discussion herein, each of the reverse pucks of FIG. 4L, and its corresponding alphanumeric identifier, is shown in series in FIG. 4M. As can be seen, the pairing step 60 of the encoding subroutine 50 should also result in an odd number of reverse pucks (which is also equal to the number of source pucks in the series of source pucks).

It should be noted that every puck in the series of source pucks shown in FIG. 4G has two symbols which are different from each other except generally one, which is located about the middle of the series of source pucks. The same is true for the series of reverse pucks shown in FIG. 4M. The source puck and the reverse puck which have two symbols that are equal or the same symbol are referred to herein by Applicant as an “inversion puck” or “middle puck.” For example, the inversion puck in FIG. 4G is the source puck identified by the alphanumeric identifier “SP22”, which has a value of CC, and the inversion puck in FIG. 4M is the reverse puck identified by the alphanumeric identifier “RP23”, which has a value of BB.

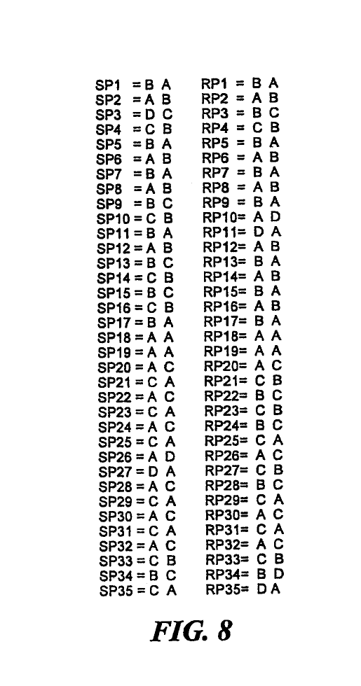

It should be noted that while generally only one inversion puck will exist in the series of source pucks and in the series of reverse pucks, there are situations in which more than one inversion puck will exist in the series of source pucks and in the series of reverse pucks, depending on the number of droplets in the input stream. This is shown by way of example in FIG. 8, wherein the series of source pucks and the series of reverse pucks shown therein have been formed in the manner discussed above for another exemplary input stream, which is equivalent to only the first thirty-six droplets of the exemplary input stream shown in FIG. 4A.

It can be seen in FIG. 8 that in the series of source pucks, there are now two inversion pucks, and in the series of reverse pucks there are now two inversion pucks. To account for or anticipate for the possibility of such occurrences, the super cooling process in one embodiment assigns two pucks as inversion pucks, regardless of whether there are two pucks that have two symbols which are the same. When there are two pucks, each of which have two symbols which are the same, the two pucks are assigned as the inversion pucks. For example, in FIG. 8, the two inversion pucks in the series of source pucks will be the source pucks labeled as “SP18” and “SP19”, and the two inversion pucks in the series of reverse pucks will be the reverse pucks labeled as “RP18” and “RP19”. However, when only one puck exists which has two symbols which are the same, which is referred to herein as a “true inversion puck”, it is assigned as one of the inversion pucks. Then for the series of source pucks, the source puck which succeeds the true inversion puck in the series will be assigned as the second inversion puck for the series of source pucks. For the series of reverse pucks, the reverse puck which precedes the true inversion puck in the series will be assigned as the second inversion puck for the series of reverse pucks. For example, in FIG. 4G, the two inversion pucks will be the source puck labeled as “SP22” (which is the true inversion puck) and the source puck labeled as “SP23” which succeeds it; and in FIG. 4M, the two inversion pucks will be the reverse puck labeled as “RP23” (which is the true inversion puck) and the reverse puck labeled as “RP22” which precedes it.

It can further be seen that when segments of the series of source pucks and segments of the series of reverse pucks are analyzed in a side-by-side comparison, there is a correspondence between the series of source pucks and the series of reverse pucks. In the comparison, each of the series of source pucks and the series of reverse pucks are first separated into two segments, which are referred to herein as a “top half” and a “bottom half.” The segments are generally formed about the inversion pucks. The top half of the series of source pucks includes the inversion pucks and the source pucks that precede the inversion pucks. The bottom half of the series of source pucks includes the inversion pucks and the source pucks that succeed the inversion pucks. Likewise, the top half of the series of reverse pucks includes the inversion pucks and the reverse pucks that precede the inversion puck, and the bottom half of the series of reverse pucks includes the inversion pucks and the reverse pucks that succeed the inversion pucks.

As shown for example in FIG. 4N, when the top half of reverse pucks of FIG. 4M is grouped with the bottom half of the source pucks of FIG. 4G taken in reverse order so as to allow for a side-by-side comparison, it can be seen that generally each reverse puck (with the exception of the first reverse puck) in the top half of reverse pucks has a value which is the reverse of the value of a source puck located in a preceding position in the reverse ordered, bottom half of source pucks. (The precedential relationship between the reverse pucks in the top half of reverse pucks and the source pucks in the reverse ordered, bottom half of source pucks is indicated in FIG. 4N by slanted lines drawn therebetween). In other words, it can be seen that the symbols of each reverse puck represents binary values which are the reverse of the binary values represented by the symbols of the corresponding precedential source puck.

Consider for example the embodiment discussed above wherein the drop code utilized to generate the source pucks and reverse pucks included the symbol A to represent the binary values 00. Those values in reverse are still 00 and therefore the symbol A would again be used to represent that reversal of values. Likewise, the symbol D represents the binary values 11. Those values in reverse are still 11 and therefore the symbol D would again be used to represent that reversal of values. However, the symbol B represents the binary values 01. Those values in reverse are now 10 and therefore a different symbol, symbol C, would be used to represent that reversal of values. Likewise, the symbol C represents the binary values 10. Those values in reverse are now 01 and therefore a different symbol, symbol B, would be used to represent that reversal of values.

Now in the case of the pucks, if for example the reverse puck includes the symbols AD, which represents 0011 (as for RP2), the corresponding preceding source puck represents the reverse of those binary values which is 1100 or the symbols DA (as for SP43). As another example, if the reverse puck includes the symbols DC, which represents 1110 (as for RP3), the corresponding preceding source puck represents the reverse of those binary values, which is 0111 or the symbols BD (as for SP42). As yet another example, if the reverse puck includes the symbols CB, which represents 1001 (as for RP4), the corresponding preceding puck represents the reverse of those binary values, which is 1001 or the symbols CB (as for SP41).

Likewise, there is also a reverse correspondence between the “top half” of the source pucks and the “bottom half” of the reverse pucks taken in reverse order. In other words, when the top half of the source pucks and the bottom half of the reverse pucks taken in reverse order are grouped together and analyzed in a side-by-side comparison, a reverse correspondence exists in that the symbols of each source puck represents binary values which are the reverse of the binary values represented by the symbols of a corresponding precedential reverse puck. For example in FIG. 4O is the top half of source pucks of FIG. 4G grouped with the bottom half of the reverse pucks of FIG. 4M taken in reverse order. (The precedential relationship between the source pucks in the top half of source pucks and the reverse pucks in the reverse ordered, bottom half of reverse pucks is indicated in FIG. 4O by slanted lines drawn therebetween).

Formation of First Group and Second Group

To exploit these reverse relationships, the control unit 18 branches to a grouping subroutine, which is shown in FIG. 3 as a step 64, wherein the series of source pucks resulting from the step 36 and the series of reverse pucks resulting from step 50 discussed above are segmented, reordered and grouped to form a first group and a second group.

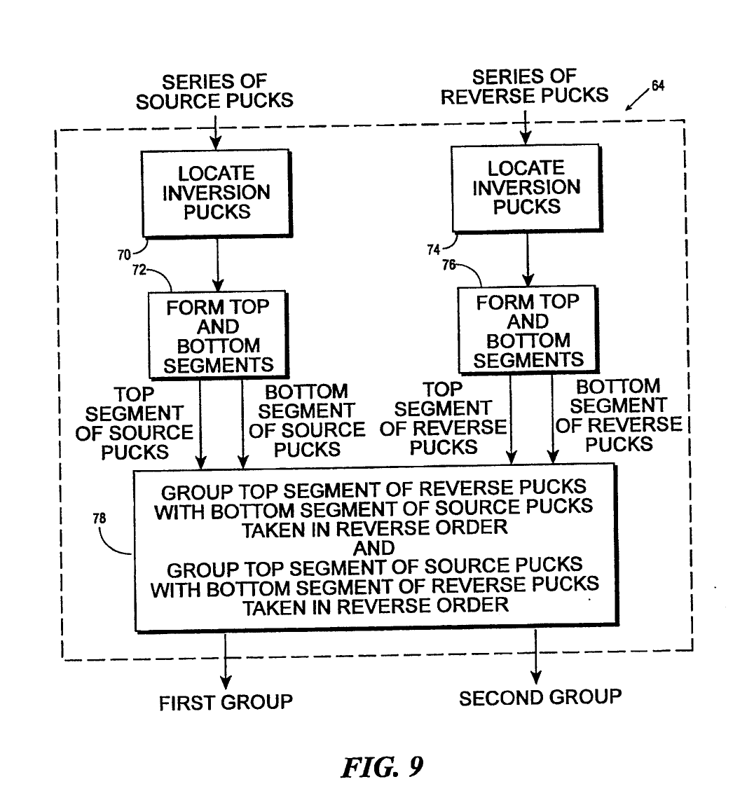

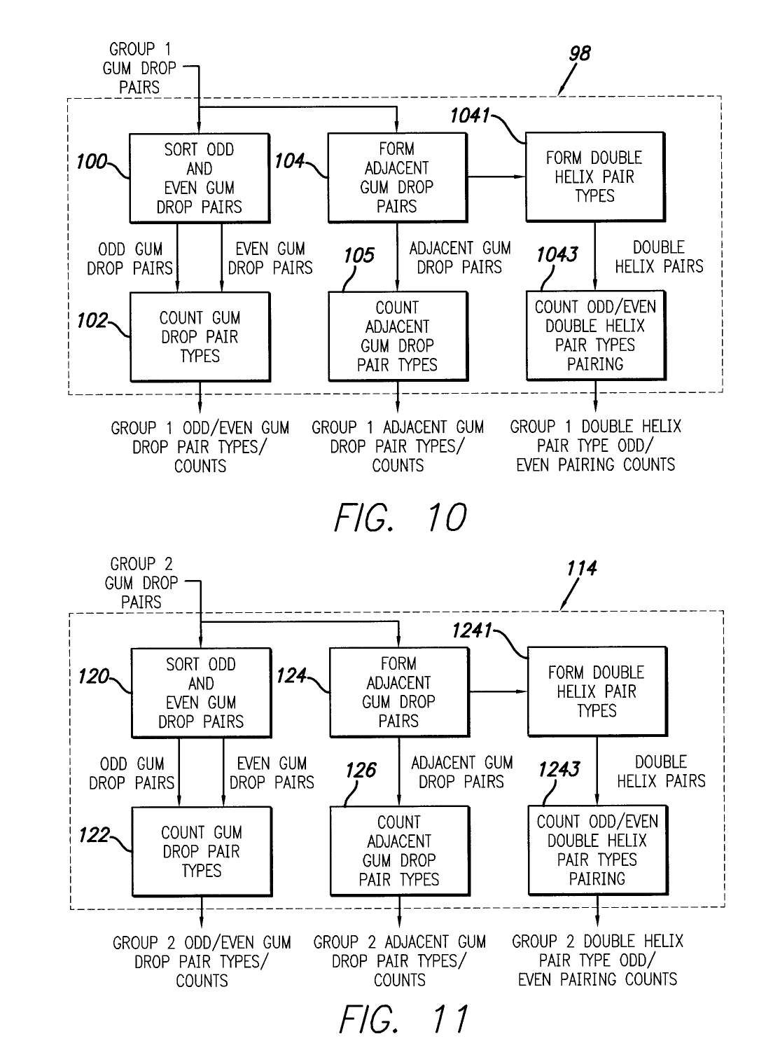

The grouping subroutine 64 is shown in more detail in FIG. 9. In the grouping subroutine 64, the control unit branches to a step 70, wherein the inversion pucks are located within the series of source pucks by identifying at least one source puck in the series of source pucks having two symbols which are equal or the same, as discussed above. The control unit 18 then branches to a step 72, wherein the series of source pucks are segmented generally about the inversion pucks so as to form a top segment of source pucks (also referred to herein as a “first segment”) and a bottom segment of source pucks (also referred to herein as a “second segment”). The top segment of source pucks includes the inversion pucks and all the source pucks that precede the inversion pucks in the series of source pucks. The bottom segment of source pucks includes the inversion pucks and the source pucks that succeed the inversion pucks in the series of source pucks.

Likewise for the series of reverse pucks, the control unit 18 in a step 74 locates the one or more inversion pucks within the series of reverse pucks by identifying at least one reverse puck in the series of reverse pucks having two symbols that are equal or the same, in a manner as discussed above. The control unit 18 then branches to a step 76, wherein the series of reverse pucks are segmented generally about the inversion pucks to form a top segment of reverse pucks (also referred to herein as a “third segment”) and a bottom segment of reverse pucks (also referred to herein as a “fourth segment”). The top segment of reverse pucks includes the inversion pucks and the reverse pucks that precede the inversion puck in the series of reverse pucks. The bottom segment of reverse pucks includes the inversion pucks and the reverse pucks that succeed the inversion pucks in the series of reverse pucks.

Although the grouping subroutine 64 is discussed above in terms of the steps 70 and 72, and then in the steps 74 and 76, it should be understood that the steps 70 and 72 can be preformed subsequent to or simultaneously with the steps 74 and 76.

Once the source pucks and the reverse pucks have been segmented in the steps 72 and 76, respectively, the control unit branches to a step 78 of the grouping subroutine 64, wherein the top segment of reverse pucks is grouped with the bottom segment of source pucks taken in reverse order to form the first group; and the top segment of source pucks is grouped with the bottom segment of reverse pucks taken in reverse order to form the second group. (See FIGS. 4N and 4O for an exemplary first group and an exemplary second group, respectively, which results from the series of source pucks of FIG. 4G and the series of reverse pucks of FIG. 4M.)

Once the first group and second group are formed in the step 64, the control unit 18 at this point utilizes the first group and the second group as an input to different sets of logic, although the sets of logic are similar. The first group will be discussed first for purposes of clarity of understanding. However, it should be understood that the logic for the first group and the logic for the second group can be performed in any order or simultaneously.

First Group—Summarization and Formation of Super Cooled Set

As shown in FIG. 3, after the first group is formed in step 64, the control unit 18 branches to a step 82, wherein the source pucks and the reverse pucks in the first group are reordered to form an ordering referred to herein as a “first group bubble.” In general, the process of reordering the source pucks and reverse pucks is referred to herein by the Applicant by the term “bubbling” or derivations thereof. To bubble the first group to form the first group bubble, the first reverse puck in the top segment of reverse pucks is assigned to a first entry of the first group bubble, followed by a plurality of entries comprising pairings of each succeeding reverse puck in the top segment of reverse pucks with its corresponding precedential source puck in the reverse ordered, bottom segment of source pucks. This operation is more specifically referred to as “Right/Left” bubbling.

Each of the reverse relationship pairings resulting from the bubbling step 82 is referred to herein by the Applicant by the term “duet” or “entities that have a precedence relationship to each other.” The final duets or last entries of the first group bubble, which includes the pairings of the inversion pucks in the top segment of reverse pucks and the inversion pucks in the reverse ordered bottom segment of source pucks, are referred to herein as “inversion duets.” For example, shown in FIG. 4P is an exemplary first group bubble resulting from the bubbling of the first group of FIG. 4N in a manner as discussed above. The first reverse puck (RP1) is given as BA, which is followed by a plurality of duets starting with AD-DA (RP2-SP43), DC-BD (RP3-SP42), CB-CB (RP4-SP41), and so on. The last two entries of the first group bubble are the inversion duets AB-CA (RP22-SP23) and BB-CC (RP23-SP22). (Note that the duets, as well as other combinations of pucks, are shown and discussed herein with a “-” placed therebetween for purposes of visual clarity, and the “-” generally has no other value or significance with regards thereto).

It can be seen that the first reverse puck in the first group bubble is not paired in a duet. This first unpaired puck is referred to herein by the Applicant by the term “bubble scum” or “first unpaired entity.” The set of duets following the bubble scum, with the exclusion of the inversion duets, is referred to herein by the term “bubble core” or “entity core.”

The adjacent pucks in adjacent duets in the bubble core in a sense “glue” the pucks together and when taken in the correct order in the bubble, substantially define the original input stream. Therefore, as part of the super cooling process, they are paired together in step 82 to form a plurality of entities referred to by the Applicant as “gum drop pairs,” “eight-bit entities,” or “gum pucks” . The gum drop pairs are also referred to herein by the Applicant by the terms “inner pairs.” In other words, the gum drop pairs are pairings of adjacent pucks in adjacent duets in the bubble core (one being a source puck from a preceding duet and one being a reverse puck from a succeeding duet). The collective gum drop pairs are referred to herein by the Applicant as a “bubble gum set.” Because the gum drop pairs are formed only within the bubble core, it can be seen that two pucks, the first and last pucks in the bubble core, will not have an adjacent puck to be paired with to form a gum drop pair, and therefore are not part of the bubble gum set.

For example, shown in FIG. 4Q is the bubble gum set comprising the gum drop pairs for the first group as determined from the first group bubble of FIG. 4P. The first gum drop pair of the bubble gum set shown in FIG. 4Q is the pairing of the adjacent pucks in the first pair of adjacent duets in the bubble core, which is DA-DC (SP43-RP3). The following gum drop pairs are BD-CB (SP42-RP4), CB-BA (SP41-RP5), and so on, and ends with the last gum drop pair of CA-BA (SP25-RP21). It can be seen that the first and last pucks in bubble core shown in FIG. 4P, which are AD (RP2) and AC (SP24) are not part of the bubble gum set.

The next stage of the super cooling process performed by the control unit 18 involves a summarization technique. In the previous steps of the super cooling process discussed above, the relative order of entities has been generally maintained. In the following steps, the entities are summarized. These summation entities result in an unordered representation of at least a portion of the input stream, containing in them positional information.

Once the first group bubble has been formed in the step 82, the control unit 18 branches to a summarization subroutine, which is shown in FIG. 3 as a step 98. In general, in the summarization subroutine 98, the gum drop pairs are summarized so as to represent the information therein in a more concise manner. To summarize the gum drop pairs, the set of gum drop pairs are evaluated to determine how many gum drop pairs contain the same sequence of drops or symbols. For each unique sequence or combination of drops within the set of gum drop pairs, which is also referred to herein as a “gum drop pair type”, a count value is assigned representing the number of gum drop pairs which contain that gum drop pair type.

One embodiment of the summarization subroutine 98 is shown in more detail in FIG. 10. In a first step 100 of the summarization subroutine 98, the gum drop pairs in the first group bubble are defined as an “odd” or “even” depending on the placement or order of the gum drop pair within the bubble gum set of the first group bubble. For example, also shown in FIG. 4Q next to each gum drop pair is an odd/even assignment for purposes of illustration, wherein each of the odd gum drop pairs are identified by the character “o” next to the gum drop pair, and each of the even gum drop pairs are identified by the character “e” next to the gum drop pair.

In a step 102 of the summarization subroutine 98, the odd set of gum drop pairs are evaluated to determine how many gum drop pairs contain the same sequence of drops or symbols, i.e., have the same gum drop pair type; and similarly the even set of gum drop pairs are evaluated to determine how many gum drop pairs have the same gum drop pair type. For each unique gum drop pair type contained within the sets of odd and even gum drop pairs, a count value is assigned representing the number of gum drop pairs which contain that gum drop pair type in both the odd set of gum drop pairs and the even set of gum drop pairs. For example, shown in FIG. 4R is the odd set of gum drop pairs of FIG. 4Q for the first group, and the unique gum drop pair types from the odd set with the count of gum drop pairs having that unique gum drop pair type. Below the odd set of gum drop pairs in FIG. 4R is the even set of gum drop pairs of FIG. 4Q for the first group, and the unique gum drop pair types from the even set with the count of gum drop pairs having that unique gum drop pair type.

While the summarization subroutine 98 has been described above in one embodiment as defining the gum drop pairs as odd or even in step 100 and then determining gum drop pair types and counts for the odd and even set of gum drop pairs in step 102, it should be understood that the odd/even characterization of step 100 can be dropped and the gum drop pair types and counts be determined for the collective set of gum drop pairs in step 102.

Also, the present invention contemplates that the gum drop pairs can be summarized and represented in a different manner. For example, it can be seen that there is a correspondence between adjacently disposed gum drop pairs in that the second or right puck (i.e., the right pair of two symbols or drops) of a preceding gum drop pair has a reverse relationship with the first or left puck (i.e., the left pair of two symbols or drops) of a succeeding gum drop pair. For example, if the right puck of the preceding gum drop pair includes the symbols DC, which represents the value 1110, the left puck of the succeeding gum drop pair includes symbols which represent the reverse of that value, 0111, which is BD.

To utilize this relationship between adjacently disposed gum drop pairs, the summarization subroutine 98 in one embodiment further includes a step 104 which takes the gum drop pairs resulting from the step 82 for the first group bubble and represents them in a partial form, which is referred to herein by the Applicant by the term “adjacent gum drop pairs”. In general, to form each adjacent gum drop pairs in the step 104, two consecutive and adjacently disposed gum drop pairs (one odd and one even) are taken together, which is referred to herein by the Applicant as a “fully qualified” representation of the gum drop pairs. Then, from the adjacent gum drop pairs, the repetitive information in the preceding gum drop pair is omitted. The process of removing the repetitive information in the representation of two adjacently disposed gum drop pairs is referred to herein by the Applicant as a “partially qualified” representation of gum drop pairs.

For example, shown in FIG. 4S are the fully qualified adjacently disposed gum drop pairs for the first group of FIG. 4Q, and the resulting partially qualified adjacent gum drop pairs derived therefrom. The omitted puck in the adjacent gum drop pairs is represented by a “:” in FIG. 4S for purposes of illustration and clarity, however it should be understood that the “:” has no other significance in regards thereto. The three remaining pucks of the adjacent gum drop pairs is referred to herein by the Applicant as a “triplet.” However, it should be understood that each of the adjacent gum drop pairs includes information indicative of two gum drop pairs (one even and one odd), and thus is actually indicative of four pucks.

Once the partially qualified adjacent gum drop pairs for the first group are formed in the step 104, the control unit 18 may branch to a step 105, wherein the set of adjacent gum drop pairs are evaluated to determine any adjacent gum drop pairs which contain the same sequence of drops or symbols, in a similar manner as discussed above for the gum drop pair counts. For each unique sequence of drops in the adjacent gum drop pairs, which is referred to herein as an “adjacent gum drop pairs type”, a count value is assigned representative of the number of the adjacent gum drop pairs which contain that sequence. For example, also shown in FIG. 4S are the corresponding adjacent gum drop pairs types and counts for the first group.

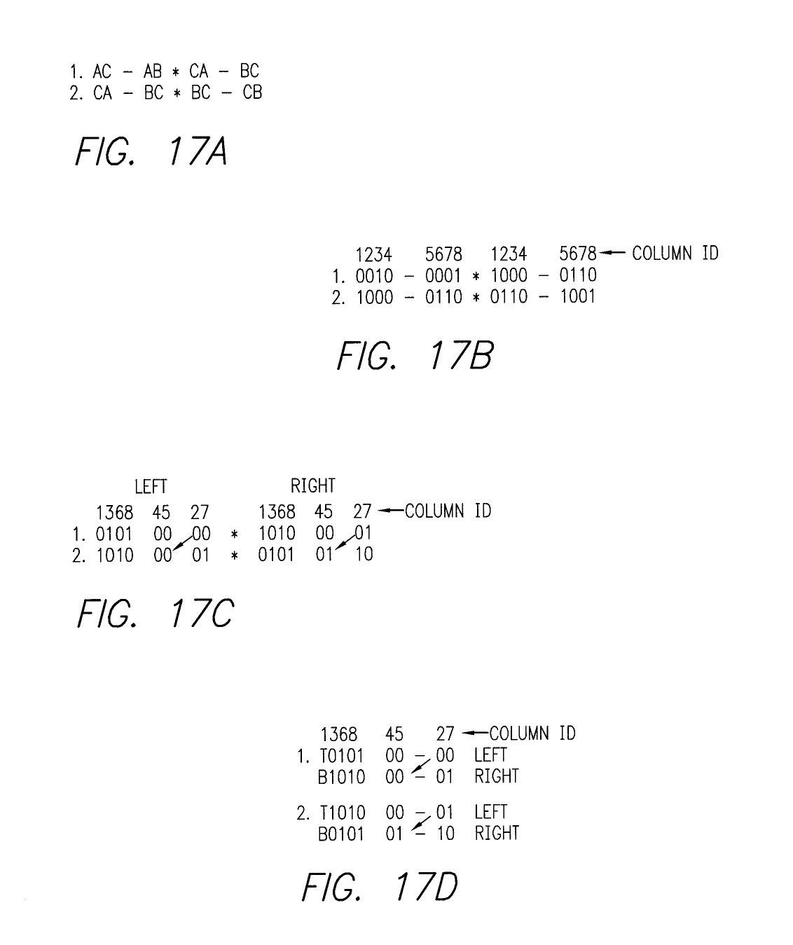

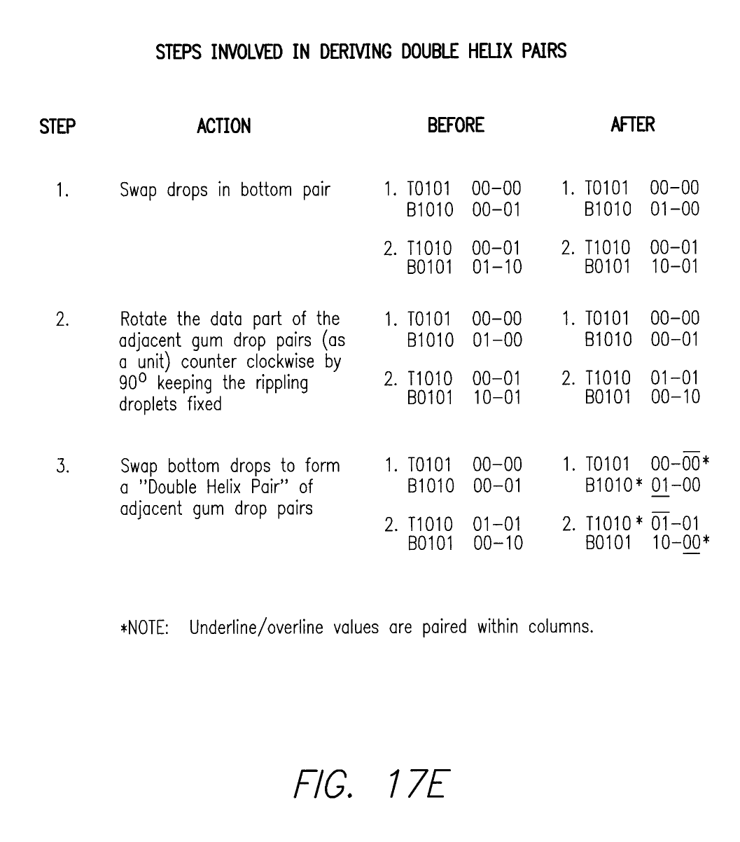

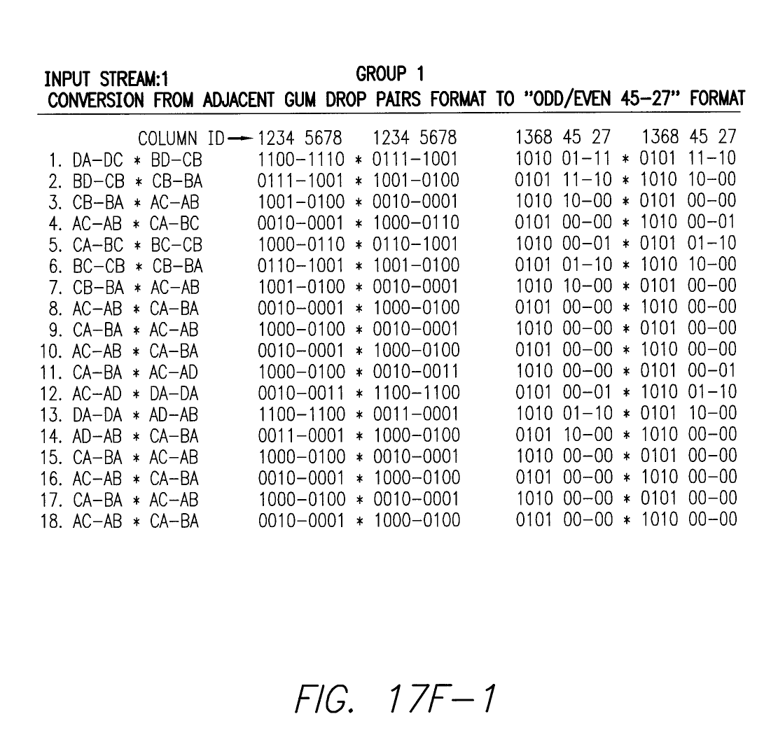

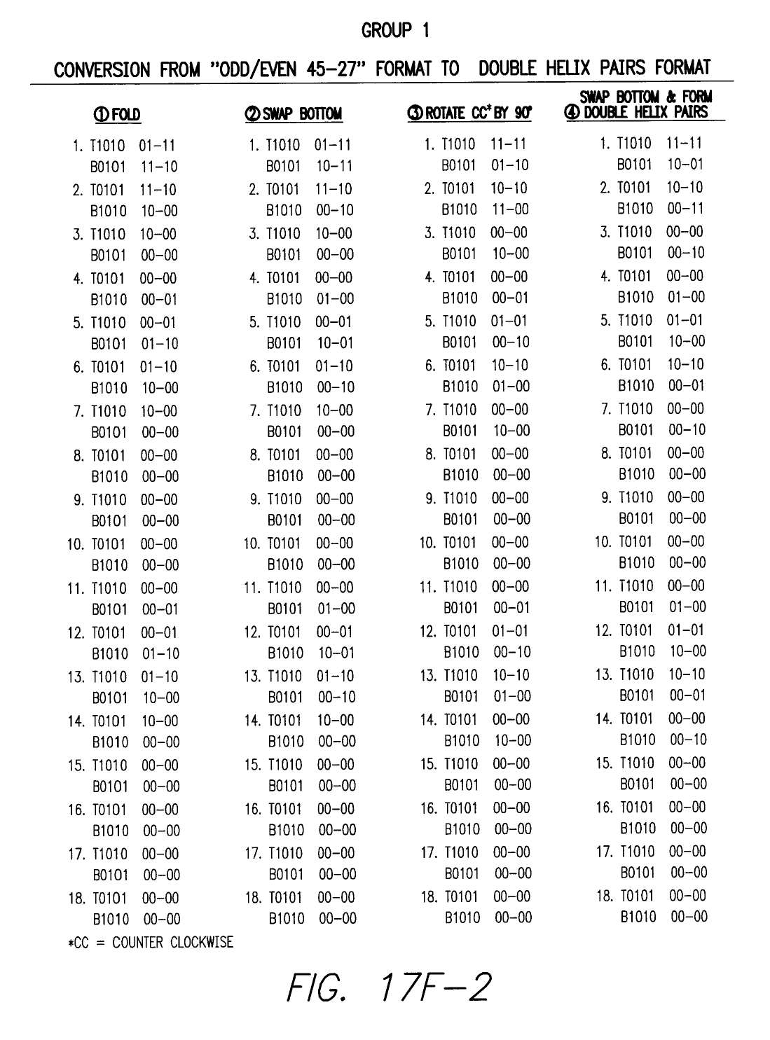

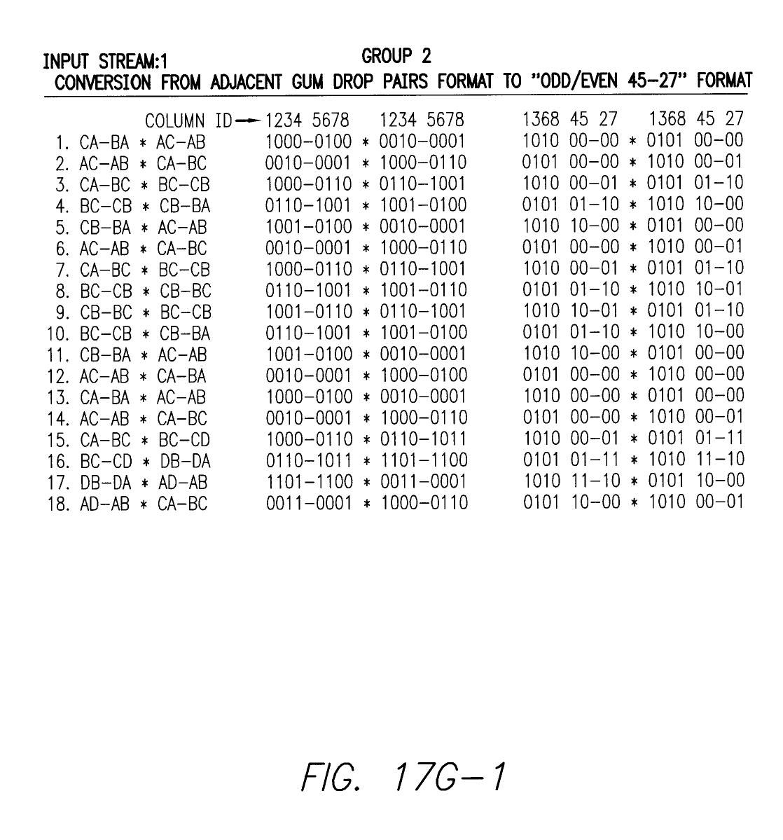

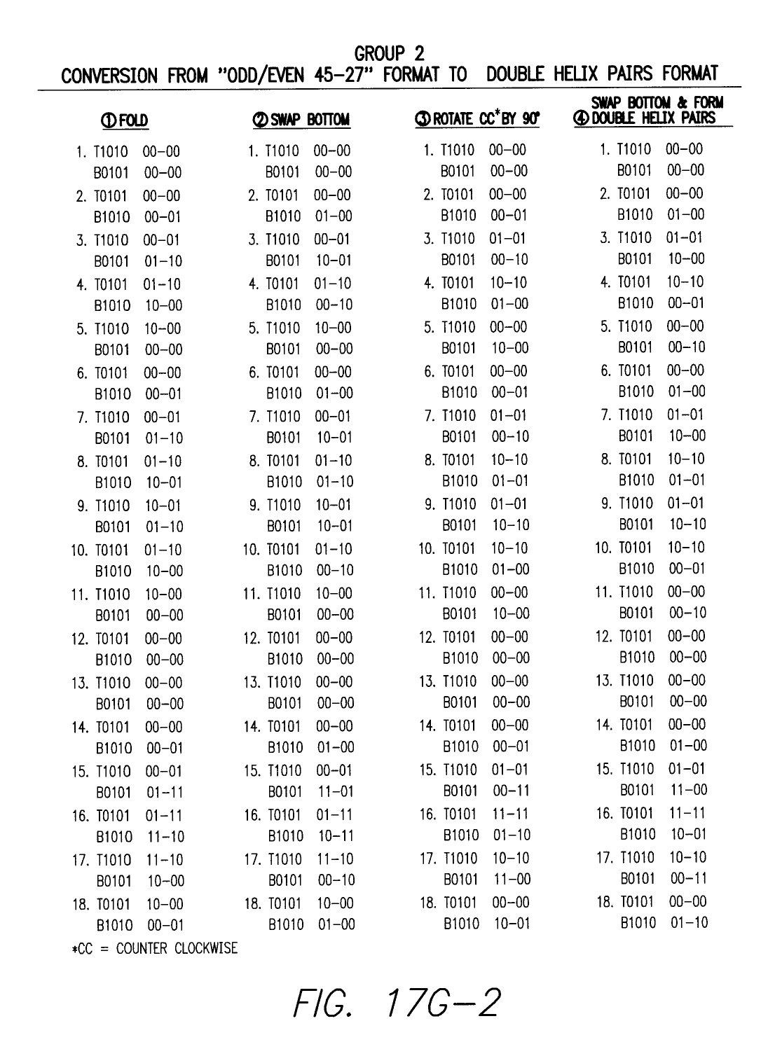

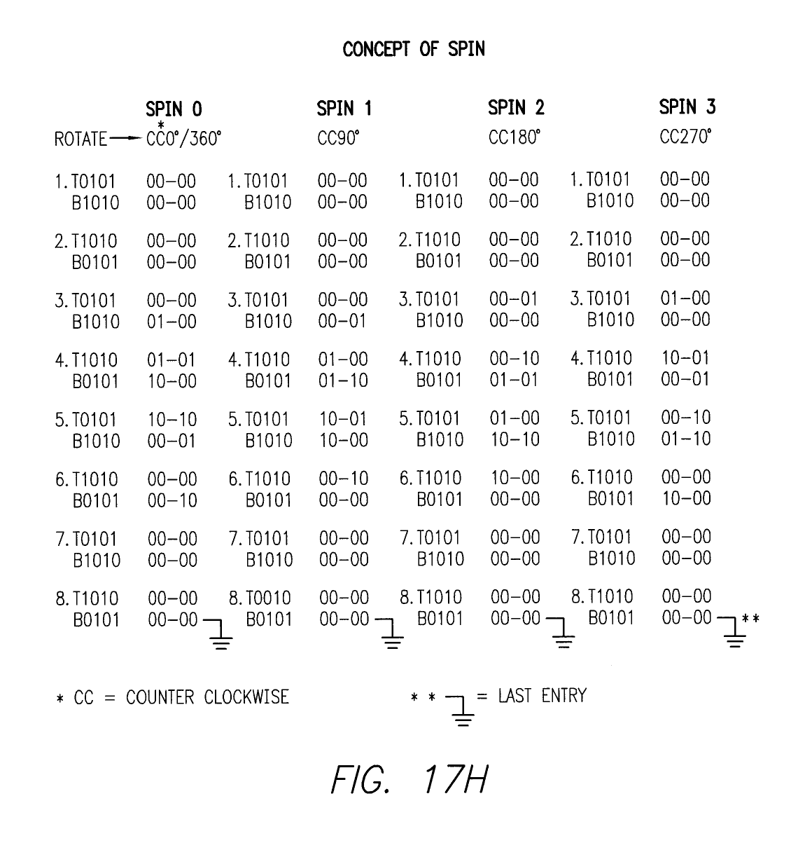

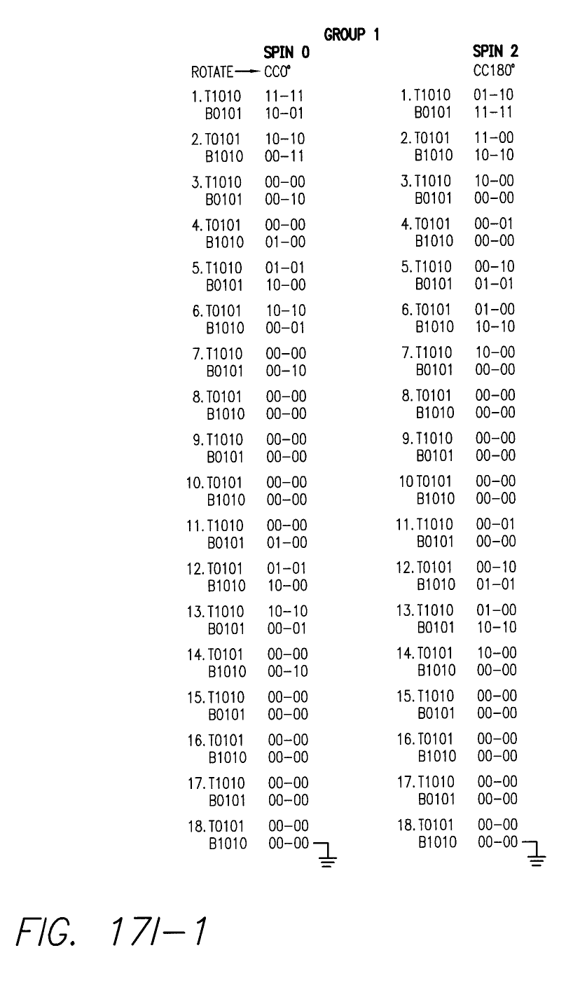

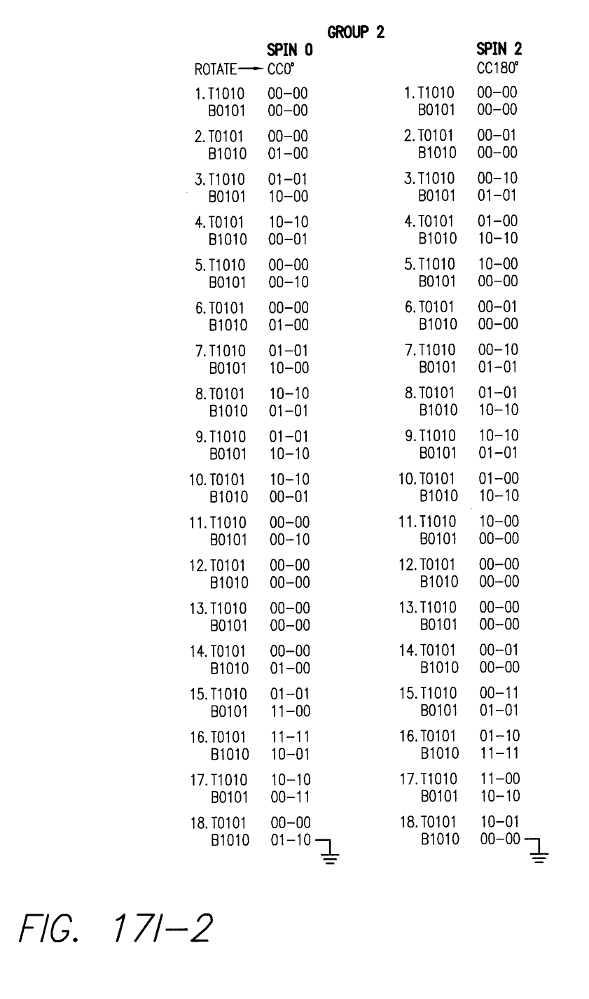

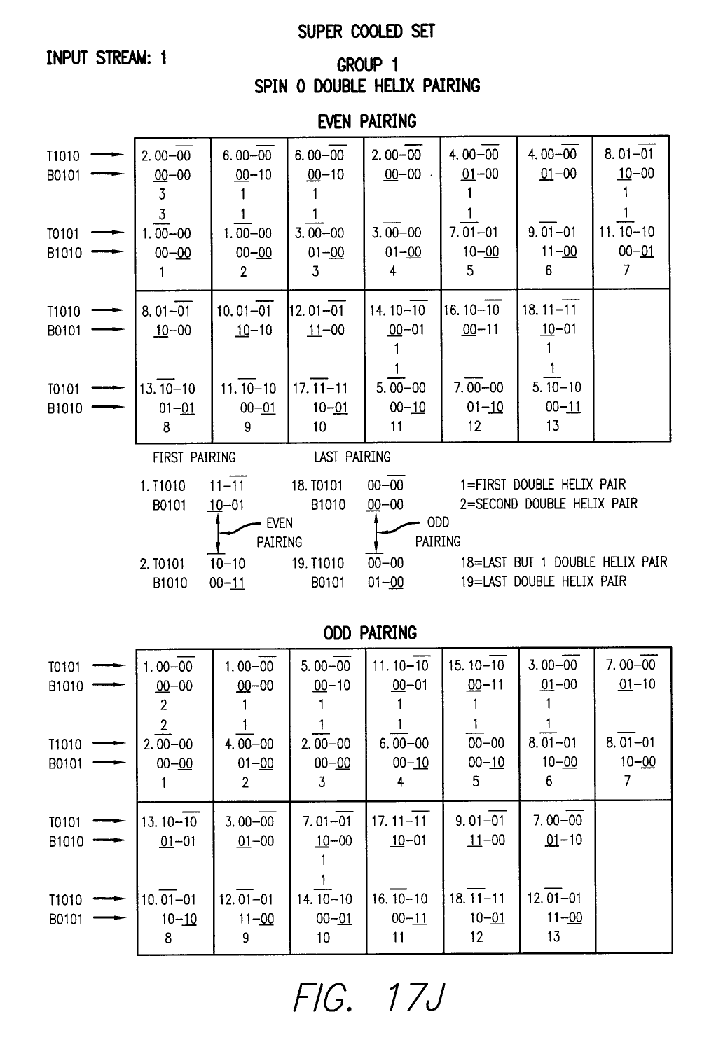

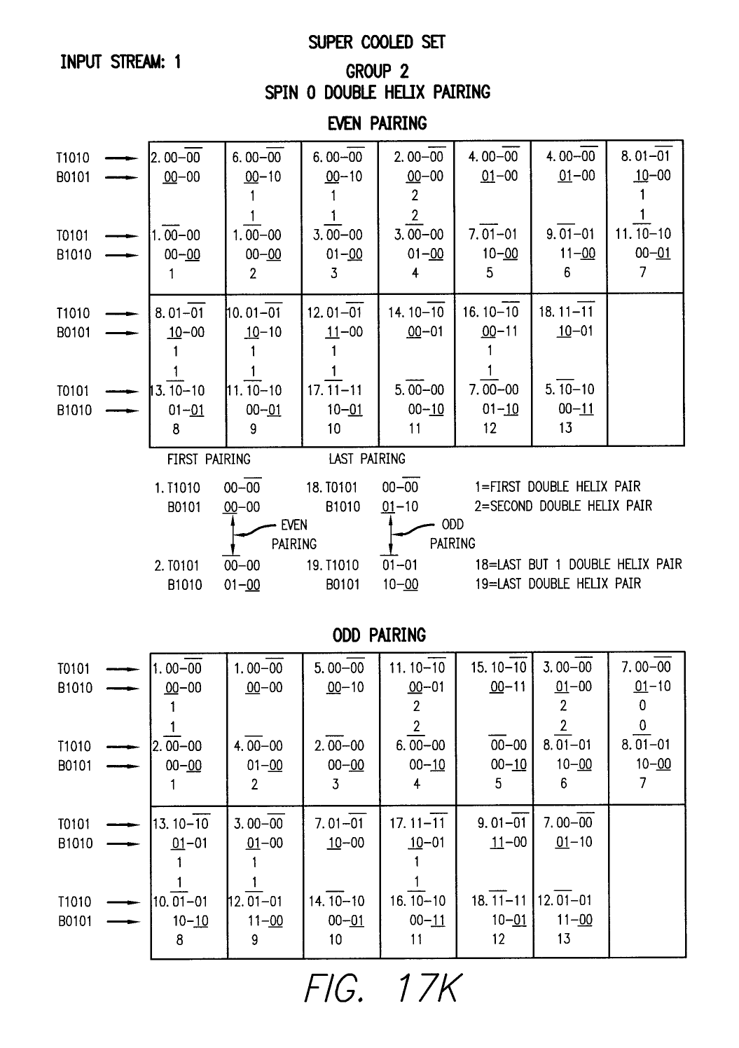

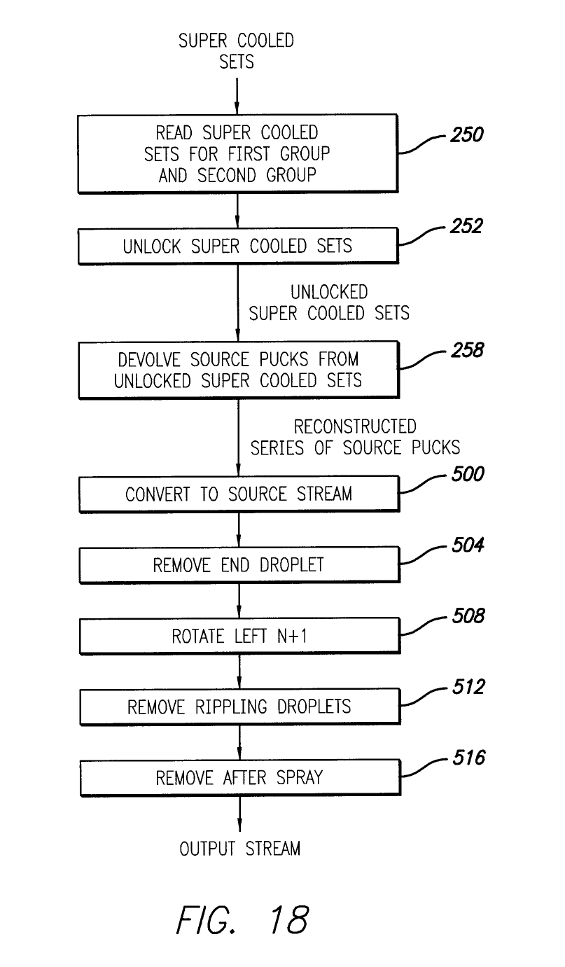

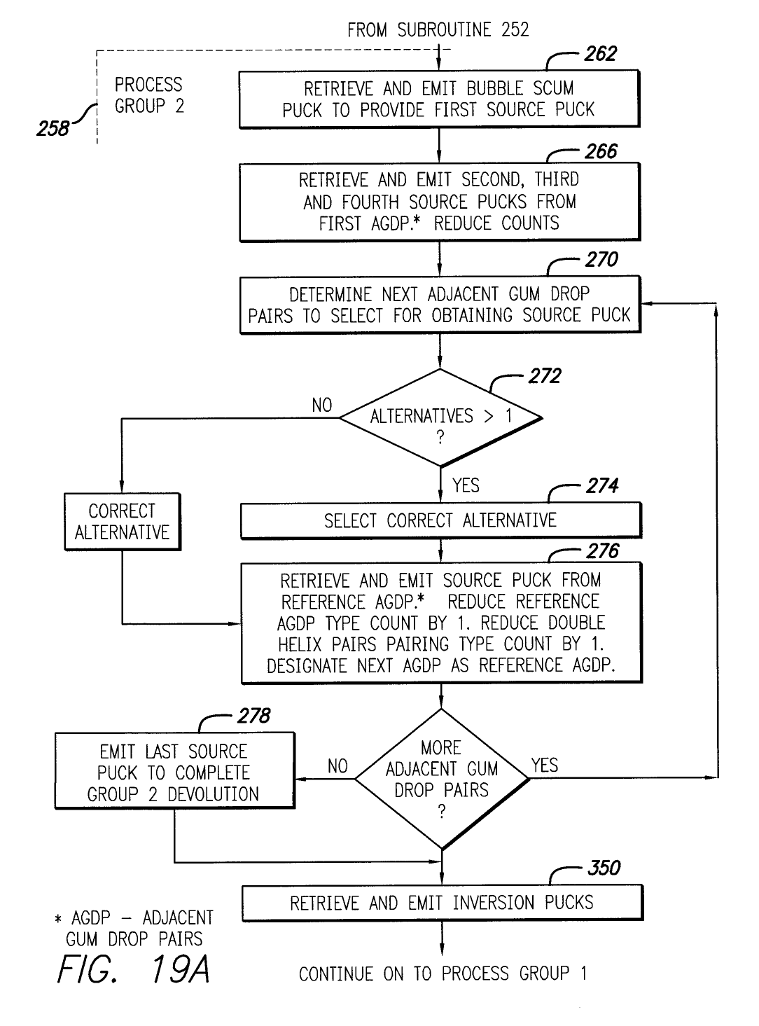

Once the partially qualified adjacent gum drop pairs for the first group are formed in the step 104, the control unit 18 may also branch to a step 1041 as shown in FIG. 10, wherein the set of adjacent gum drop pairs are converted into a double helix pair format. For example, FIG. 17A illustrates two exemplary consecutive adjacent gum drop pairs, [AC-AB*CA-BC] and [CA-BC*BC-CB]. In FIG. 17B, the consecutive adjacent gum drop pairs are represented in their droplet values (i.e. 0 or 1). For example [AC-AB] is represented by droplet values [0010-0001]. This representation is based on the droplet values previously discussed herein (i.e. A=00, B=01, C=10, D=11).

The representations of the adjacent gum drop pairs in their droplet values (i.e. 0 or 1) are assigned within left and right columns represented by the numbers 1-8. For example, the droplet values [0010] representing [AC] are assigned to columns 1, 2, 3 and 4. The droplet values within the columns 1, 3, 6, and 8 (hereinafter referred to as C1, C3, C6, C8) are representative of the “rippling droplets.” Droplet values within columns 2, 4, 5, and 7 (hereinafter referred to as C2, C4, C5, C7) are representative of the input data stream.

In the next step, the rippling droplets are separated from the droplet values representing the input data stream as shown in FIG. 17C. Droplet values within C1, C3, C6, and C8 of FIG. 17B are separated and placed in the order:
[C1 droplet value, C3 droplet value, C6 droplet value, C8 droplet value].

For example, the “rippling droplets” in the left first adjacent gum drop pairs are placed in the order [0101], and in the right first adjacent gum drop pairs as [1010]. The “rippling droplets” in the left second adjacent gum drop pairs are placed in the order [1010], and in the right second adjacent gum drop pairs as [0101]. The “rippling droplets” having the value [0101] are arbitrarily designated as “even.” The “rippling droplets” having the value [1010] are arbitrarily designated as “odd.” Droplet values within columns C2, C4, C5, and C7 of FIG. 17B are then separated and placed in the order:
[C4 droplet value, C5, droplet value, C2 droplet value, C7 droplet value]

For example, as illustrated in FIG. 17C, the droplet values in columns C2, C4, C5, and C7 of the left first adjacent pair are placed in the order [0000], and in the right first adjacent pair as [0001]. The droplet values in columns C2, C4, C5, and C7 of the left second adjacent gum drop pairs are placed in the order [0001], and in the right second adjacent gum drop pairs as [0110]. This format of is generally referred to as the “45-27 format” as the droplet values within C2, C4, C5, and C7 are arranged in the order C4, C5, C2, and C7 respectively.

When the droplet values are separated and arranged in the “45-27 format,” as illustrated in FIG. 17C, the droplet values reflect the precedence relationship exhibited in the adjacent gum drop pairs. For example, the values in columns C2 and C7 of the first adjacent gum drop pairs have a precedential relationship to columns C4 and C5 of the second adjacent gum drop pairs. This is illustrated in FIG. 17C as an arrow that links the left first adjacent gum drop pairs [00] to the left second adjacent gum drop pairs [00] having a like value. Similarly, an arrow links the right first adjacent gum drop pairs [01] to the right second adjacent gum drop pairs containing [01] having a like value.

The droplet values of FIG. 17C are then folded as shown by FIG. 17D. In folding the adjacent gum drop pairs, generally the right section is folded below the left section. In the folded representation, a letter “T” is added to the left section and a letter “B” is added to the right section of the rippling droplets signifying the Top and Bottom sections of the folded adjacent gum drop pairs. The letter “T” is added to the left first adjacent gum drop pairs and the letter “B” is added to the right first adjacent gum drop pairs. The left first adjacent gum drop pairs are then placed on top of the right first adjacent gum drop pairs. Similarly, the letter “T” is added the left second adjacent gum drop pairs and the letter “B” is added to the right second adjacent gum drop pairs. The left second adjacent gum drop pairs are then placed on top of the right second adjacent gum drop pairs forming a top pair and a bottom pair. For example, in FIG. 17D, the top pair of the first adjacent gum drop pairs is comprised of [T0101 00-00], and the bottom pair of the first adjacent gum drop pairs is comprised of [B1010 00-01]. Similarly, the top pair of the second adjacent gum drop pairs is comprised of [T1010 00-01], and the bottom pair of the second adjacent gum drop pairs is comprised of [B0101 01-10].

The adjacent gum drop pairs are then transformed to double helix pairs. The transformation process applied to the adjacent gum drop pairs of FIG. 17D is shown in FIG. 17E. It should be noted that throughout the transformation process the rippling droplets remain in a fixed position, (i.e. droplets within the columns C1, C3, C6, and C8).

Initially, the droplets in the bottom pair of columns C4, C5, and C2, C7 are swapped or reversed in order. This is shown in Step 1 of FIG. 17E. For example, the bottom pair of the first adjacent gum drop pairs before swapping is [00-01]. After swapping, the bottom pair of the first adjacent gum drop pairs is [01-00] as shown in FIG. 17E.

Once the droplets in the bottom pair are swapped, the droplets in columns C4, C5, and C2, C7 are treated as a unit and rotated counter-clockwise by one position or ninety degrees. This is shown in Step 2 of FIG. 17E. For example, as shown in FIG. 17E, prior to rotation, in the second adjacent gum drop pairs the top pair is [00-01] and the bottom pair is [10-01]. After rotation, the top pair is [01-01] and the bottom pair is [00-10].

After rotation, the droplets in the bottom pair of columns C4, C5, and C2, C7 are again swapped or reversed in order to form “double helix pairs.” This is shown in Step 3 of FIG. 17E. For example, the bottom pair of the first adjacent gum drop pairs before swapping is [00-01]. After swapping, the bottom pair of the first adjacent gum drop pairs is [01-00] as shown in FIG. 17E forming the first double helix pair. Similarly, the bottom pair of the second adjacent gum drop pairs before swapping is [00-10], and after swapping is [10-00] forming the second double helix pair.

Each double helix pair consists of at least one “even” drop pair and at least one “odd” drop pair. As previously described, rippling droplets having the value [0101] are arbitrarily designated as “even,” and the rippling droplets having the value [1010] are arbitrarily designated as “odd.” As such, an example of an even drop pair in FIG. 17E is shown as [T0101 00-00] and its corresponding odd drop pair within the double helix pair is shown as [B1010 01-00]. Similarly, the odd drop pair [T1010 00-01] corresponds to the even drop pair [B0101 10-01] within the double helix drop pair.

Generally, double helix drop pairs will pair with similar rippling droplet values. For example, if [B0101 XX-XX] is part of a double helix drop pair wherein XX are two droplets, [B0101 XX-XX] will generally pair with [T0101 XX-XX] of the next double helix drop pairs. Similarly, If [B1010 XX-XX] is part of a double helix drop pair wherein XX are two droplets, [B1010 XX-XX] will generally pair with [T1010 XX-XX] of the next adjacent double helix drop pairs.

The pairing of adjacent gum drop pairs using rippling droplet values can provide either an odd pairing or an even pairing. An odd pairing is formed when the bottom rippling droplets of a double helix pair has a value of [1010]. An even pairing is formed when the bottom rippling droplets of a double helix drop pair has a value of [0101]. This is illustrated for “odd” pairing in step 3 of FIG. 17E in the “after” column. Also, the values that must pair (i.e., must be the same) are shown by an underline/overline within the same columns for two consecutive double helix pairs. It should also be noted that the two drops of items labeled with a “T” are the same. For instance item 1 is shown as T0101 00-00 (where both drop values are 00) and item 2 is shown as T1010 01-01 (where both drop values are 01).

Referring again to FIG. 10, the adjacent gum drop pairs are converted to double helix pairs as illustrated by steps 1041. For convenience, the conversion of the adjacent gum drop pairs to the equivalent double helix pairs using the process as described above is shown in FIG. 17F for Group 1.

As illustrated in FIG. 17H, the input data components (e.g. data units excluding the ripple droplets) of double helix pairs may be taken as a unit and rotated clockwise or counterclockwise by one or more positions or ninety degree increments. In the preferred embodiment, the double helix pairs as a unit are rotated counterclockwise.

Generally, there are four separate rotation states: zero degrees/no rotation/rotation through 360 degrees, 90 degrees, 180 degrees, and 270 degrees. After conversion, the double helix pair is initially in the zero degree rotation state, also referred to as “Spin 0.” A rotation of one position or ninety degrees is referred to as a ninety degree rotation state or “Spin 1.” A rotation of two positions or 180 degrees is referred to as a 180 degree rotation state or “Spin 2.” A rotation of three positions or 270 degrees is referred to as a 270 degree rotation state or “Spin 3.” For example, the Spin rotation states for a sequence of double helix pairs is illustrated in the table of FIG. 17H. For convenience, the double helix pairs of Group 1 and Group 2 are illustrated in Spin 0 and Spin 2 in FIGS. 17I-1 and 17I-2 respectively.

Referring again to FIG. 10, the double helix pairs, after formation in step 1041, are converted into odd and even pairing counts as illustrated by step 1043. The conversion of double helix pairs into odd and even summarized pairing counts for Group 1 is shown in FIG. 17J. The odd and even pairing counts for Group 1 is shown in Spin 0 rotation state. Other rotation states, however, may be used. Additionally, it should be noted that the first and last double helix pair have only the even or odd pairing satisfied in contrast to the remaining double helix pairs that have both the even and odd pairing satisfied.

The first and second double helix pairs, and the last and the second to the last double helix pairs are identified and stored as part of the Super Cooled set for Group 1. A portion of the final Super Cooled set for Group 1 therefore includes the information contained in FIG. 17J and is incorporated into the details shown in FIG. 4T.

As illustrated in FIG. 3, a final step 106 performed by the control unit 18 for the super cooling process for the first group is to derive a super cooled set for the first group, which represents a portion of the information within the original input stream in a different form containing positional information. In one embodiment, the super cooled set includes data indicative of the following elements for the first group: 1) the total number of droplets in the input stream, 2) the number of source pucks in the first group, 3) the number of reverse pucks in the first group, 4) the bubble scum puck for the first group, 5) the starting or first gum drop pair and the starting adjacent gum drop pairs in the bubble gum set for the first group, 6) the ending or last gum drop pair and ending adjacent gum drop pairs in the bubble gum set for the first group, 7) the odd and even gum drop pair types and counts 8) the adjacent gum drop pairs types and counts for the first group, 9) the inversion pucks (or duets) in the first group, 10) the padding droplets (after spray), 11) the odd and even pairing counts of the double helix pairs (for adjacent gum drop pairs) by type in Group 1, 12) the first and second double helix pairs by type in Group 1, and 13) the last and the second to the last double helix pairs by type in Group 1.

For example, shown in FIG. 4T is an exemplary super cooled set for the first group. (Note that element ten is not applicable in the exemplary super cooled set since the exemplary input stream from which it is derived did not have any padding droplets, and is denoted as such in FIG. 4T by a “N/A” for purposes of illustration. Also, the parenthetical references in FIG. 4T are only included for purposes of illustration and clarity.)

Second Group—Summarization and Formation of Super Cooled Set

In a similar manner as the first group, once the second group has been formed in the step 64, the control unit branches to a step 110 as shown in FIG. 3, wherein the source pucks and the reverse pucks in the second group are reordered to form an ordering referred to herein as a “second group bubble”. Similar to the step 82 discussed above for the first group bubble, to form the second group bubble in the step 110, the first source puck in the top segment of source pucks (or the bubble scum of the second group bubble) is followed by a plurality of pairings of each succeeding source puck in the top segment of source pucks with its corresponding precedential reverse puck in the reverse ordered, bottom segment of reverse pucks. These pairings are likewise referred to as duets, with the final pairings being inversion duets of the second group bubble. The set of duets, excluding the inversion duets, is likewise referred to as the bubble core of the second group bubble. Similarly, a pairing of adjacent pucks in adjacent duets in the bubble core of the second group bubble (one being a reverse puck from a preceding duet and one being a source puck from a succeeding duet) is likewise referred to herein by the term “inner pair,” or “gum drop pair” and the collective gum drop pairs of the second bubble group are referred to herein by the term “bubble gum set” for the second group. Again, the first and last puck in the bubble core will be unpaired and are not used to form a gum drop pair.

For example, shown in FIG. 4U is an exemplary second group bubble resulting from bubbling of the second group of FIG. 4O in a manner as discussed above, and shown in FIG. 4V is the bubble gum set comprising the gum drop pairs for the second group as determined from the second group bubble of FIG. 4U.

Once the second group bubble has been formed in the step 110, the control unit 18 branches to a summarization subroutine which is shown in FIG. 3 as a step 114. Once embodiment of the summarization subroutine 114 for the second group, which is similar to the summarization subroutine 98 discussed above for the first group, is shown in more detail in FIG. 11. In a first step 120 of the summarization subroutine 114, the gum drop pairs in the second group bubble are defined as an “odd” or “even” depending on the placement or order of the gum drop pair within the bubble gum set of the second group bubble. For example, also shown in FIG. 4V next to each gum drop pair is an odd/even assignment for purposes of illustration, wherein each of the odd gum drop pairs are identified by the character “o” next to the gum drop pair, and each of the even gum drop pairs are identified by the character “e” next to the gum drop pair.

In a step 122 of the summarization subroutine 114, the odd set of gum drop pairs are evaluated to determine how many gum drop pairs contain the same sequence of drops or symbols, and similarly, the even set of gum drop pairs are evaluated to determine how many gum drop pairs contain the same sequence of drops or symbols. For each unique sequence of drops contained within the odd and even gum drop pairs, which is also referred to herein as a “gum drop pair type” , a count value is assigned representing the number of gum drop pairs which contain that gum drop pair type in both the odd set of gum drop pairs and the even set of gum drop pairs for the second group. For example, shown in FIG. 4W is the odd set of gum drop pairs of FIG. 4V for the second group, and the unique gum drop pair types from the odd set with the count of gum drop pairs having that unique gum drop pair type. Below the odd set of gum drop pairs in FIG. 4W is the even set of gum drop pairs of FIG. 4V for the second group, and the unique gum drop pair types from the even set with the count of gum drop pairs having that unique gum drop pair type.

While the summarization subroutine 114 has been described above in one embodiment as defining the gum drop pairs as odd or even in step 120 and then determining gum drop pair types and counts for the odd and even set of gum drop pairs in step 122, it should be understood that the odd/even characterization of step 120 can be dropped and the gum drop pair types and counts determined for the collective set of gum drop pairs in step 122.

Similar to the summarization subroutine 98 discussed above for the first group, the summarization subroutine 114 for the second group in one embodiment includes a step 124 wherein adjacent gum drop pairs are formed from the gum drop pairs of the second group. Then once the adjacent gum drop pairs for the second group are formed, the control unit 18 branches to a step 126 wherein the set of adjacent gum drop pairs are evaluated to determine the adjacent gum drop pairs types and counts for the second group. For example, shown in FIG. 4X are the resulting fully and partially qualified adjacent gum drop pairs for the second group of FIG. 4V, and the corresponding adjacent gum drop pairs types and counts.

Similar to group 1, once the partially qualified adjacent gum drop pairs for group 2 are formed in the step 124, the control unit 18 may also branch to a step 1241 as shown in FIG. 11, wherein the set of adjacent gum drop pairs are converted into a double helix pair format using the methods previously described. For convenience, the conversion of the adjacent gum drop pairs to the equivalent double helix pairs using the process as described above is shown in FIG. 17G for Group 2. Additionally, the double helix pairs may be placed in a different spin format. For convenience, the double helix pairs of Group 2 are illustrated in Spin 0 and Spin 2 in FIGS. 17I-2.

Referring again to FIG. 11, the double helix pairs, after formation in step 1241, are converted into odd and even pairing counts as illustrated by step 1243. The conversion of double helix pairs into odd and even pairing counts for Group 2 is shown in FIG. 17K. The odd and even pairing counts for Group 2 is shown in Spin 0 rotation state. Other rotation states, however, may be used. Additionally, it should be noted that the first and last double helix pair have only the even or odd pairing satisfied in contrast to the remaining double helix pairs that have both the even and odd pairing satisfied.

The first and second double helix pairs, and the last and the second to the last double helix pairs are identified and stored as part of the Super Cooled set for Group 2. A portion of the final Super Cooled set for Group 2 includes the information contained in FIG. 17K.

As shown in FIG. 3, a final step 128 performed by the control unit 18 for the super cooling process for the second group is to derive a super cooled set for the second group, which represents a portion of the information within the original input stream in a different form, containing positional information, in a similar manner as discussed above in step 106 for the first group. In one embodiment, the super cooled set includes data indicative of the following elements for the second group: 1) the total number of droplets in the input stream, 2) the number of source pucks in the second group, 3) the number of reverse pucks in the second group, 4) the bubble scum puck for the second group, 5) the starting or first gum drop pair and the starting adjacent gum drop pairs in the bubble gum set for the second group, 6) the ending or last gum drop pair and the ending adjacent gum drop pairs in the bubble gum set for the second group, 7) the odd and even gum drop pair types and counts for the second group, 8) the adjacent gum drop pairs types and counts for the second group, 9) the inversion pucks (or duets) in the second group, 10) the padding droplets (after spray), 11) the odd and even pairing counts of the double helix pairs (for adjacent gum drop pairs) by type for Group 2, 12) the first and the second double helix pairs by type for Group 2, and 13) the last and the second to the last double helix pairs by type for Group 2.

For example, shown in FIG. 4Y is a super cooled set for the second group. (Note that element ten is not applicable in the exemplary super cooled set since the exemplary input stream from which it is derived did not have any padding droplets, and is denoted as such by a “N/A” for purposes of illustration. Also, the parenthetical references in FIG. 4Y are only included for purposes of illustration and clarity.)

It should be understood that while the super cooled sets for the first and second groups have been described herein in one embodiment as including thirteen elements each, elements within the super cooled set for the first group and for the second group (taken individually or in combination) which lend themselves to being repetitive, redundant, or otherwise unnecessary can be omitted accordingly (however redundancy can be beneficial, such as for example for checking validity or to ensure structural consistency between super cooled sets). For example, since the number of droplets in the input stream is already provided in the super cooled set for the first group, it may be omitted from the second group. Further, elements that lend themselves to being derived from one or more other elements can likewise be omitted accordingly since such information can be obtained indirectly form the other elements. Further, while the super cooling process has been discussed in terms of generating a super cooled set for the first group and a super cooled set for the second group, it should be understood that the elements thereof may be combined together and provided in a common super cooled set in accordance with the present invention.

Once the super cooled sets are determined for the first group and second group in the steps 106 and 128, respectively, the control unit 18 of the transmitter 12 outputs the super cooled sets such that the super cooled sets can be utilized (e.g. transmitted and/or stored). In one embodiment, as shown in FIG. 1, the super cooled sets are outputted by the transmitter 12 and passed to the receiver 14 via link 16 such that the receiver 14 may perform the super heating process on the super cooled sets to reconstruct the input stream represented thereby.

Even though the double helix pairings are described with adjacent gum drop pairs as the basis, one skilled in the art will readily realize that double helix pairs may also be derived with gum drop pairs as the basis in a similar manner, in order to obtain the same end result in reproducing the original input stream as part of the super heating process.

Open Box Mode and Lock Box Mode

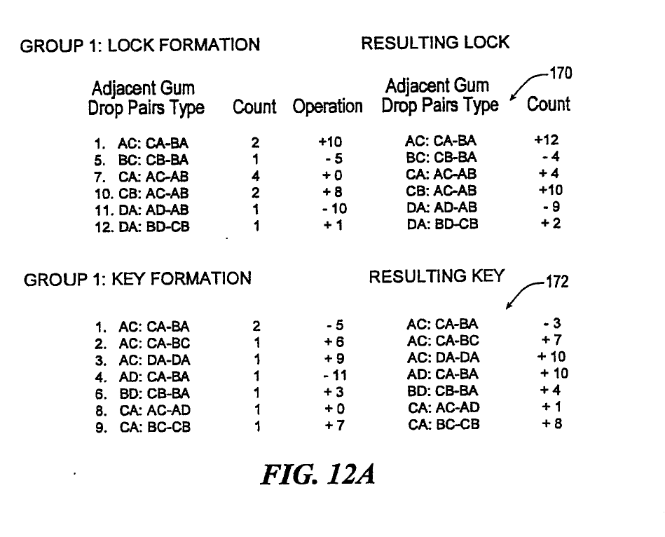

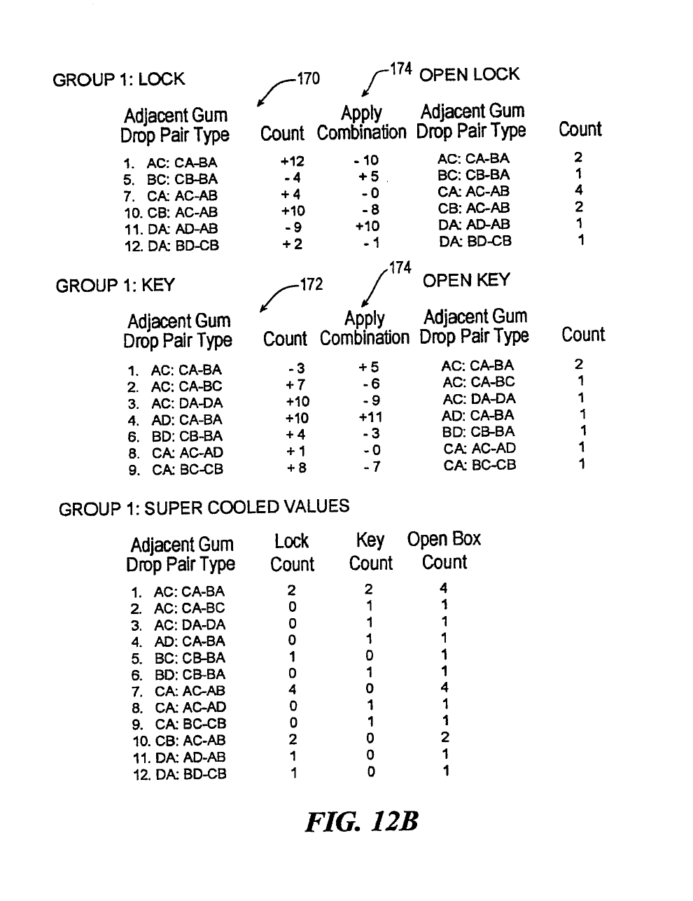

The super cooled sets of the present invention can be outputted in its whole form, which the Applicant refers to herein as being in an “open box mode” representation of the input stream. This is the preferred mode of representing the input stream when the information within the input stream is not sensitive to confidentiality or in the public domain. However, in instances where information is of a confidential or sensitive nature, each of the super cooled sets is “encrypted” by a method referred to herein by the Applicant by the term “lock box mode.” Because the lock box mode can be applied similarly to any super cooled set, only the super cooled set for the first group is discussed in further detail with reference to FIGS. 12A-12B for purposes of brevity and clarity.

The lock box mode consists of a “lock” component 170, a “key” component 172 and a “combination” component 174, that when combined, provides the super cooled set in the open box mode. To “lock” the super cooled set so as put the super cooled set in the lock box mode, at least a portion of the super cooled set for the first group is divided into two parts, one of which is used for forming the lock component 170 and one of which is used for forming the key component 172. In one embodiment, the adjacent gum drop pair types and counts of the super cooled set is the portion of the super cooled set which is divided into the two parts, as shown for example in FIG. 12A. The division of the adjacent gum drop pairs types and counts can be done in any manner, but are preferably divided so as to maximize bandwidth efficiency. A predetermined mathematical operation is then applied to the counts in each part, which results in the lock component 170 and the key component 172. In one embodiment, as shown for example in FIG. 12A, the mathematical operations are predetermined numbers which are added to or subtracted from the adjacent gum drop pair counts.

The combination component 174 of the lock box mode is the reverse of the mathematical operations applied to form the lock component 170 and key component 172. Therefore, it can be seen that to transform the super cooled set from the lock box mode to the open box mode, the combination component 174 (which reverses the mathematical operation for each adjacent gum drop pair count) is applied to the lock component 170 and to the key component 172. The resulting adjacent gum drop pair counts in the lock component 170 are then combined to the resulting adjacent gum drop pairs counts in the key component 172 to obtain the full counts for the adjacent gum drop pairs of the super cooled set for the first group. For example, shown in FIG. 12B is the combination component 174 being applied to the lock component 170 and key component 172 of FIG. 12A, and the resulting super cooled set in the open box mode after the resulting adjacent gum drop pairs of the lock component 170 and the key component 172 have been combined.

In the lock box mode, the lock component 170, the key component 172, and the combination component 174 are preferably transmitted and/or stored apart so that there is no indication of the input stream being represented by the super cooled set until the lock, key and combination components 170, 172 and 174 are combined to derive the super cooled set in the open box mode. Further encryption can result from the use of multiple lock components 170, key components 172, and/or combination components 174.

While the present invention is described in one embodiment as encrypting the super cooled input stream set using the lock box mode for transmission and storage, it should be understood that the present invention contemplates that any encryption technique known in the art or later developed can be utilized during the transmission and/or storage of the super cooled input stream set in accordance with the present invention. Further, while only the adjacent gum drop pair counts have been discussed and shown by way of illustration as being modified in the lock box mode, it should be understood that the present invention contemplates that other information contained within the super cooled set can also be modified in the lock box mode. One skilled in the art will readily see that the concept of the “lock box” method described in relation to the adjacent gum drop pair types and counts can be extended to the double helix pairs pairing types and counts and therefore not discussed further.

It should be pointed out that the encoding technique containing positional information of the present invention discussed herein is really a summation process. Counts for each entity defined is in the form similar to the number system used in every day life where counts are expressed in the units ones, tens, hundreds, thousands, etc., to represent the number of objects. This is normally recognized to be a “geometric” representation of the object counts. Therefore by inference, it should be pointed out that this method of summation leads to a “geometric” encoding of information with positional information implicit in it.

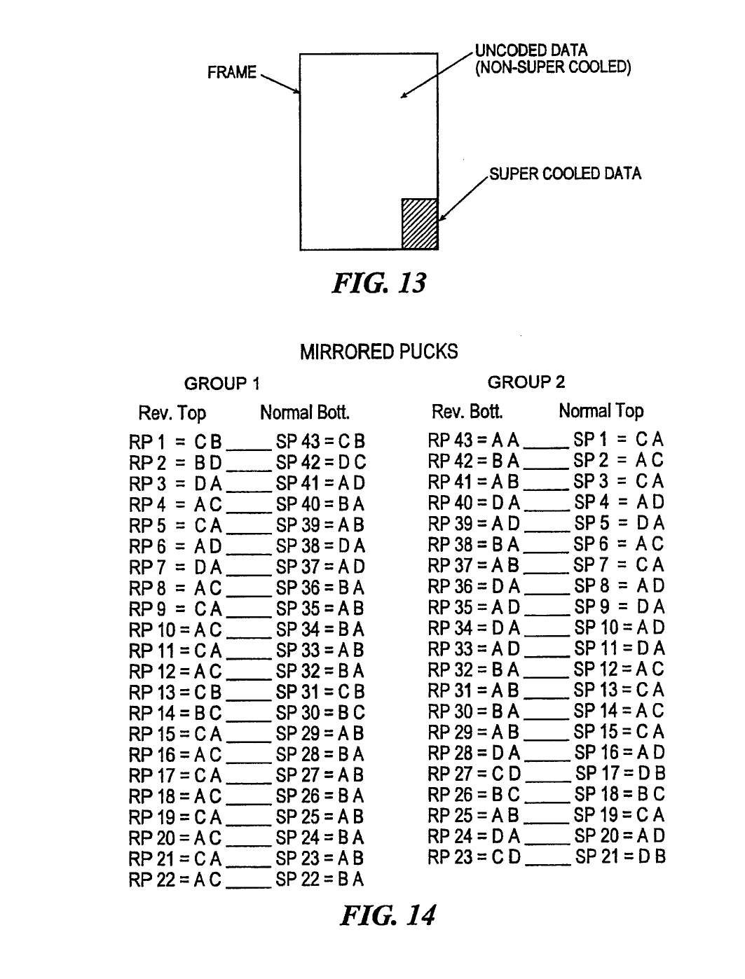

Due to the summarization technique of the super cooling process, the present invention allows for information to be present in the encoded and un-coded formats within a frame or fixed memory space (e.g., one megabyte of storage). Along with the un-coded data in this frame, the super cooled sets may represent the en-coded and summarized data in some other frame, as shown for example in FIG. 13. Generally, the super cooled sets will represent the en-coded data in some other frame. Repeated super cooling of data in a frame comprising the super cooled set from the previous or last cycle performed and the non-super cooled data in the current frame (which is new data) is referred to herein by the Applicant by the term “super freezing”. This process can be repeated ad-infinitum to obtain a final super frozen set consisting of the first group and second group super frozen sets (which is the same as a super cooled set for the final frame) from which all the frames can be derived. In essence, what is accomplished is geometric encoding of geometrically compressed information leading to infinite compression.

In addition to the various processes described above, Applicant further presents two other phenomena observed in relation to the super cooling process of the present invention. First, it should be noted that a special case arises in step 32 of the super cooling process if the rippled input stream is rotated to the right in the formation of the source stream, and the duplicate rippled stream is rotated to the left in the formation of the reverse stream, by N positions (rather than N+1 positions). In this case, the source and reverse pucks lose their precedence relationship and exhibit a “mirrored” relationship when they are divided into the first group and second group in step 64, wherein the source pucks and reverse pucks in the same position in the side-by-side comparison are evenly matched (with one exception in the second group: RP 43=AA and SP1=CA). Pucks that are in the same position and exhibiting the mirrored relationship are referred to herein by the Applicant as “twins”.

For example, shown in FIG. 14 is the resulting first group and the second group when the exemplary rippled input stream of FIG. 4C is rotated to the right by N droplet positions and the exemplary duplicate rippled stream (which is a duplicate of the rippled input stream of FIG. 4B) is rotated to the left N droplet positions. The mirrored relationships are indicated by a horizontal line drawn between the reverse pucks and source pucks in FIG. 14 for purposes of illustration.

With regard to the second observation, it was discussed above in reference to the super cooling process that the source pucks and the reverse pucks have a precedential reverse relationship when the top half of the source pucks is compared side-by-side to the bottom half of the reverse pucks taken in reverse order, and the top half of the series of reverse pucks is compared side-by-side to the bottom half of the source pucks taken in reverse order. The precedential reverse relationship arises in that substantially each reverse puck in the top half of reverse pucks has a value which is the reverse of the value of a source puck located in a preceding position in the reverse ordered, bottom half of source pucks; and substantially each source puck in the top half of source pucks has a value which is the reverse of the value of a reverse puck in the top half of reverse pucks. By taking the duets, which are the pairs of reverse pucks and source pucks having the precedential reverse relationship, it can be seen that the duets have a double helix arrangement, similar to that seen in DNA.

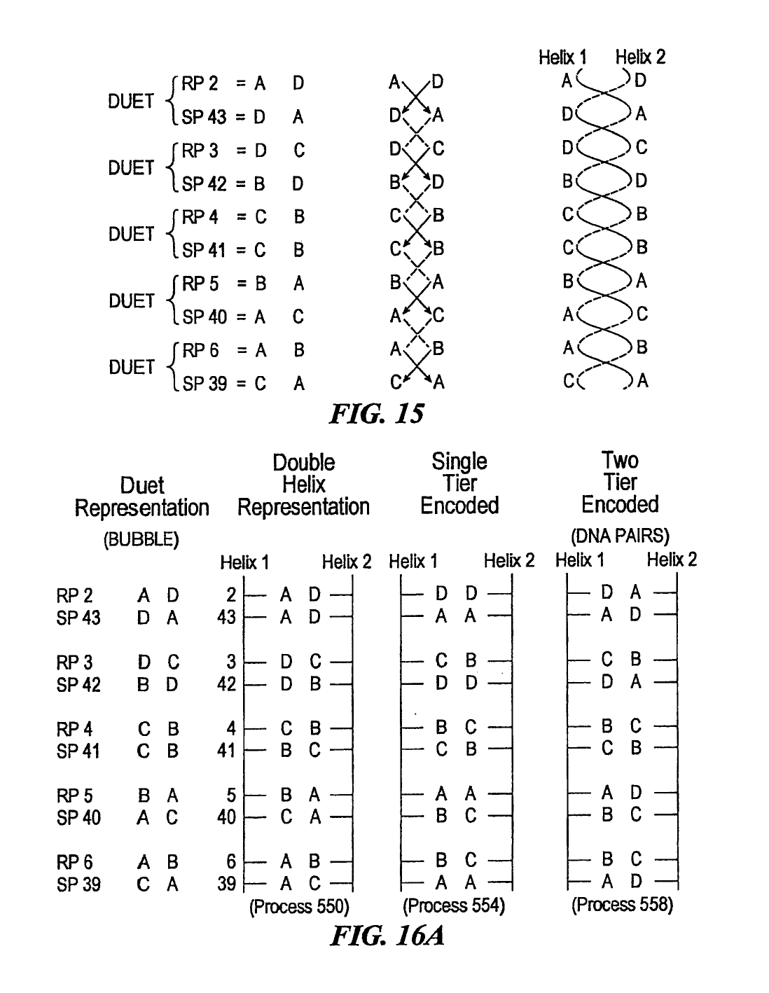

For example, shown in FIG. 15 is a subset of duets taken from the exemplary bubble core of duets of FIG. 4P for the first group. Next to the subset of duets are two representations of the subset. In the leftmost representation of the subset, the reverse relationship between drops of the duets are shown by arrows drawn therebetween. The non-relationships (as between adjacent duets) are shown by the dotted lines drawn therebetween. If the arrows and the dotted lines are taken to be part of the same line, they result in a double helix, as shown in the rightmost representation of the subset. Applicant believes this phenomenon explains how the double helix nature of the DNA structure comes about.

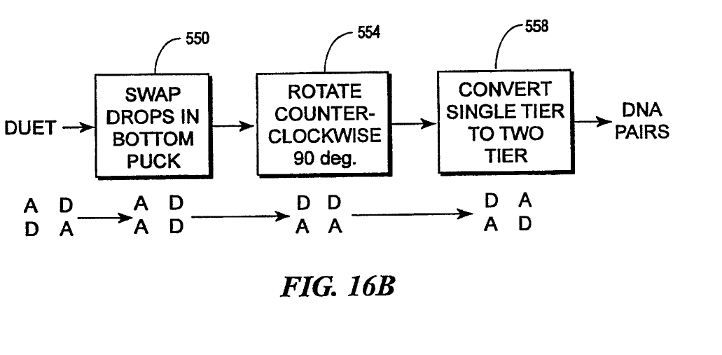

It is Applicant's belief that the bubble groups of the super cooling process of the present invention is the same as DNA, but in a slightly different mold. To see how the arrangement of drops from the exemplary subset of duets of FIG. 15 relates to the double helix arrangement of DNA, a transformation process is applied to the subset of duets, as shown in FIGS. 16A-16B and as discussed further below. The Applicant believes that the reason for this modification is the nature of replication associated with DNA. The rightmost structure of FIG. 15 does not lend itself to easy replication.

Shown in FIG. 16A is the subset of duets in the different stages of the transformation process, as will be discussed further below with reference to FIG. 16B. In FIG. 16A, the subset of duets is shown first. Shown next thereto is a representation of a first double helix structure (as indicated by the vertical and horizontal lines) for the subset of duets after the first step of the transformation (labeled as process 550) is applied. Then shown is a second double helix structure using a single tier encoded representation of the subset of duets using the first helix and resulting in the second helix structure from the next step of the transformation process (labeled as process 554), followed by a two tier encoded DNA representation with the first helix and the second helix resulting from the last step of the transformation process (labeled as process 558).

Note that the letters “A”, “B”, “C”, and “D” are used in the DNA representation here. They map to the common DNA sequence letters “A”, “C”, “G”, and “T” although not necessarily on a one-to-one basis.

The transformation process applied to the subset of duets is shown in a general flow diagram in FIG. 16B, with an example shown below wherein the first duet of the subset of duets is shown during each step of the transformation process for purposes of illustration. From the illustration of the transformation process for the first duet, one skilled in the art will understand how to apply the transformation process to the other duets.

As shown in FIG. 16B, in a step 550 of the transformation process, the drops in the bottom or second puck in the duet are swapped or reversed in order. For example, as shown in FIG. 16B for the first duet, the bottom puck is the source puck DA. After swapping the drops in the bottom puck, the bottom puck of the duet now has a value of AD (as also shown in FIG. 16A). In a step 554, the set of four drops in the duet at this point are then rotated counter-clockwise by one position or ninety degrees. For example, as shown in FIG. 16B, the result of rotating the set of four drops in the duet is a top “puck” with a value DD and a bottom “puck” with a value M (as also shown in FIG. 16A). In a step 558, the drops at this point are then converted from single tier encoding to two-tier encoding. For example, as shown in FIG. 16B, the result of converting the drops from single tier encoding to two-tier encoding is a top “puck” with a value DA and a bottom “puck” with a value AD (as also shown in FIG. 16A). Each of the resulting “pucks” of the transformation process is referred to herein by the Applicant as a “DNA pair”.

Thus, it can be seen that the reverse of the transformation process applied to two adjacent DNA pairs yields the duets of the bubble core. In other words, by taking two adjacent DNA pairs, converting the DNA pairs to single tier encoding, rotating the DNA pair values clockwise by ninety degrees, and reversing the order of the bottom pair, the duet values result and can be subsequently decoded into an ordered binary stream by reversing the steps recited above for encoding the ordered binary stream into the DNA pair values. Therefore, Applicant believes that one application of the present invention is its use in converting the double helix structure of DNA into a binary sequence so as to retrieve a data stream in the form of 0's and 1's which represents the information contained in the DNA structure.

Further, the Applicant believes that if the DNA sequence has strictly sequenced information and their summarized values are to be found in the stem cell set, then transforming the DNA to a binary sequence of values and super cooling it would yield information that closely corresponds to those facets of the stem cell set which are represented in the DNA. From this established correspondence, it should be possible to derive the binary sequence of those features of the stem cell set which are not represented in the DNA, such as those needed for the regeneration of most organs.

2. Super Heating Process

As discussed above, the super heating process of the present invention re-expands and decodes (“decompress”) the data which was “compressed” via the super cooling process. Generally, the super heating process expands and re-orders the information contained within super cooled sets resulting from the super cooling process to produce at least one reconstructed ordered source stream or at least one reconstructed reverse stream. The original input stream in its original order may then be provided by the reconstructed ordered source stream and/or the reconstructed reverse stream. The process of expanding the super cooled set having little or no ordering information and reconstructing the original input stream in its original order is also referred to herein by Applicant by the term “devolution.”

It should be understood that generally it is only necessary to devolve the super cooled sets to reconstruct either the source stream or the reverse stream, as both the source stream and the reverse stream represent the same input stream. As such, only devolution of the super cooled sets to reconstruct the source stream is discussed in further detail herein below as one skilled in the art will be able to devolve the super cooled sets to reconstruct the reverse stream based on the examples provided below.

Referring now to FIG. 18, the operation of the control unit 218 of the receiver 14 to perform the super heating process will now be described. At a step 250, the control unit 218 of the receiver 14 receives and/or reads super cooled sets for group 1 and group 2 formed by the super cooling process described herein. The super cooled sets may be in any form such as lock box mode, open box mode, and/or the like. For example, if the super cooled sets are in lock box mode, the control unit 218 receives the lock component 170, the key component 172, and the combination component 174 in the manner described herein.

As illustrated in FIG. 18, if the control unit 218 receives the super cooled sets in lock box mode, the additional step of unlocking 252 is included within the process. In the unlocking step, the combination component 174 is applied to the lock component 170. The key component 174 may then be combined to retrieve the values of super cooled sets for group 1 and group 2 providing both in open box mode. As one skilled in the art will appreciate, if the super cooled sets are received by the receiver 14 in open box mode, then the step 252 may be omitted.

Once the super cooled sets for group 1 and group 2 are received in an unlocked mode, the control unit 218 begins a devolving subroutine. In the devolving subroutine, source pucks are devolved from the unlocked super cooled sets as shown by step 258. Generally, within the devolving subroutine 258, the group 2 source pucks and the group 1 source pucks are devolved from the super cooled set. The combination of the group 2 source pucks (e.g. the top segment of the source pucks), the group 1 source pucks (e.g. the bottom segment of the source pucks), and the inversion pucks provides reconstruction of the series of sources pucks.

For clarity and conciseness, the following devolution process uses adjacent gum drop pairs and their associated double helix pairs. It should be noted that the process may be extended to all gum drop pairs and their associated double helix pairs. Generally, for the devolution process to use adjacent gum drop pairs, at least two consecutive adjacent gum drop pairs must be known. The first known adjacent gum drop pairs is referred to as a reference adjacent gum drop pairs. Initially, the first two known adjacent gum drop pairs are provided as first and second double helix pairs in the super cooled set's first pairing.

During devolution of the source pucks shown by step 258 in FIG. 18, source pucks from the adjacent gum drop pairs of the super cooled set are removed and provided in a reconstructed series. For example, each source puck is generally retrieved by finding the gum drop pair in the first adjacent gum drop that contains the corresponding source puck. This source puck is then provided to the reconstructed series of source pucks. If the subsequent adjacent gum drop pairs is a known value, then the first adjacent gum drop pairs, from which the source puck was devolved, will be removed from the super cooled set. At this point, the value of that gum drop pair within the super cooled set is reduced by 1. Additionally, the associated double helix pairs pairing count is reduced by 1. This process of removing the source puck from its corresponding adjacent gum drop pairs and providing the source puck to a reconstructed series of source pucks is referred to herein by the Applicant by the term “emitting” or derivations thereof.

For clarity and conciseness, the following description of the devolving subroutine 258 is generally discussed herein by first analyzing the super cooled set for the second group (e.g. top segment of source pucks) and then analyzing the super cooled set for the first group (e.g. bottom segment of source pucks). It should be understood, however, that the super cooled sets may be analyzed in any order and/or simultaneously.

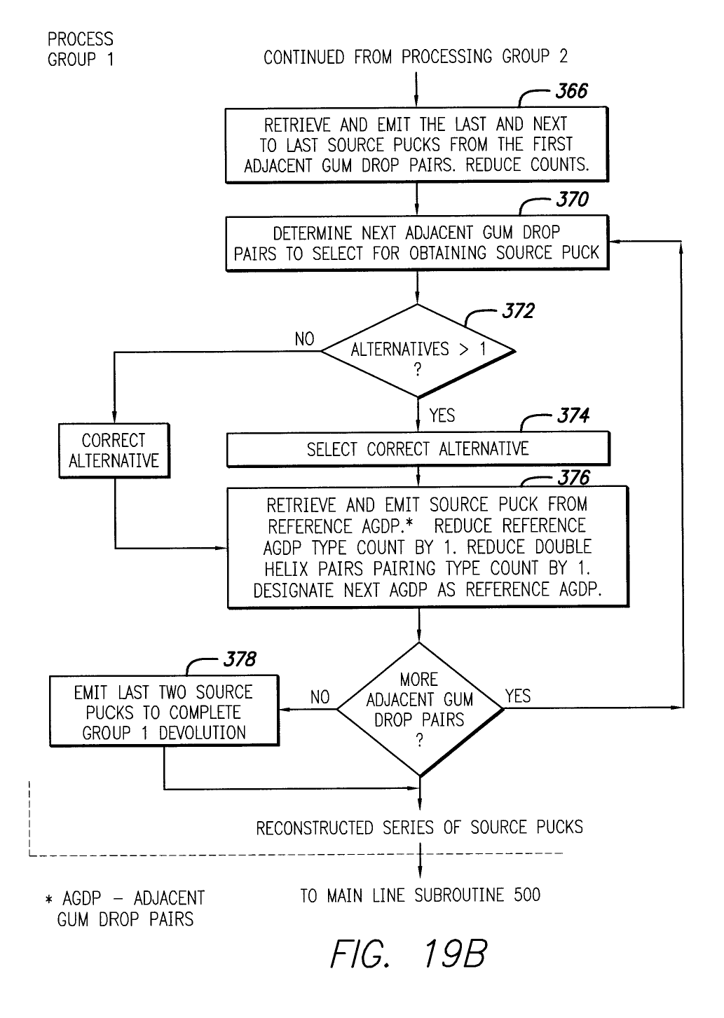

The devolving subroutine 258 is illustrated in further detail in FIGS. 19A and 19B. In a step 262 of the devolving subroutine 258, the bubble scum puck of the second group is determined and placed as the first source puck in the reconstructed series of source pucks. For example, the super cooled set for the second group shown in FIG. 4Y indicates that the bubble scum puck is represented as [BA]. Thus, the bubble scum puck [BA] becomes the first source puck (SP1) in the reconstructed series of source pucks as shown in FIG. 4Z. The reconstructed series of source pucks uses identifier “SPx” for purposes of illustration and clarity of understanding.

Referring again to FIG. 19A, in a step 266, the starting adjacent gum drop pairs is used to provide the second, third, and fourth source pucks for the reconstructed series of source pucks. The second source puck in the reconstructed series of source pucks is generally the reverse of the left drop pair of the left gum drop pair of the starting adjacent gum drop pairs. As illustrated in FIG. 4Y, the starting adjacent gum drop pairs is represented as [CA-BA*AC-AB]. The left gum drop pair of the starting adjacent gum drop pairs is thus represented as [CA-BA]. As such, the left drop pair of this is [CA] (i.e. in droplet form 1000). The reverse of the left drop pair of the left gum drop pair provides the second source puck. The reverse of [CA] in droplet form is [0001]. As such, the reverse of the left drop pair [CA] is [AB] (i.e. in droplet form 0001). The reverse left drop pair [AB] is thus the second source puck (SP2) in the reconstructed series of source pucks as shown in FIG. 4Z.

The third source puck in the reconstructed series of source pucks is generally the reverse of the left drop pair of the right gum drop pair of the starting adjacent gum drop pairs. For example, in the super cooled set shown in FIG. 4Y the starting adjacent gum drop pairs are represented as [CA-BA*AC-AB]. The right gum drop pair of the starting adjacent gum drop pairs are thus represented as [AC-AB]. As such, the left drop pair of the right gum drop pair of the starting adjacent gum drop pairs is [AC] (i.e. in droplet form 0010). The reverse of [AC] in droplet form is [0100]. As such, the reverse of the left drop pair [AC] is [BA] (i.e. in droplet form 0100). The reverse of the left drop pair [BA] is thus the third source puck (SP3) in the reconstructed series of source pucks as shown in FIG. 4Z.

The fourth source puck in the reconstructed series of source pucks is generally the right drop pair of the right gum drop pair of the starting adjacent gum drop pairs. For example, in the super cooled set shown in FIG. 4Y the starting adjacent gum drop pairs is represented as [CA-BA*AC-AB]. The right gum drop pair of the starting adjacent gum drop pairs is thus represented as [AC-AB]. As such, the right drop pair [AB] is the fourth source puck (SP4) in the reconstructed series of source pucks as shown in FIG. 4Z.

The double helix pairs pairing generally defines the pairing between consecutive adjacent gum drop pairs. Since the first and second double helix pairs are already identified in the super cooled set, the second adjacent gum drop pairs is known. As previously described, since the second adjacent gum drop pairs is known, the first adjacent gum drop pairs can be removed from the super cooled set and the type count corresponding to the first adjacent gum drop pairs reduced by one in the super cooled second group set. Also, the first double helix pairs pairing count is reduced by one and the second adjacent gum drop pairs is now designated as the reference adjacent gum drop pairs for the remaining super cooled set of the second group.

In order to obtain the remaining source pucks for the reconstructed series of source pucks for the second group, individual adjacent gum drop pairs are analyzed beginning with the third adjacent gum drop pairs. The determination as to the adjacent gum drop pairs following the reference adjacent gum drop pairs is made in a step 270 of the devolving subroutine 258 shown in FIG. 19A

To devolve the remaining source pucks included in the super cooled set for the second group, at most two alternatives are possible as being the next (third) adjacent gum drop pairs.

The next source puck to be emitted is available in the currently designated reference adjacent gum drop pairs but it is deferred until the adjacent gum drop pairs following the reference adjacent gum drop pairs is determined. Specifically, the current reference adjacent gum drop pairs [AC-AB*CA-BC] provides direct information regarding the left gum drop pair and the left drop pair of the right gum drop pair of the next adjacent gum drop pairs as discussed in further detail below.

Generally, the right gum drop pair of the reference adjacent gum drop pairs is the same as the left gum drop pair of the next adjacent gum drop pairs. As such, the left gum drop pair of the next adjacent gum drop pair is [CA-BC].

Additionally, the reverse of the right drop pair of the left gum drop pair of the next adjacent gum drop pairs is the left drop pair of the right gum drop pair of the next adjacent gum drop pairs due to the reverse relationship between adjacently disposed gum drop pairs previously discussed above. In this example, the right drop pair of the left gum drop pair is [BC] (i.e. 0110 in droplet form). The reverse of [BC] is [BC] (i.e. 0110 in droplet form). As such, the left drop pair of the right gum drop pair of the next adjacent gum drop pairs is [BC].

Therefore three of the four components of the next (third in sequence) adjacent gum drop pairs are identified as [CA-BC*BC]. By analyzing the remaining adjacent gum drop pairs in the super cooled set as illustrated in FIG. 4Y, there are two entries in which the first three components are [CA-BC*BC]. Specifically, the two entries are [CA-BC*BC-CB] having a count of two and [CA-BC*BC-CD] having a count of one. In a selection step 274, one of the two alternatives is determined as the correct next (third in sequence) adjacent gum drop pairs to be used for retrieving the next source puck for the reconstructed series of source pucks of FIG. 4Z.

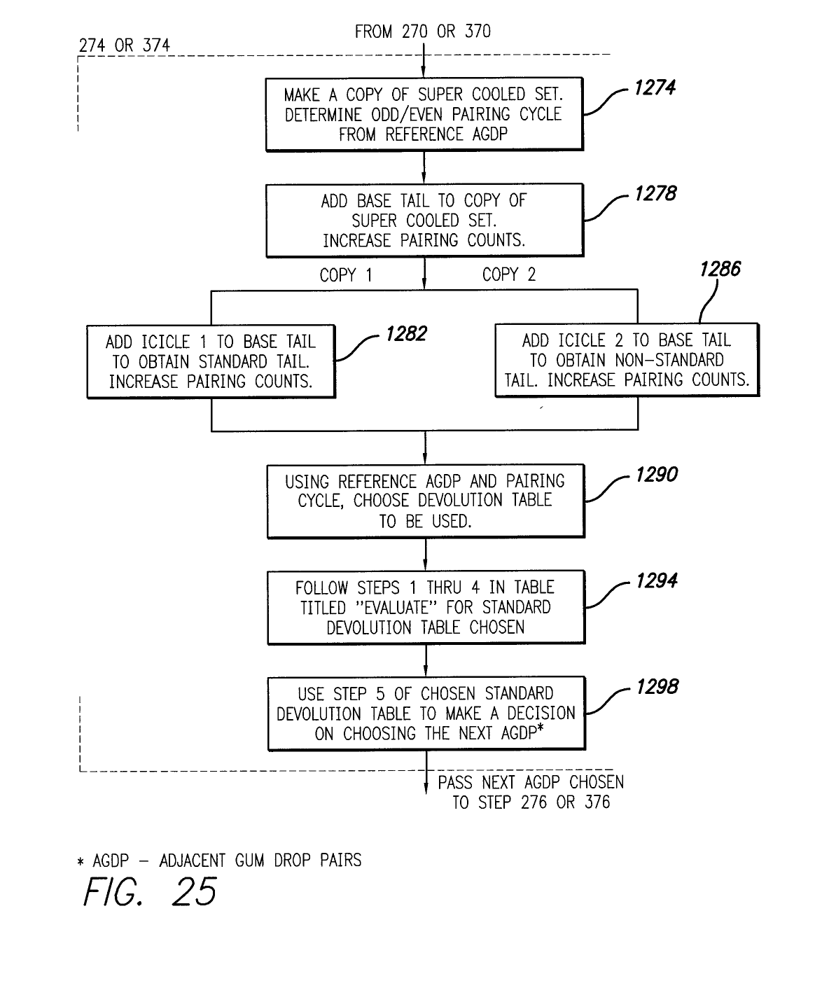

The selection between one of the two alternatives pairing with the reference adjacent gum drop pairs is shown as step 274 for group 2 and as step 374 for group 1. The steps for selecting between one of the two alternatives is similar for groups 1 and 2 and are shown in a combined flow chart of FIG. 25.

Before proceeding to describe the steps gone through in the selection process, it is necessary to explain the concept of “loops,” “tails” and “Standard Devolution Tables.”

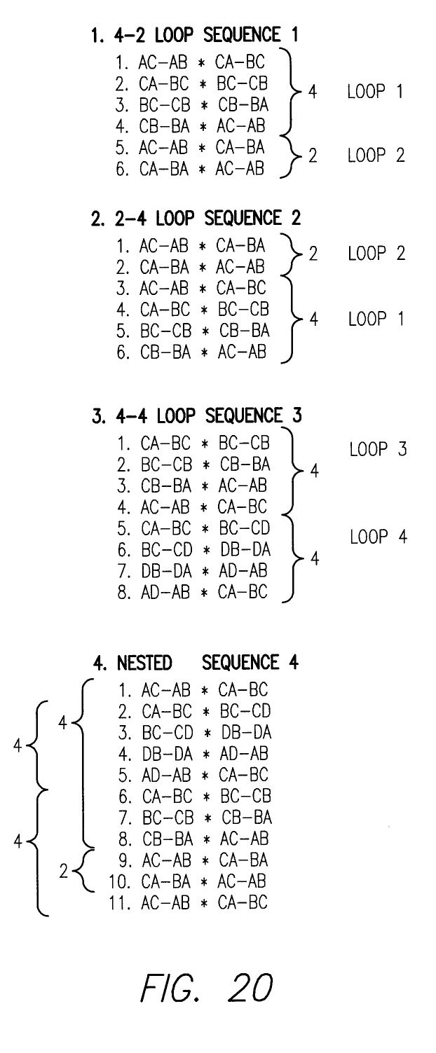

The concept of a loop is best explained by FIG. 20. It shows four sets of adjacent gum drop pairs referred to as sequence 1, sequence 2, sequence 3 and sequence 4. The term “loop” is generally used when the left most gum drop pairs of the first adjacent gum drop pairs in a sequence of adjacent gum drop pairs is the same as the right most gum drop pairs of the last adjacent gumdrop pairs in the sequence.

In FIG. 20, primarily two types of loops are shown—a loop containing four elements and a loop containing two elements wherein the elements are adjacent gum drop pairs. For example, sequence 1 consists of a four element loop followed by a two element loop. Sequence 2 consists of a two element loop followed by a four element loop. Sequence 3 consists of two separate four element loops. Sequence 4 consists of loops in a nested arrangement in which the entire sequence itself is not a loop. It should be pointed out that the nested arrangement is generally the manner in which the majority of adjacent gum drop pair sequences occur.

FIG. 20 also illustrates what might be termed as “elemental loops”. Elemental loops are the smallest set of adjacent gum drop pairs which contain an adjacent gum drop pairs forming a loop. For instance loops 1, 2, 3 and 4 are elemental loops. Every adjacent gum drop pairs belongs in an elemental loop because of the precedence relationship requirement.

Tails are adjacent gum drop pair sequences which are appended to a set of adjacent gum drop pairs which aid in the devolution process.

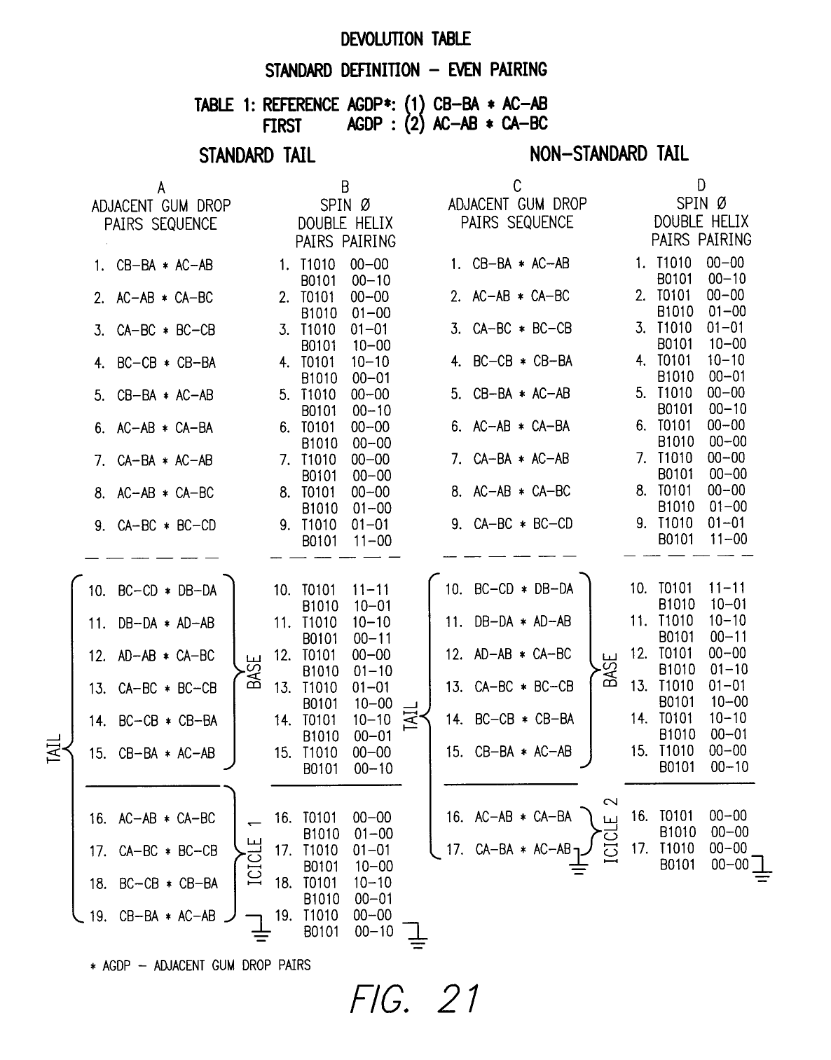

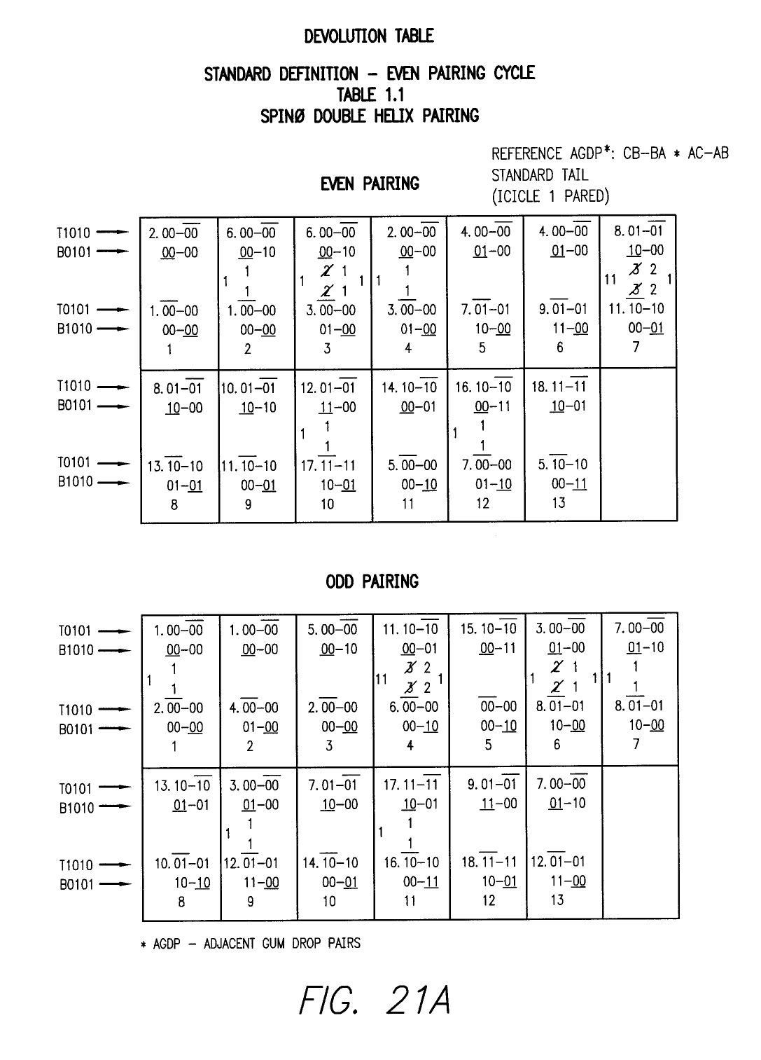

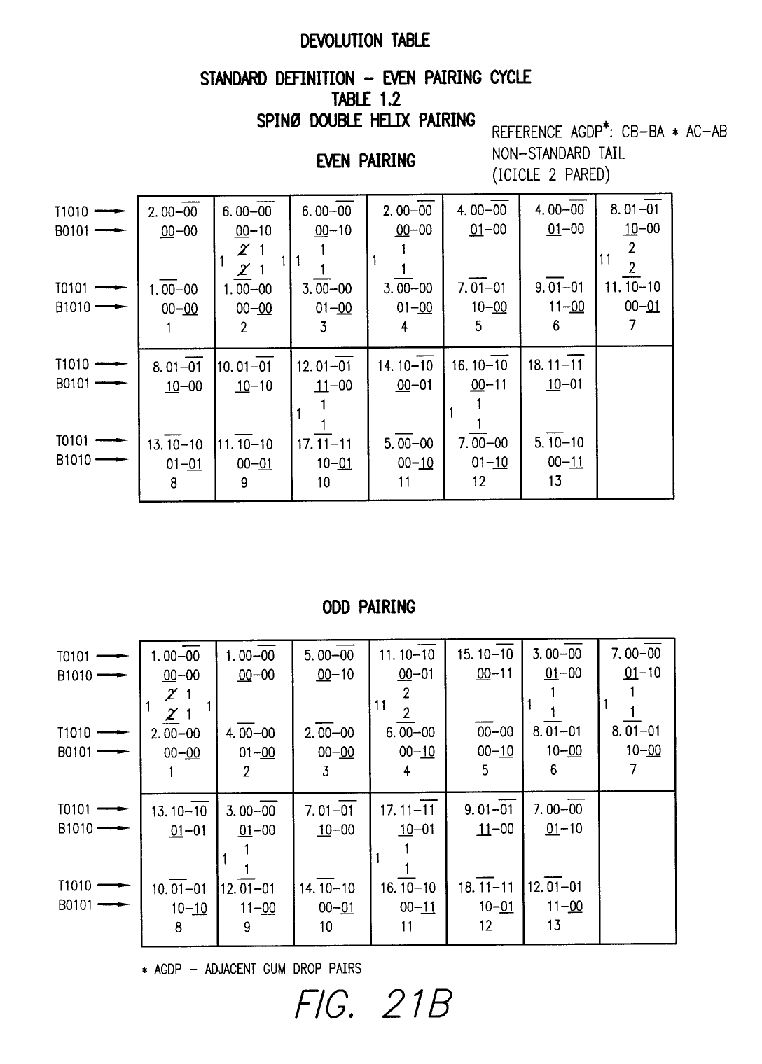

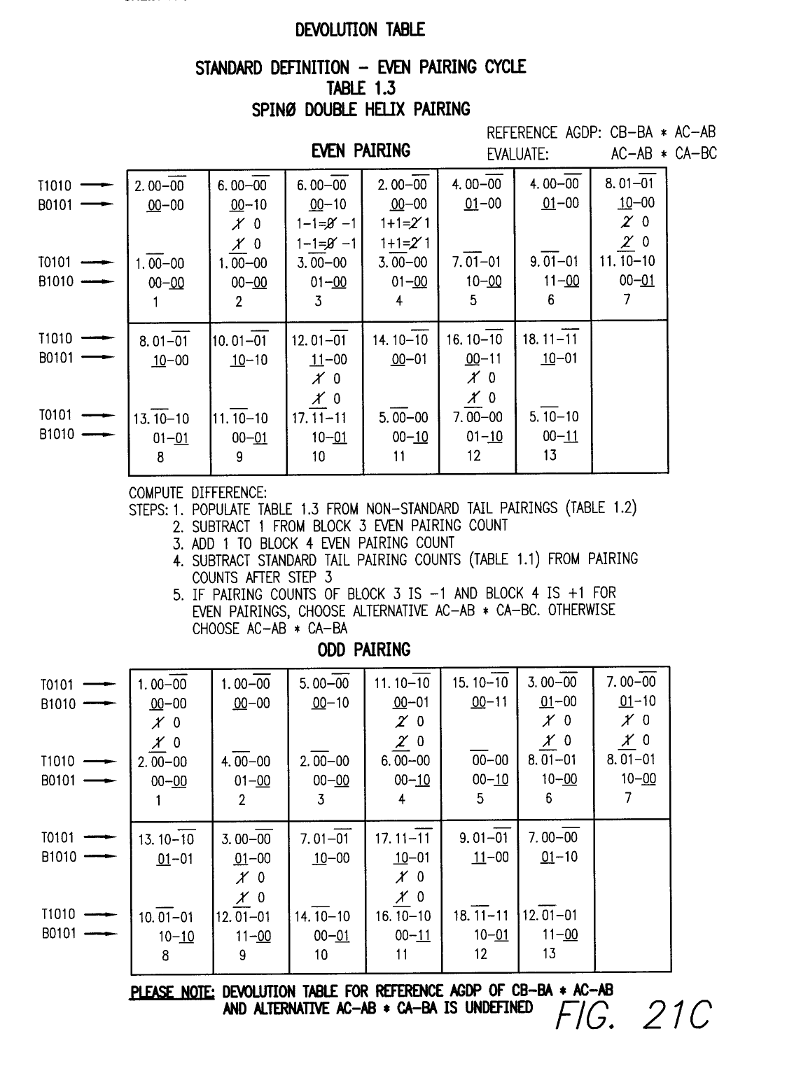

Tails consist of two parts—a “base” part and an “Icicle” part. When a base part of the tail is added, the last adjacent gum drop pairs in the sequence is the same as the first adjacent gum drop pairs (also referred to as the “reference adjacent gum drop pairs”) which is known. Referring to FIG. 21, the first adjacent gum drop pairs is shown as CB-BA*AC-AB. When the Base tail (items numbered 10 thru 15) is added to the adjacent gum drop pairs set (items numbered 1 thru 9) the last adjacent gum drop pairs (item 15: CB-BA*AC-AB) of the combined set is the same as the first. This whole set is referred to as the “Base Line set”.

Icicles are elemental loops added at the end of base tails. Each of the alternative adjacent gum drop pairs is contained in an elemental loop, distinct from each other. By definition, the elemental loop whose last adjacent gum drop pairs is the same as the reference adjacent gum drop pairs is referred to as Icicle 1. The elemental loop whose last adjacent gum drop pairs is not the same as the reference adjacent gum drop pairs is by definition referred to as Icicle 2. The tail containing Icicle 1 is referred to as the “Standard Tail” and tail containing Icicle 2 is referred to as the “Non-standard Tail.” Referring again to FIG. 21, in column A, items 16 thru 19 are labeled Icicle 1 since the last adjacent gum drop pairs of this elemental loop (item 19: CB-BA*AC-AB) is the same as the reference adjacent gum drop pairs (item 1: CB-BA*AC-AB). In column C, items 16 and 17 are labeled as Icicle 2 since the last adjacent gum drop pairs (item 17: CA-BA*AC-AB) is not the same as the reference adjacent gum drop pairs (item 1: CB-BA*AC-AB).

Standard devolution tables outline steps to be gone through in evaluating which alternative to pick during devolution. Standard devolution tables are constructed for a specific reference adjacent gum drop pairs. These tables may be constructed in various ways. For instance, even though the determination of the correct alternative is shown in terms of pairing between consecutive double helix pairs, it could have been done just as well using pairing between adjacent gum drop pairs. The applicant believes that the method chosen enhances clarity of understanding. One such example is provided in FIGS. 21, 21A, 21B and 21C for the reference adjacent gum drop pairs: CB-BA*AC-AB. Further in a standard devolution table, the adjacent gum drop pairs following the reference adjacent gum drop pairs has to belong to the same elemental loop. For example in FIG. 21, the reference adjacent gum drop pairs is shown as CB-BA*AC-AB (item 1) and the adjacent gum drop pairs following is shown as AC-AB*CA-BC (item 2). Items 1 and 2 both belong to the same elemental loop (refer to Loop 1 of FIG. 20).

Standard devolution tables are undefined when the reference adjacent gum drop pairs and the one following it belong to two different elemental loops. For instance, no standard devolution table is defined if the reference adjacent gum drop pairs is CB-BA*AC-AB and the one following it is AC-AB*CA-BA. Referring to the 4-2 loop sequence 1 of FIG. 20, CB-BA*AC-AB is part of elemental loop 1 where as AC-AB*CA-BA is part of elemental loop 2.

Standard devolution tables essentially answer the question as to whether a reference adjacent gum drop pairs and the one following it belong to the same elemental loop.

Referring again to FIG. 21, column A shows a sequence of adjacent gum drop pairs with the standard tail attached. Column B shows the double helix pairs corresponding to the adjacent gum drop pairs in column A. In FIG. 21A, the double helix pairing counts for the standard tail is shown separated into even pairing and odd pairing by type. An explanation is provided as to how to read the pairing tables as shown.

Take, for instance, the adjacent gum drop pairs 1 and 2 in column A of FIG. 21. They translate to the double helix pair types 1 and 2 shown in column B. Since the bottom rippling droplets of item 1 is shown as B0101, items 1 and 2 result in an even pairing. This even pairing by type is shown in block 3 of even pairings in FIG. 21A. Further, there is only one pairing of this type within the Base line set (i.e. the adjacent gum drop pairs 1 thru 9 and 10 thru 15 combined) and is shown by a tally line on the left side of block 3 of even pairings in FIG. 21A. There is one pairing of this type attributable to Icicle 1 (items 15 and 16 in FIG. 21) and shown by a tally line on the right side of block 3 of even pairings in FIG. 21A. Therefore, there is a total of two pairings in block 3 of even pairings shown by a pair of 2's. The total pairing count (2) is pared or reduced by the pairing count (1) due to icicle 1. This is shown by an overstrike over the 2's and a net count of 1 pairing is shown in block 3 of even pairings. This process is repeated for all pairings of FIG. 21—odd and even for the standard tail and results in the numbers shown in FIG. 21A.

This process is repeated for the non-standard tail shown in columns C and D of FIG. 21 and the results are shown in FIB. 21B.

FIG. 21C shows the steps to be gone through in determining whether the adjacent gum drop pairs following the reference adjacent gum drop pairs belongs to the same elemental loop. First the even and odd pairing tables in FIG. 21C are populated from the (pared) non-standard tail pairing counts of FIG. 21B. Since the pairing cycle is determined to be even, a value of 1 is subtracted from block 3 of even pairings and a value of 1 is added to block 4 of even pairings. The rationale for this operation is as follows. It involves deriving the correct loop counts for the standard and non-standard tails. The double helix pairing counts as shown for column B already correctly represents the loop count. The explanation is as follows. Since the pairing of item 19 is not included in the pairing counts, if item 1 is deleted, then item 19 loops around and pairs with item 2 for the same pairing counts since item 19 and item 1 are the same. If on the other hand item 1 in column D for the non-standard tail is deleted, then since item 17 is not included in the pairing counts, the pairing counts for the non-standard tail mis-states the loop pairing counts since item 1 and item 17 are not the same. Therefore in order for the non-standard tail to accurately represent the loop count, the pairing counts for items 1 and 2 must be reduced by 1 and the pairing counts for item 17 and 2 must be increased by 1. As a final step, the (pared) pairing counts for the standard tail (shown in FIG. 21A) are subtracted from their corresponding pairing type counts in FIG. 21C and shown by overstrikes and the net result. The net count is a −1 in block 3 and a +1 in block 4 of the even pairings. If this criterion is met, the devolution table specifies that the adjacent gum drop pairs following the reference adjacent gum drop pairs (CB-BA*AC-AB) is AC-AB*CA-BC. If not, the adjacent gum drop pairs following the reference adjacent gum drop pairs (CB-BA*AC-AB) must be inferred to be AC-AB*CA-BA and must be chosen as the one following the reference adjacent gum drop pairs.

In general, paring (reducing) icicle pairing counts from total pairing counts for the double helix pairing set (with standard and non-standard tails as shown) may be dispensed with and the standard devolution tables may be reconstituted showing pairing differences for the various pairing types in a variation of the standard devolution tables as shown.

Standard devolution tables are an elaborate way to describe how to choose an adjacent gum drop pairs which follows the reference adjacent gum drop pairs. One skilled in the art will immediately see many simplifications that might be carried out. For instance when in the even cycle, dealing with odd pairings may be dispensed with as they are not involved in the decision process. These must not be construed as improvements. Rather, the solution is presented in elaborate detail for clarity of the concepts and ease of understanding.

Now the process of deciding which alternative to pick as item 3 for group 2 will be discussed. The process logic is outlined in FIG. 25 which describes steps to be gone through and shown as the overall step 274 for group 2 and step 374 for group 1.

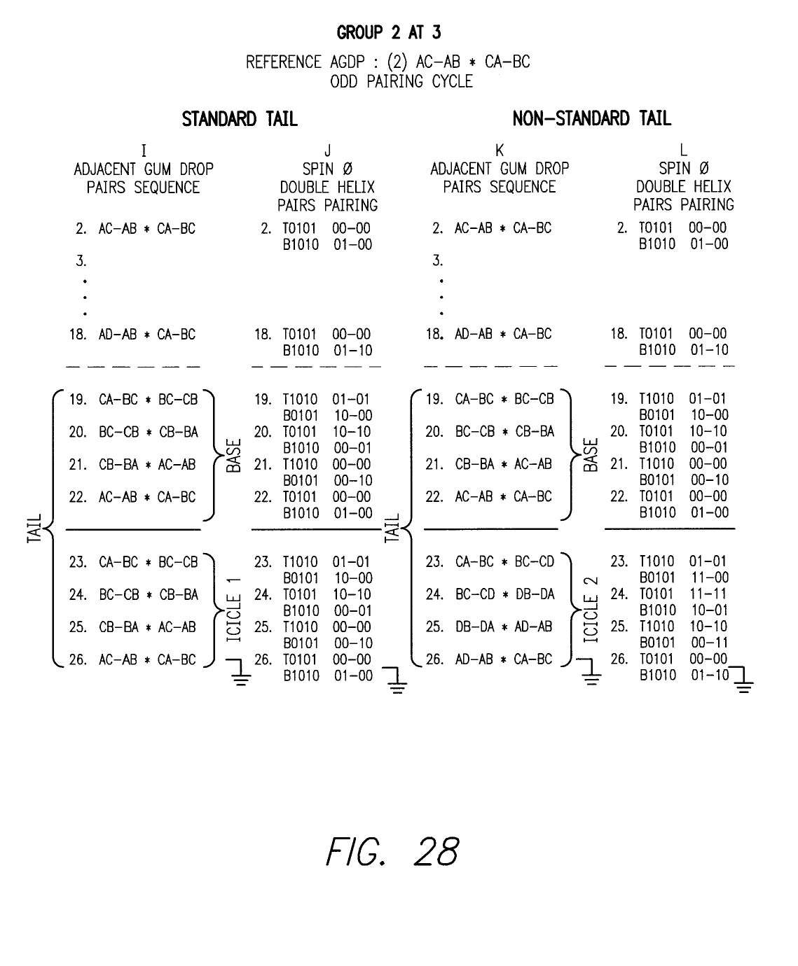

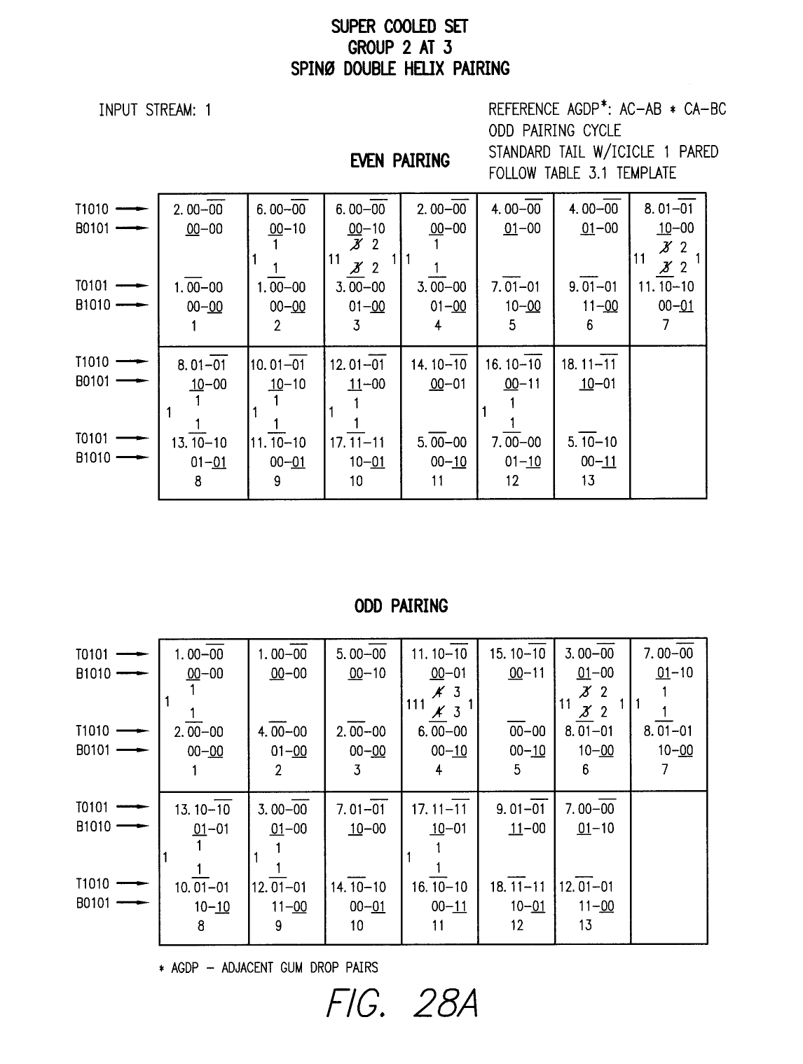

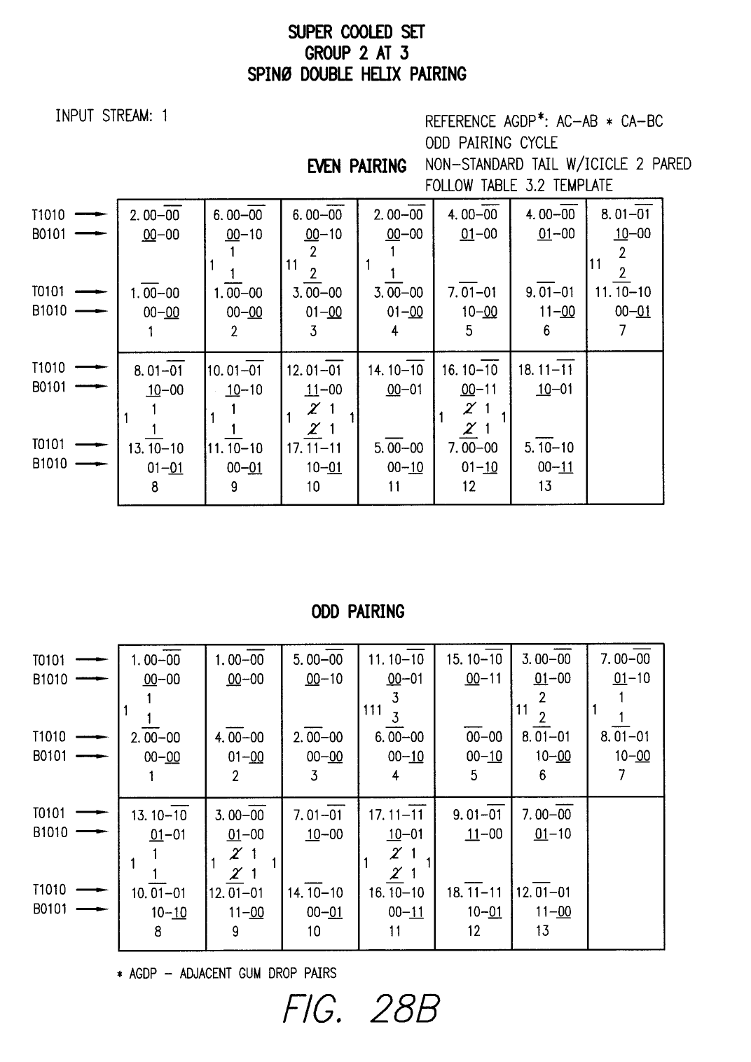

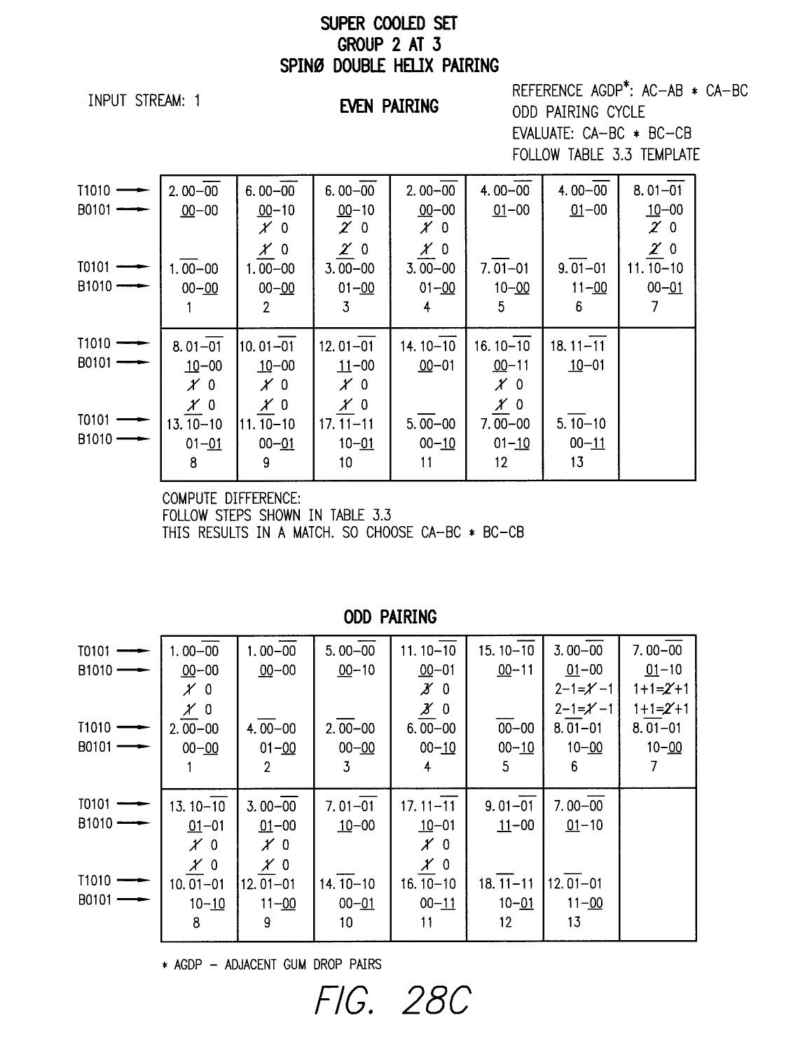

In a step 1274, a copy of the super cooled set as reflected at this point is made. All operations are carried out on the copy/copies leaving the original untouched. At this point, the reference adjacent gum drop pairs (item 2) is known to be AC-AB*CA-BC. The bottom rippling droplets of the double helix pairs corresponding to it is shown as B1010 (Refer to FIG. 28). Therefore in step 1274, the devolution cycle is defined to be in the odd pairing cycle.

Reference is now made to FIG. 28. In a step 1278, the base tail (items 19 thru 22) is added to the super cooled set (items 2 thru 18) to bring it to base line status. The odd/even pairing counts of the double helix pairs by type are increased (not specifically shown in a figure). Two copies are made of this set.

In a step 1282, one copy of the double helix odd/even pairing counts by type are inserted into the appropriate blocks of FIG. 28A with corresponding tally lines shown to the left in the various blocks. (It should be noted that these tally lines are not needed and are only shown for consistency with the format and the looks of the standard devolution tables of FIG. 21 discussed earlier.) Next, the double helix pairing type counts for Icicle 1 are shown as tally lines to the right in the appropriate blocks and the total counts are derived (by adding together the counts for the base line set and icicle 1 set) and shown as a pair of digits in the various blocks showing the pairing counts. Finally the pairing counts due to Icicle 1 are pared from the total pairing counts in the applicable boxes shown as overstrikes and the reduced pairing counts are shown. All this is shown for consistency in the write-up and for ease of understanding and most likely will not be gone through in a practical implementation.

In a step 1286, the same process is repeated for the second copy and a non-standard tail with icicle 2 as shown in FIG. 28. The resulting pairing counts are presented in FIG. 28B.

Next, the process branches to step 1290. Since the standard devolution tables are defined by reference adjacent gum drop pairs and the current reference adjacent gum drop pairs is identified as AC-AB*CA-BC, the standard devolution table 3 is chosen as the template to follow and the steps specified in Table 3.3 are carried out as follows in step 1294.

TABLE 3.3

| STEP | |
|---|---|
| 1. | Table shown in FIG. 28C is populated from the Non-standard |
| | pairing counts of FIG. 28B. |
| 2. | A count of 1 is subtracted from Block 6 of odd pairing counts. |
| 3. | A count of 1 is added to Block 7 of odd pairing count. |
| 4. | The standard pairing counts of FIG., 28A are subtracted from |
| | the pairing counts after Step 3. These are shown as overstrikes |
| | and the resulting counts. |

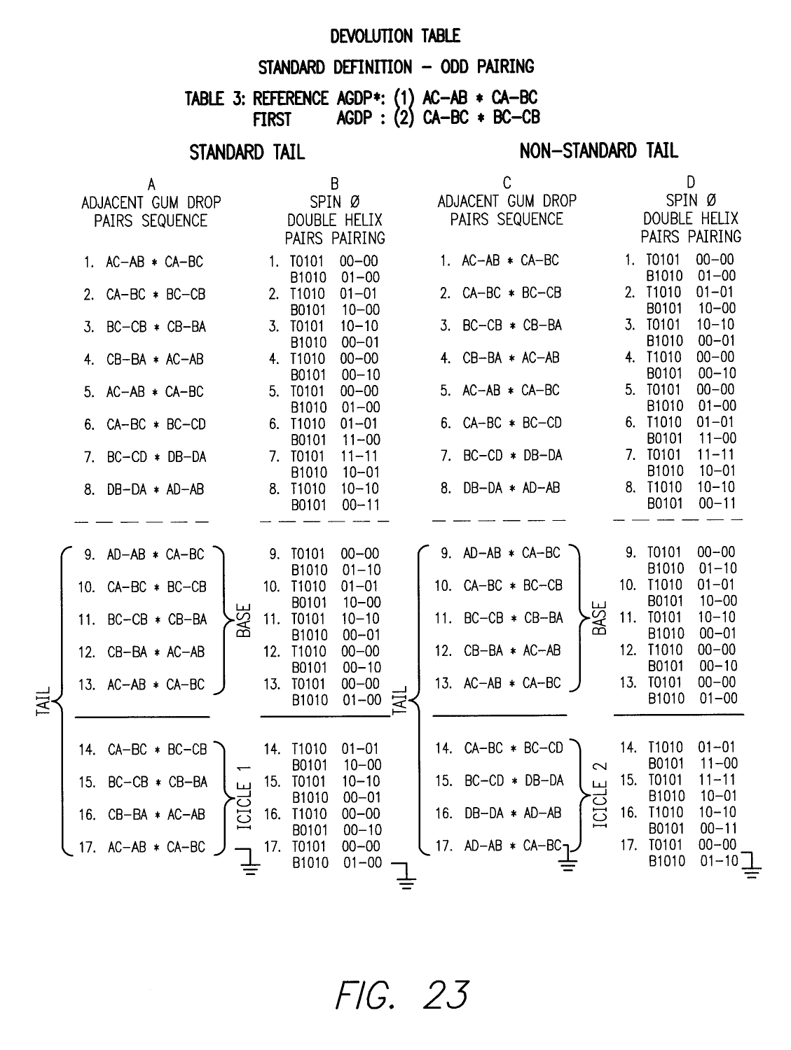

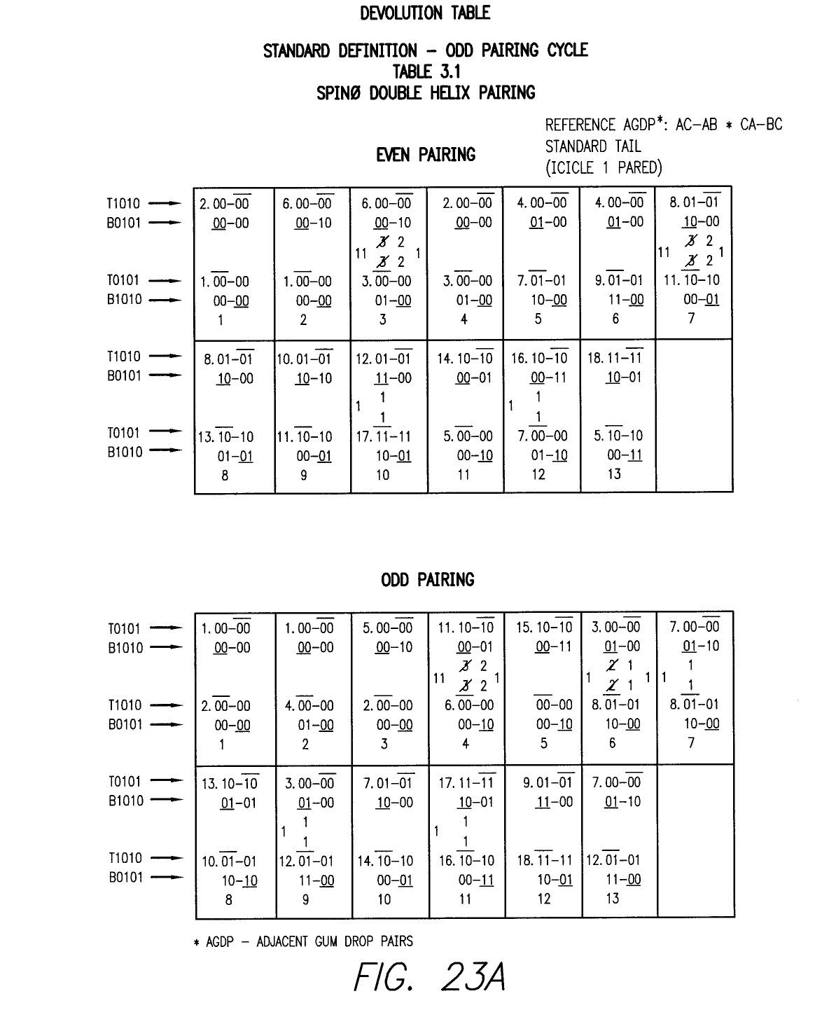

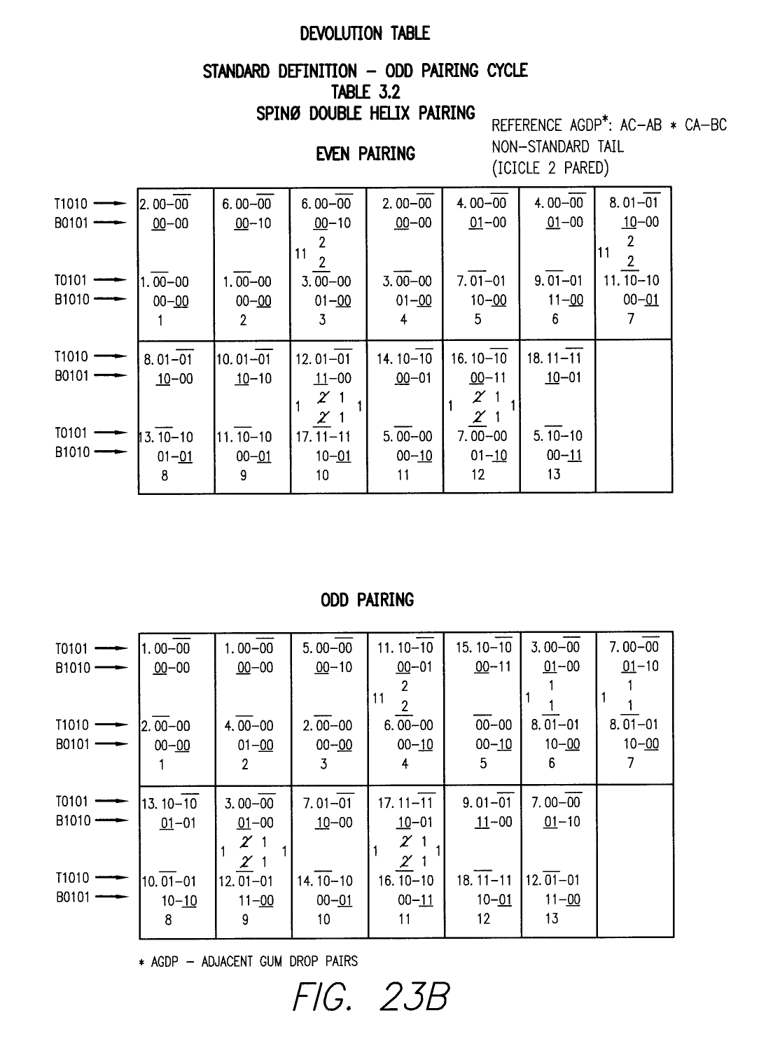

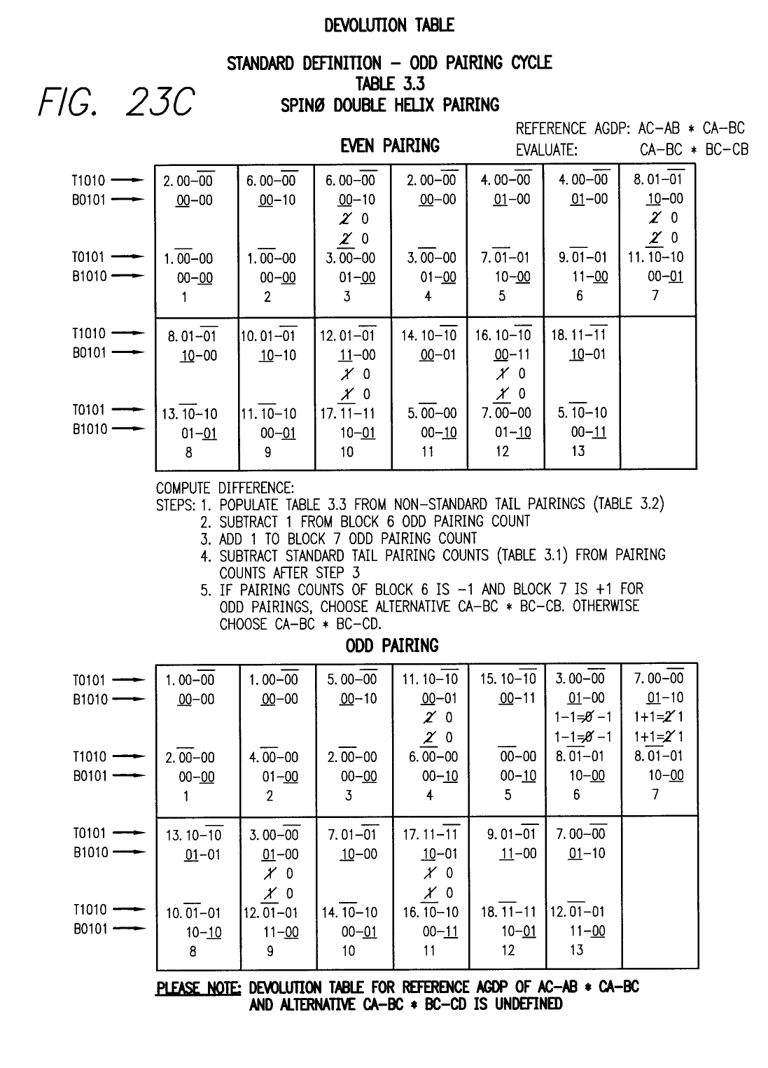

The process then branches to step 1298. The pairing value differences of FIG. 28C are compared with the pairing value differences of FIG. 23C and a match is shown. So as specified in step 5 of the standard devolution Table 3.3 (FIG. 23C) the adjacent gum drop pair value of CA-BC*BC-CB is returned as the next (sequence 3) adjacent gum drop pairs and the control branches back to step 276 of group 2 devolution.

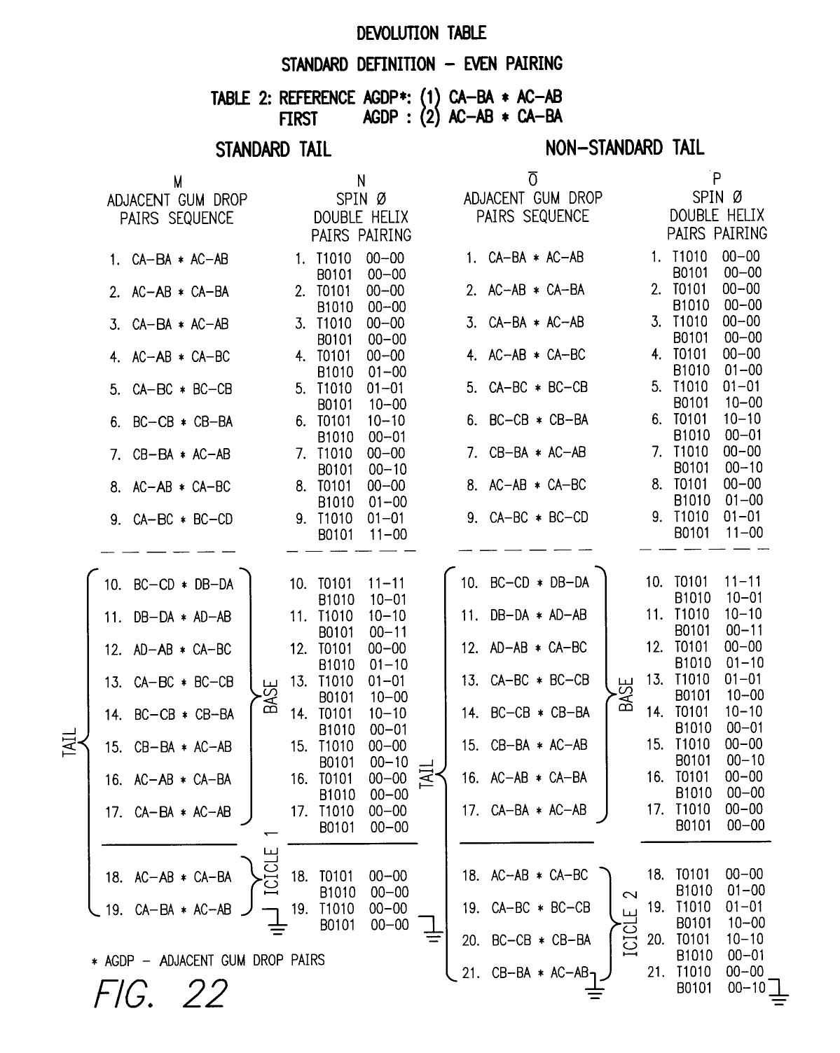

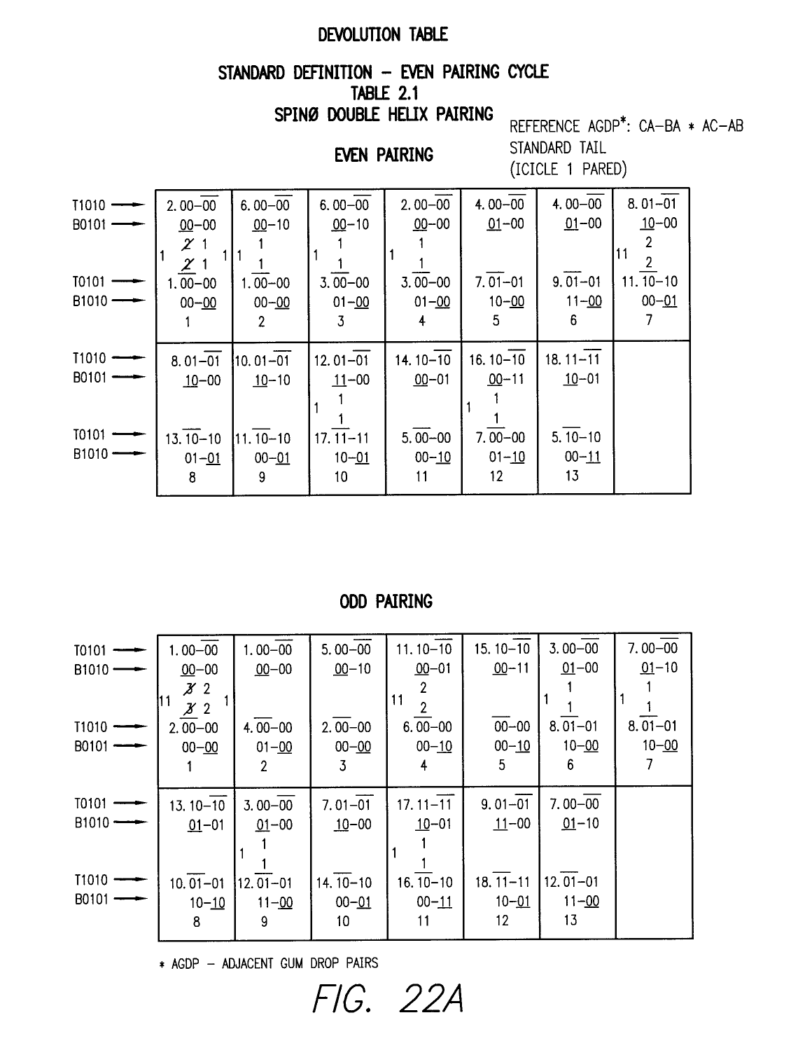

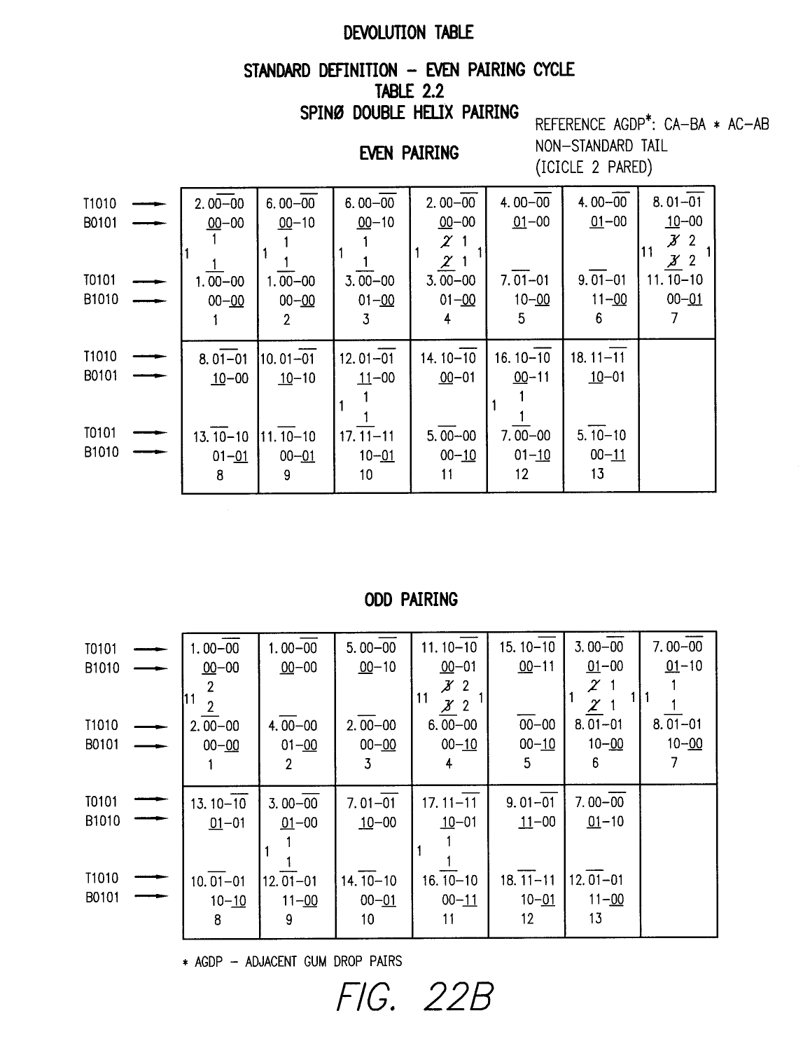

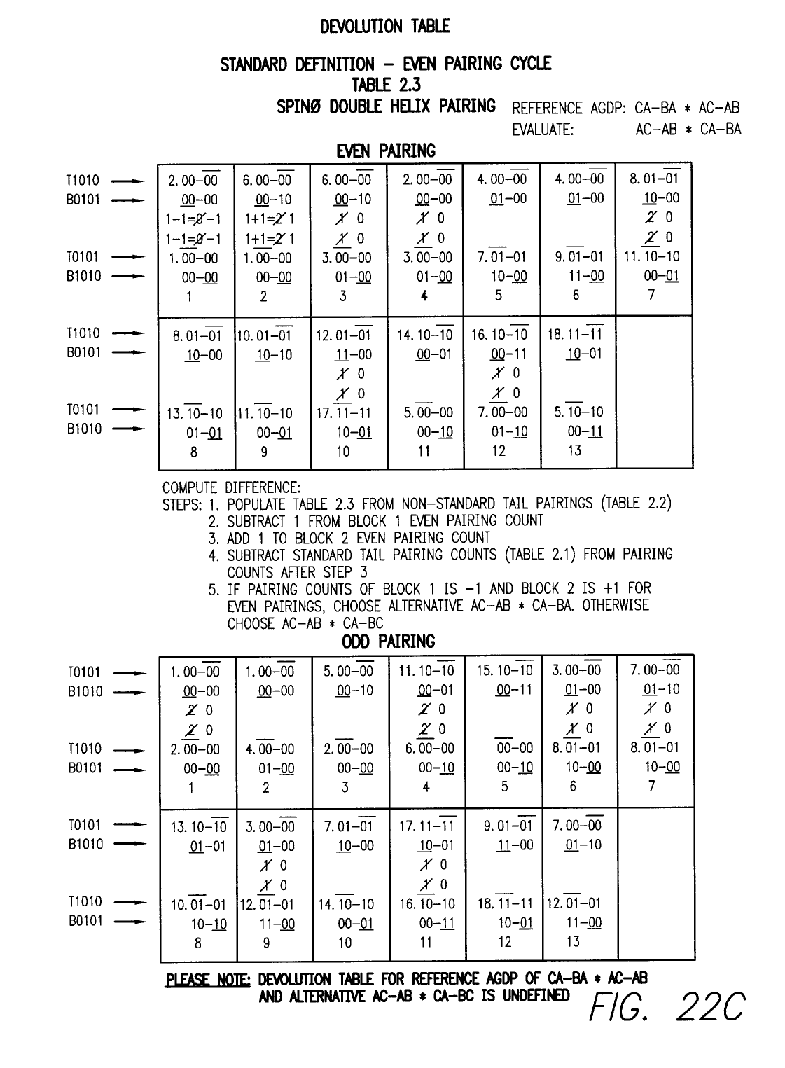

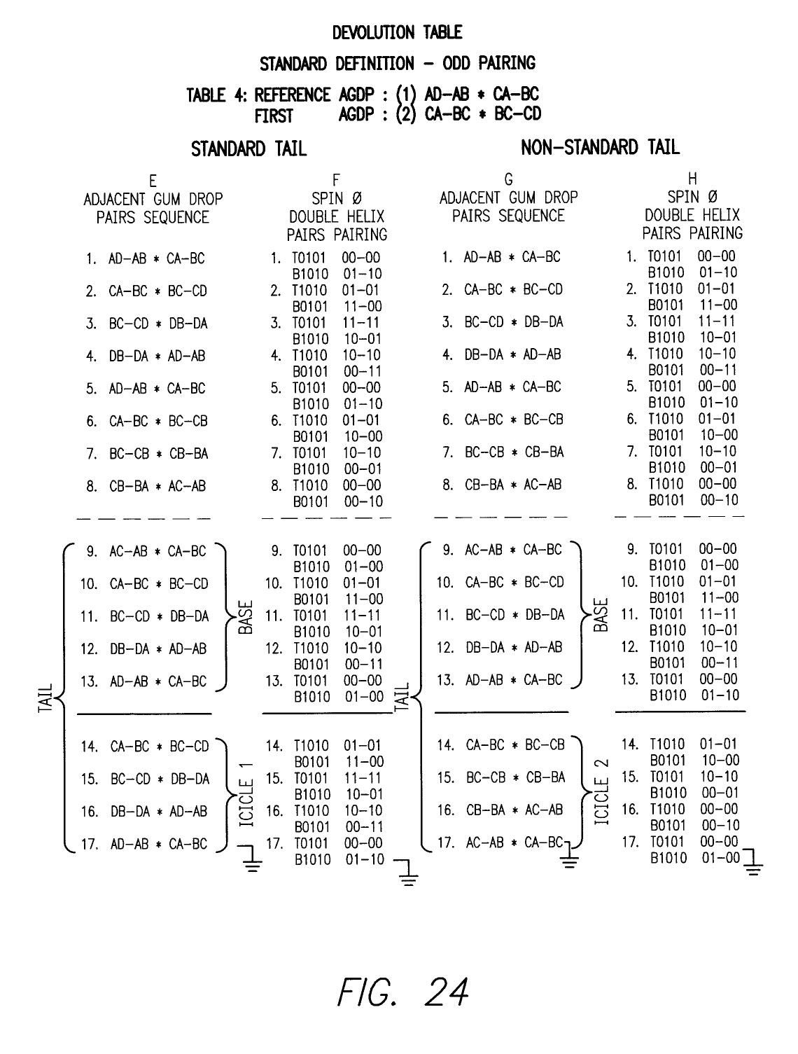

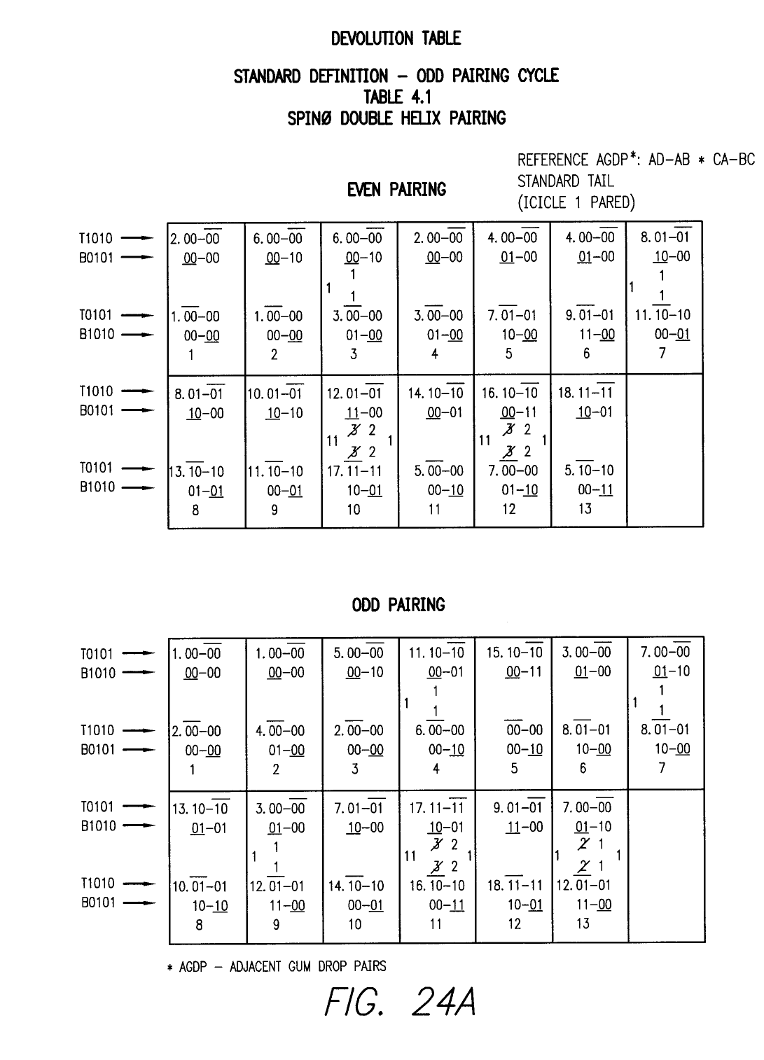

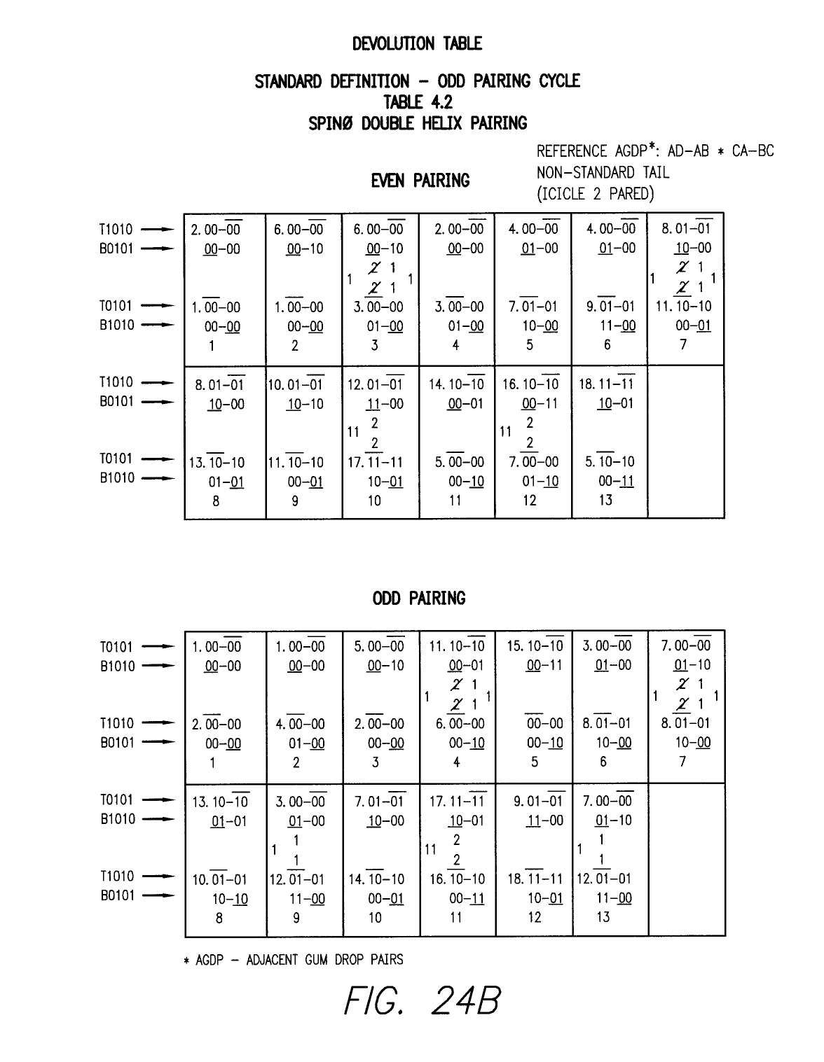

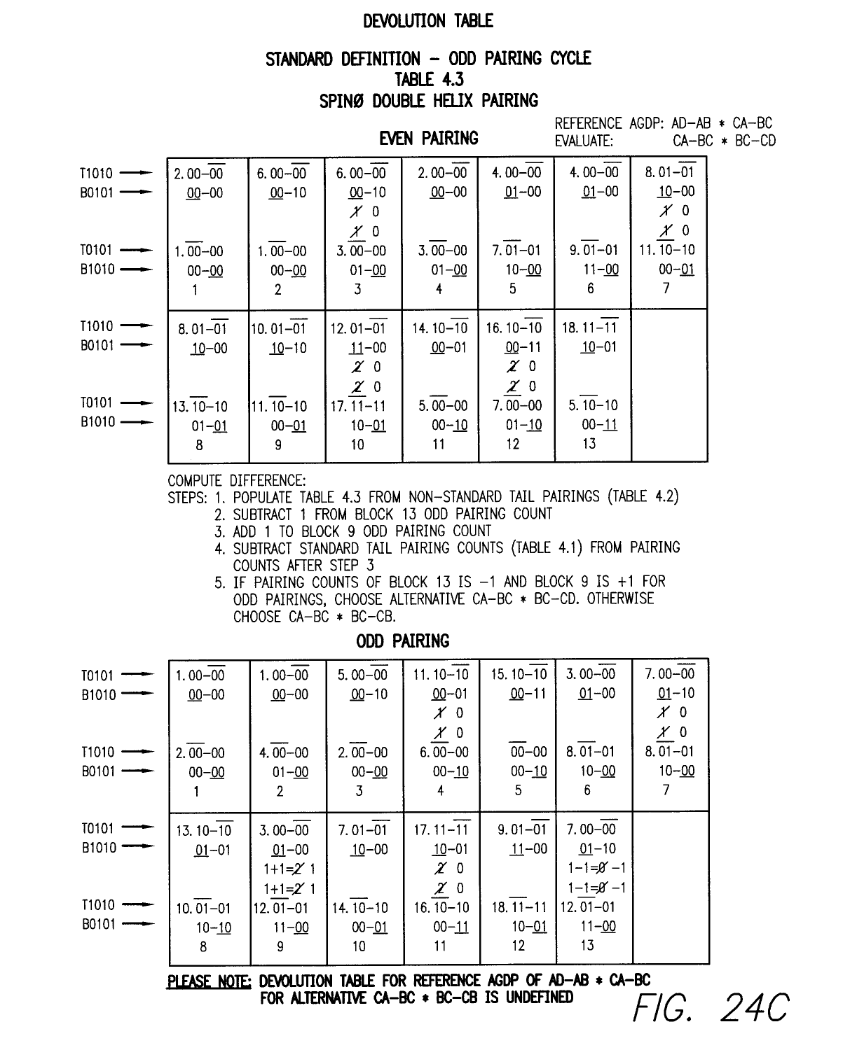

Before resuming discussion of the devolution process, a few additional comments are in order. Standard Devolution tables are presented for the following reference adjacent gum drop pairs;
1. CB-BA*AC-AB (Tables 1, 1.1, 1.2 and 1.3 shown in FIGS. 21, 21A, 21B and 21C respectively)
2. CA-BA*AC-AB (Tables 2, 2.1, 2.2 and 2.3 shown in FIGS. 22, 22A, 22B and 22C respectively)
3. AC-AB*CA-BC (Tables 3, 3.1, 3.2 and 3.3 shown in FIGS. 23, 23A, 23B and 23C respectively) and
4. AD-AB*CA-BC (Tables 4, 4.1, 4.2 and 4.3 shown in FIGS. 24, 24A, 24B and 24C respectively)
   This is only a partial list. Standard Devolution Tables need to be defined for every possible adjacent gum drop pair type.

Devolution examples are worked out and the details shown for the following:
1. Group 2 at 2: Reference AGDP*: CA-BA*AC-AB
   Next AGDP: AC-AB*CA-BC

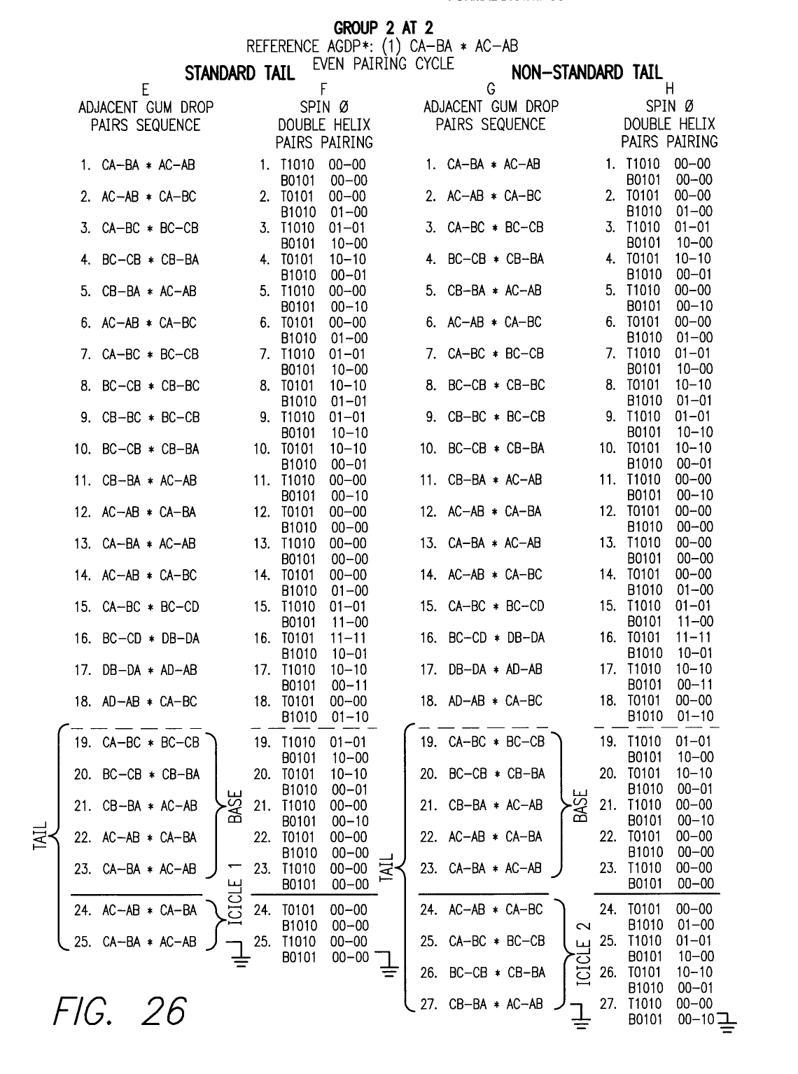

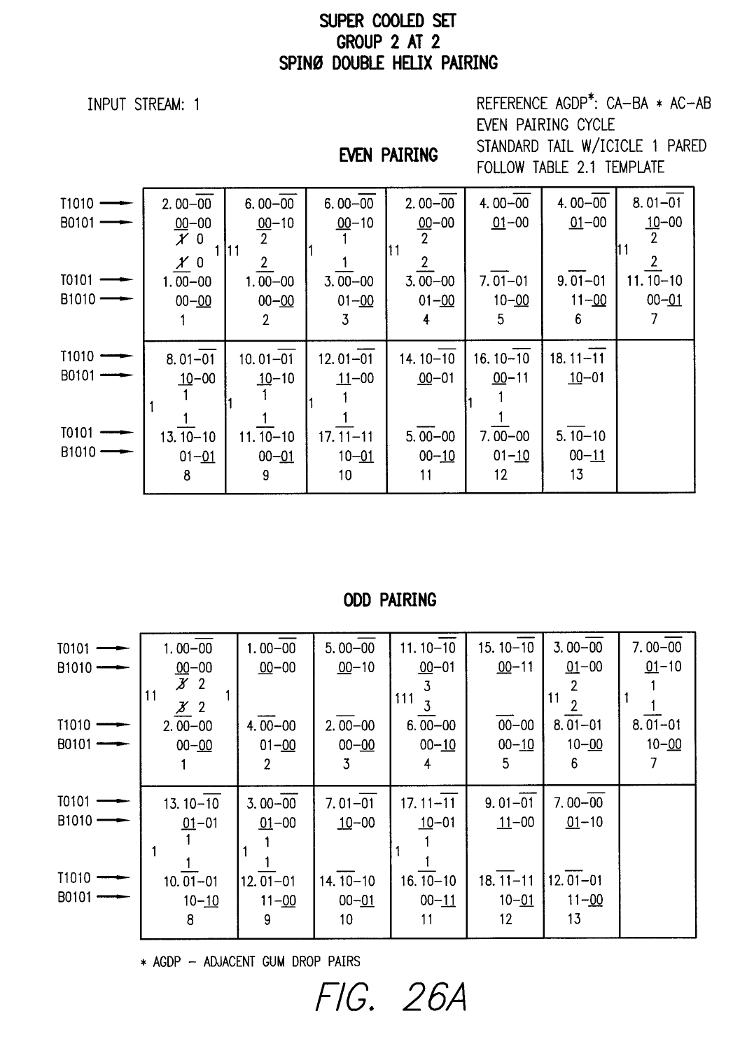

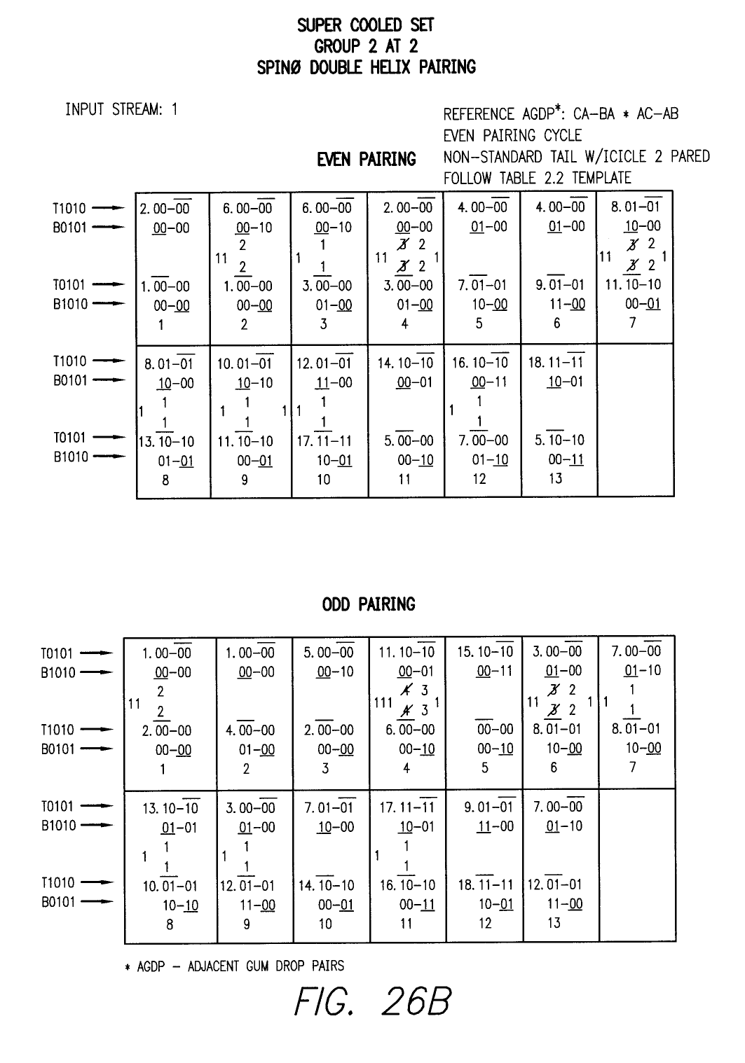

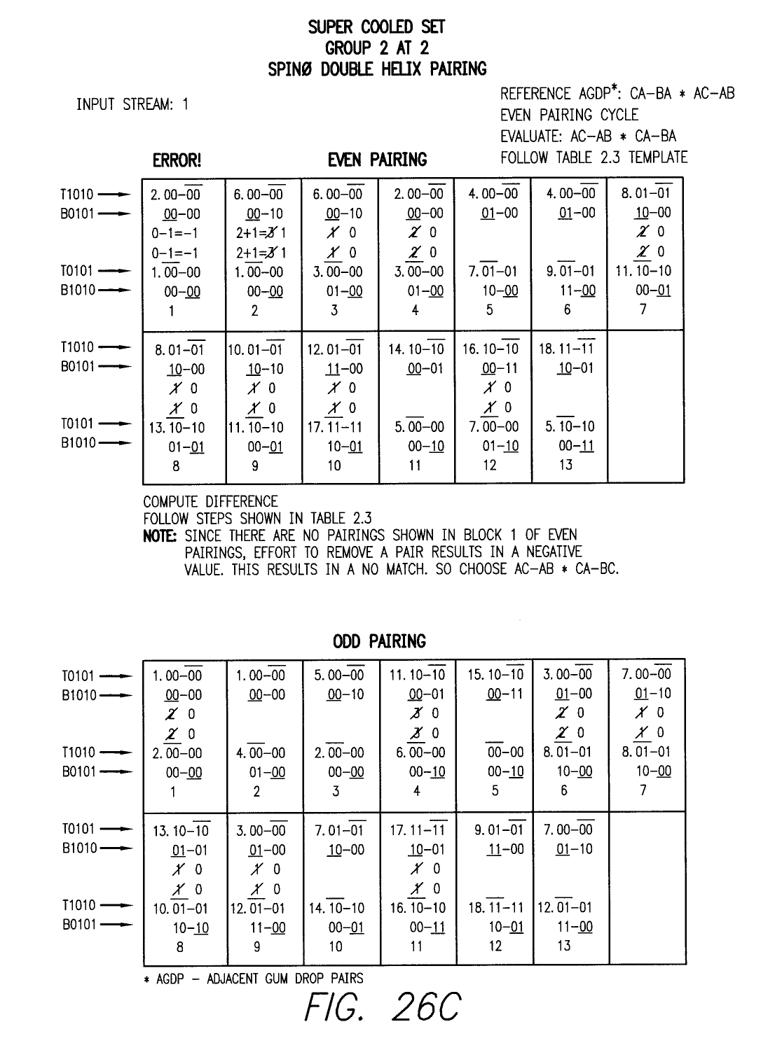

Details presented in FIGS. 26, 26A, 26B and 26C.
2. Group 1 at 4: Reference AGDP: CB-BA*AC-AB
   Next AGDP: AC-AB*CA-BC

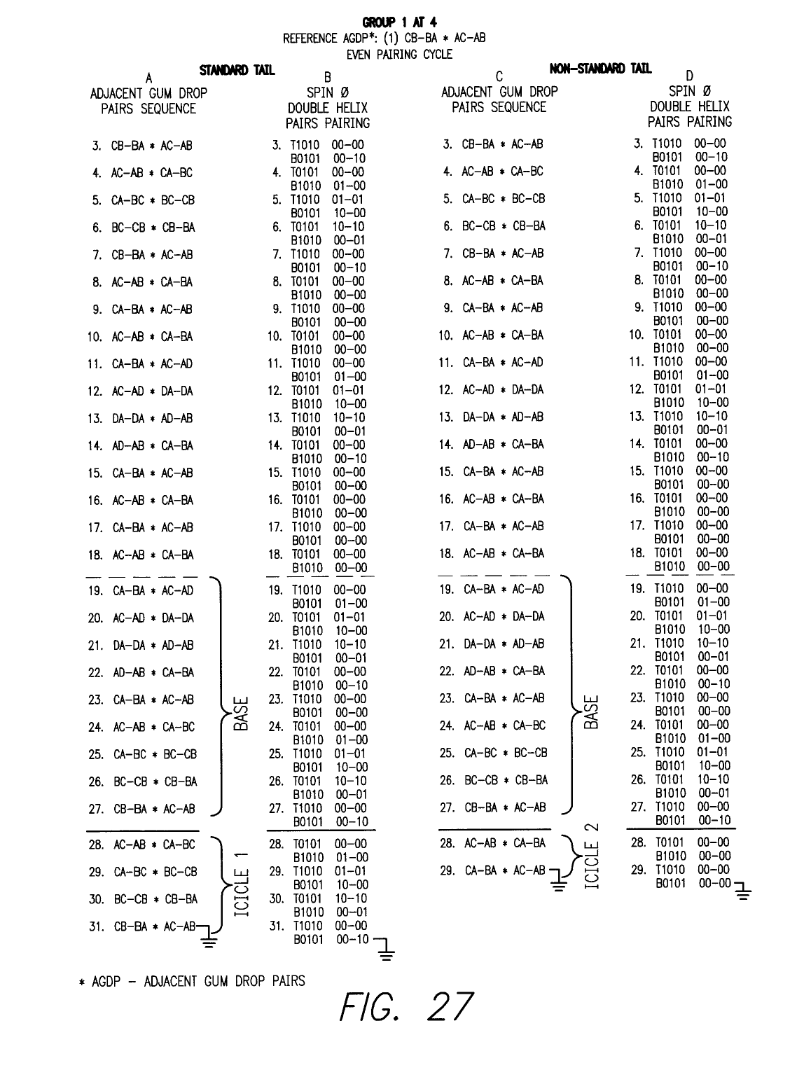

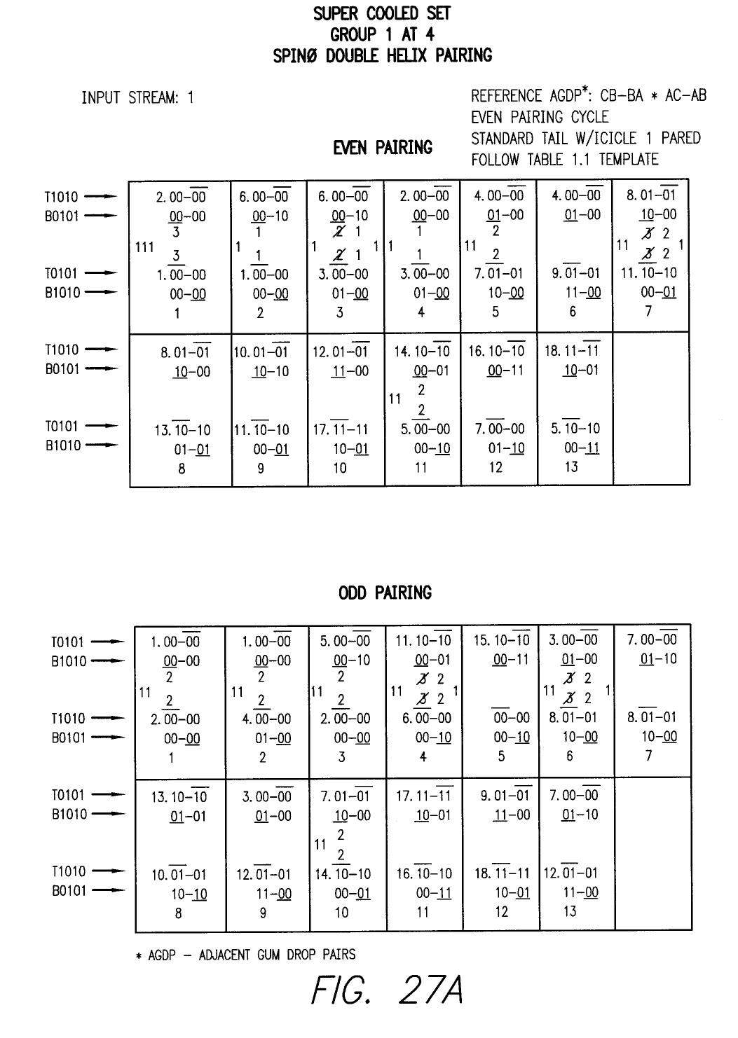

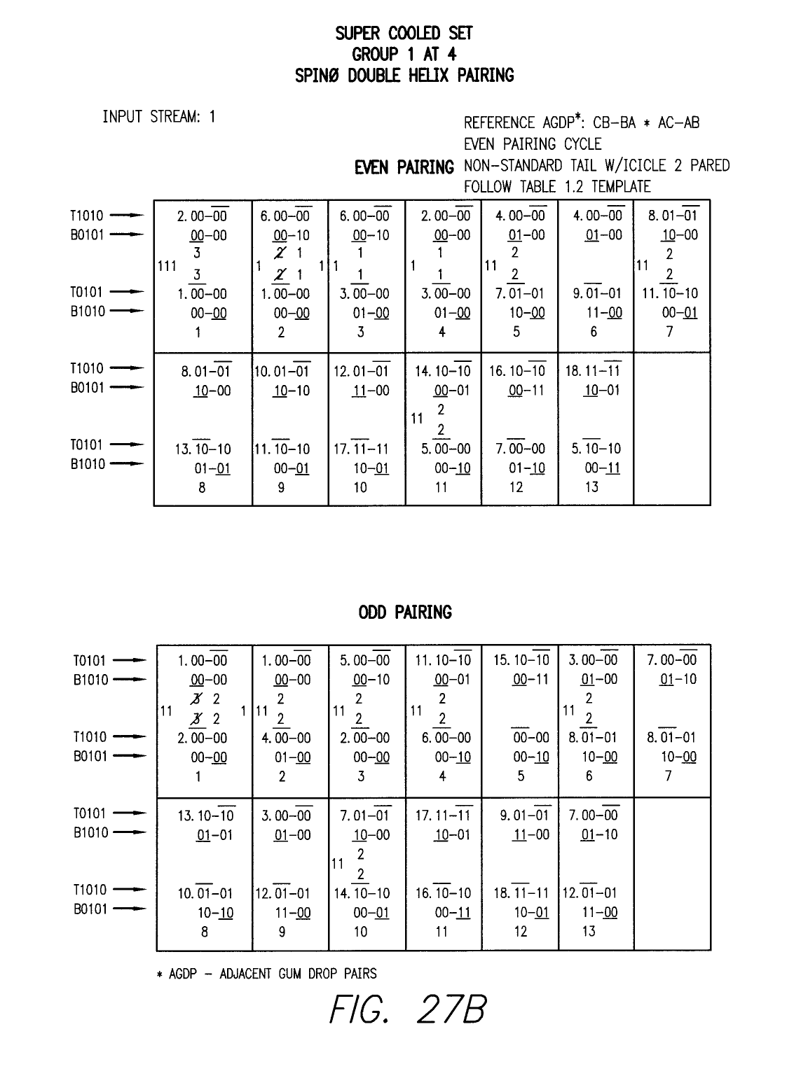

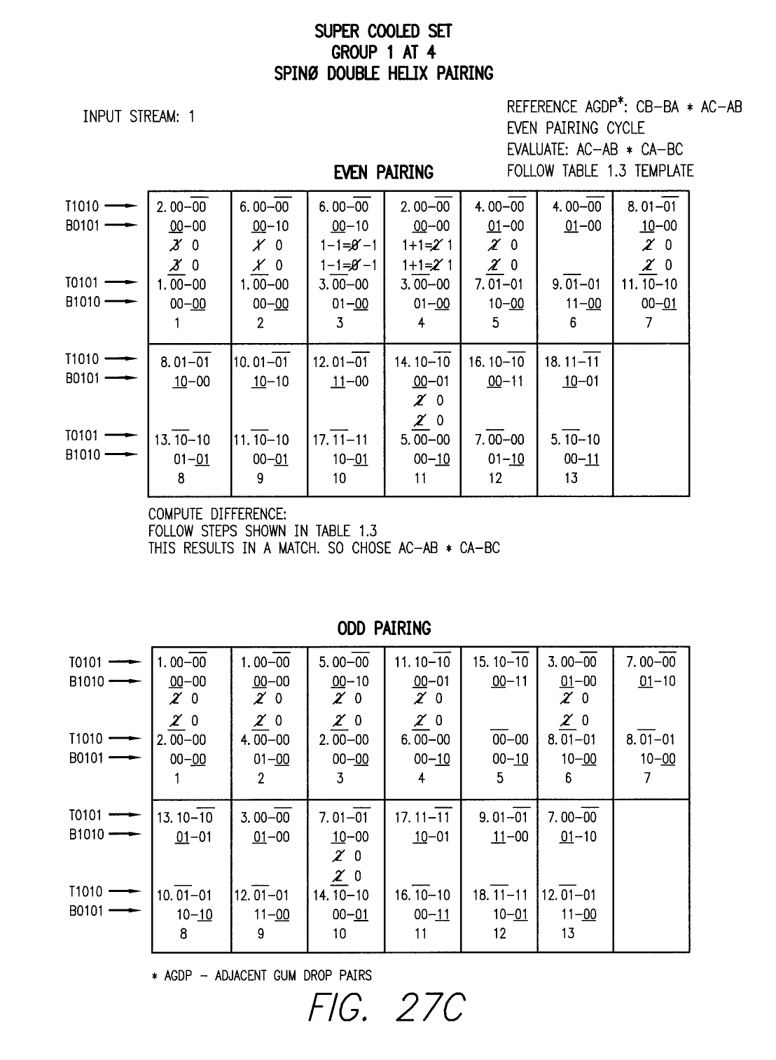

Details presented in FIGS. 27, 27A, 27B and 27C.
3. Group 2 at 3: Reference AGDP: AC-AB*CA-BC
   Next AGDP: CA-BC*BC-CB

Details presented in FIGS. 28, 28A, 28B and 28C.
4. Group 2 at 15: Reference AGDP: AC-AB*CA-BC
   Next AGDP: CA-BC*BC-CD

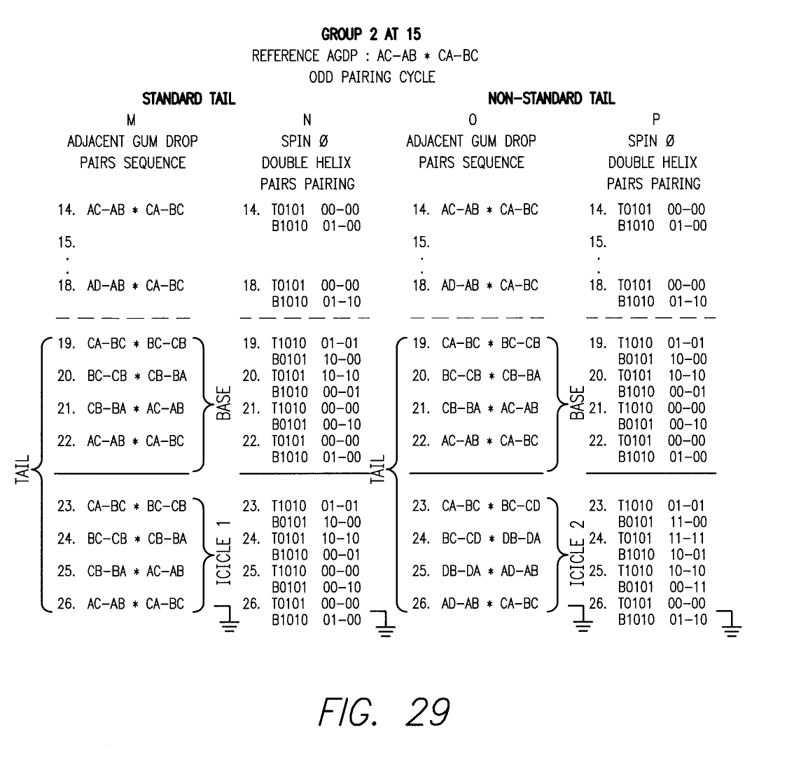

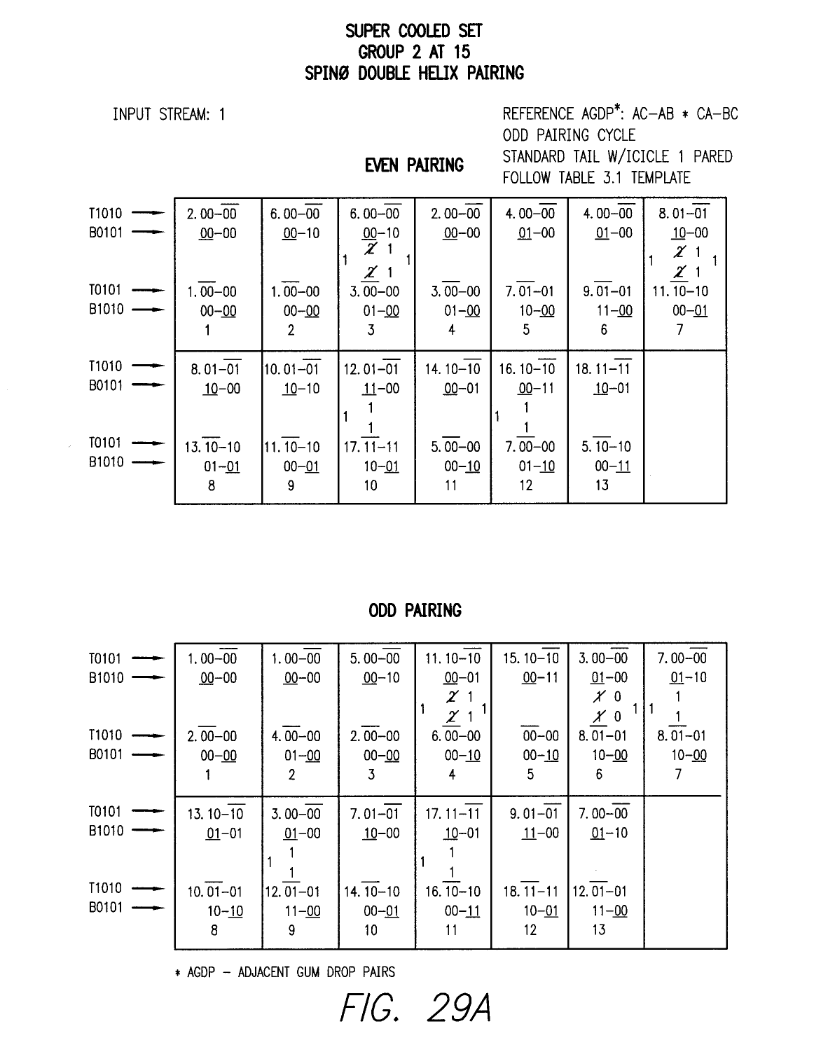

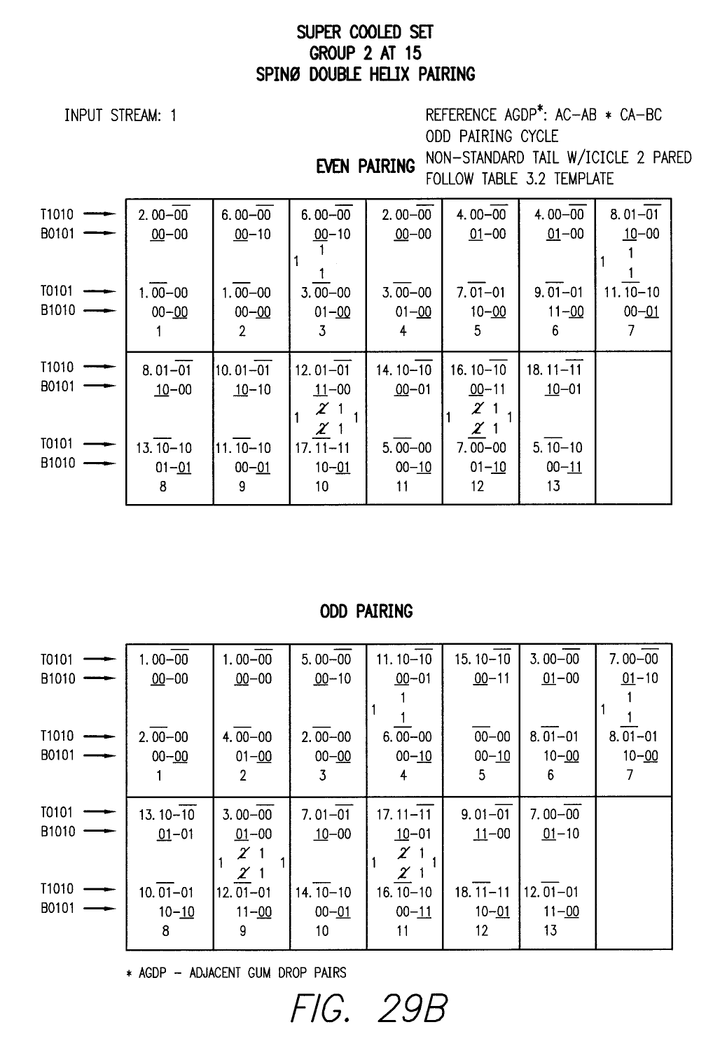

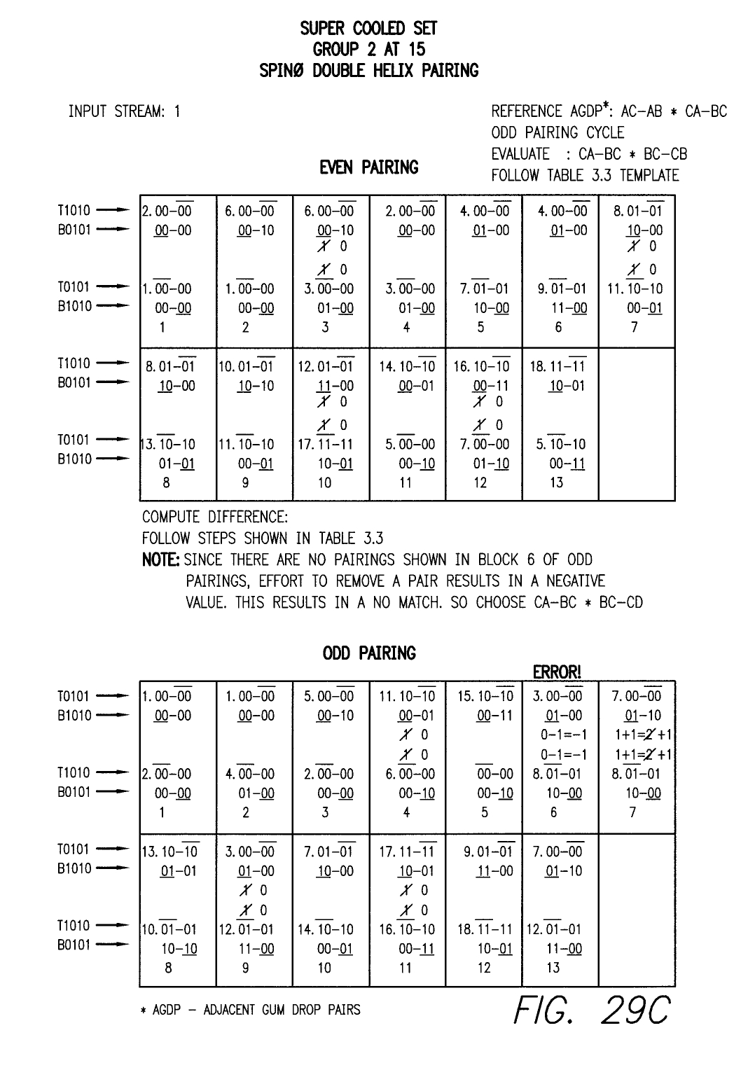

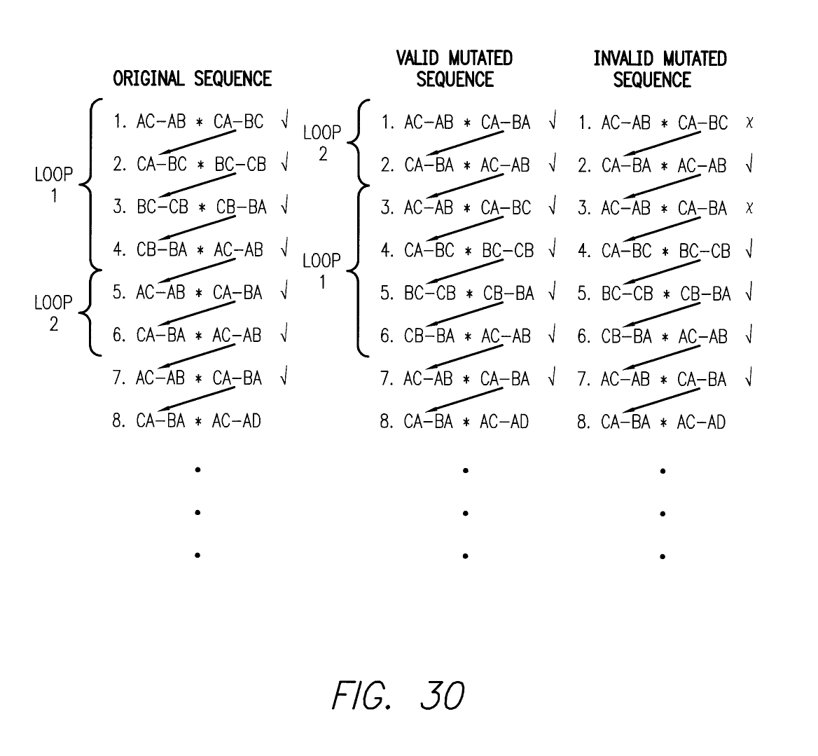

Details presented in FIGS. 29, 29A, 29B and 29C.

These devolution examples were deliberately chosen. In the case of items 1 and 2, the reference adjacent gum drop pairs are different, but what follows them is the same adjacent gum drop pairs. In the case of items 3 and 4, the reference adjacent gum drop pairs are the same but what follows them are two different adjacent gum drop pairs.

Except for item 3, the other examples are worked out and shown without explanation. In all cases, the correct choice is made for the adjacent gum drop pairs which follows the reference adjacent gum drop pairs, thereby validating the approach defined.

If there are more adjacent gum drop pairs left in the super cooled set, then control branches back to step 270. Steps 270, 274 and 276 are repeated until there are no more adjacent gum drop pairs available. At this point control branches to step 278 and the right drop pair of the right gum drop pairs of the last adjacent gum drop pairs is emitted as the last source puck for group 2 and labeled as SP21 [BC].

When the last source puck [SP21] of the reconstructed series of source pucks is emitted, the control unit 218 identifies the inversion pucks as shown as a step 350 in FIG. 19A. For example, the inversion pucks [CC] and [CA] of the super cooled set in FIG. 4Y are identified and placed into the reconstructed series of source pucks as SP22 and SP23 as shown in FIG. 4Z.

Referring now to FIG. 19B, once the source pucks of the second group have been devolved as described above, the control unit 218 retrieves the source pucks from the first group of the super cooled set and executes the logic as shown by steps 366, 370, 374, 376 and 378. The steps 366, 370, 374, 376 and 378 of the devolving subroutine 258 of the first group is substantially similar to steps 266, 270, 274, 276 and 278 of the devolving subroutine 258 for the second group, except that the steps 366, 370, 374, 376 and 378 take into account that the source pucks in the first group were provided in reverse order during the super cooling process discussed herein. As such, it can be seen that devolving the source pucks in the second group results in the “first half” of the reconstructed source stream wherein the source pucks retrieved are ordered from the “first” or “left-most” source puck and move “right” towards the “middle.” In contrast, devolving the source pucks in the first group results in the “second half” of the reconstructed source stream, where the source pucks retrieved are ordered from the “last” or “right-most” source puck and move “left” towards the “middle.”

Additionally, steps 366, 370, 374, 376 and 378 take into account that the source pucks in the first group are the left drop pair of the right gum drop pair of each adjacent gum drop pair included in the super cooled set for the first group with the exception of the first and last adjacent gum drop pairs in the set, each of which yield two source pucks of Group 1. For example, in the step 366, the starting adjacent gum drop pairs of the first group is represented as [DA-DC*BD-CB]. The left most drop pair is thus [DA] and represents the last source puck [SP43] in the reconstructed series of source pucks as shown in FIG. 4Z and the left drop pair of the right gum drop pairs shown as [BD] is the second to last source puck in the reconstructed series of source pucks shown in FIG. 4Z. Since the super cooled set for the first group specifies the first and second double helix pairs, the first two adjacent gum drop pairs are known. Therefore the two source pucks (the last, SP43 and second to last, SP42) are identified as part of the first adjacent gum drop pairs are emitted. The first adjacent gum drop pair type count is reduced by 1 in the super cooled set; the first double helix pair type pairing count is reduced by 1 and the second adjacent gum drop pairs is now designated as the reference adjacent gum drop pairs for the remaining super cooled set for the first group.

Similar to step 270, a determination as to whether the next adjacent gum drop pairs can be identified within the first group is shown as step 370. If more than one alternative exists, then in the selection subroutine 258, a correct alternative for the next adjacent gum drop pairs is determined for the first group as shown by step 374. This determination is similar to the step 274 discussed above. Control now branches to step 376. In this step, the left drop pair of the right gum drop pair of the reference adjacent gum drop pair is emitted as the next source puck in reverse order in the reconstructed series of source pucks. The reference adjacent gum drop pairs type count is reduced by 1; the double helix pairing type count corresponding to the reference adjacent gum drop pairs and the one following it is reduced by 1 in the remaining super cooled set; the following adjacent gum drop pairs type is designated as the reference adjacent gum drop pairs as shown in step 376.

If there are more adjacent gum drop pairs in the remaining super cooled set for the first group, control branches back to step 370 and the process is repeated

When there is no more adjacent gum drop pairs left, the last two source pucks are emitted from the last reference adjacent gum drop pairs as determined by the left drop pair of the last adjacent gum drop pairs as shown by step 440 of FIG. 19B. For example, for the last adjacent gum drop pairs represented by [CA-BA*AC-AD], the left drop of the left gum drop pair is [CA]. Thus, [CA] is the source puck [SP25] in the reconstructed series of source pucks shown in FIG. 4Z. The left drop of the right gum drop pair is [AC]. Thus, [AC] is the source puck [SP24] in the reconstructed series of source pucks shown in FIG. 4Z.

When the source pucks from the last adjacent gum drop pairs are emitted, there are no more remaining adjacent gum drop pairs. As such, the exemplary reconstructed series of source pucks shown in FIG. 4Z are the same as the series of source pucks shown in FIG. 4G (i.e. the source pucks derived during the super cooling process.)

The remaining steps of the super heating process after reconstruction of the series of source pucks includes reversing steps 20, 22, 24, 32, 34, and 36 of the super cooling process. While the remaining steps of the super heating process are described in terms of separate steps performed in sequence, it will be apparent to one skilled in the art that the steps and/or portions thereof may be done in parallel as the reconstruction of the series of source pucks in the devolving subroutine 258 is performed.

Referring now to FIG. 18, overlapping drops in adjacent pucks are removed and the drop code is applied to the remaining drops so as to reconstruct the source stream having droplets as shown by step 500. For example, removal of overlapping drops and applying the drop code will alter the reconstructed series of source pucks in FIG. 4Z to be the same as the source stream shown in FIG. 4D.

Once the source stream is reconstructed, the control unit 218 branches to a step 504, wherein the final end droplet of the reconstructed source stream is removed. For example, by removing the final end droplet of the reconstructed source stream, the result is the source stream shown in FIG. 4C.

The control unit 217 may then branch to a step 508 wherein the remaining droplets of the reconstructed source stream are rotated to the left by N+1 droplets, where N is the number of droplets in the input stream as provided by the super cooled sets of FIGS. 4T and 4Y. The result is a stream that is the same as the rippled input stream shown in FIG. 4B. It should be understood the offset approach of the super cooling process described herein may be used instead of “rotating” to provide the same end result in the super heating process.

In a step 512, the rippling droplets are removed from the stream shown in FIG. 4B to yield the original input stream shown in FIG. 4A. If any padding droplets (also referred to as “after spray”) were added as specified in the super cooled sets of FIGS. 4T and 4Y, they are removed from the stream shown in FIG. 4A to yield the original input stream.

The resulting stream of step 516 is the reconstructed or “decompressed” input stream in its original order, also referred to as the output stream. Thus, the super heating process performed by the control unit 218 of the receiver 14 of the system 10 decompressed and reordered the compressed unordered representation to an ordered representation of the input stream provided by the super cooling process. The output stream provided from the super heating process may then be output by the receiver 14 such that the information of the original input stream may be utilized (e.g. processed or displayed) in its binary form.

As previously described, the encoding and summarization and the re-expansion and decoding models described herein present several analogies to the double helix structure referred to as DNA. For example, the definitions found in the Y-Chromosome are analogous to the pairing types and counts defined in the devolution table because without them the summarizations cannot be re-expanded. Although adjacent gum drop pairs and equivalent double helix pairs are discussed, a similar table can be derived using the gum drop pairs and the equivalent double helix pairs. Devolution of the summarizations found in the super cooled sets requires the use of the devolution tables which is analogous in nature to expansion of the stem cell sets which are essential to the creation of life. In particular, life cannot be created without the union of the male (Y-chromosome) with those of the female. Thus, the type and structure of the devolution table may provide clues as to the nature and content of the Y-chromosome.

Additionally, the phenomenon of cell death (which is accompanied by the disappearance of DNA tails) may also follow this model. For example, in order for devolution to occur, the super cooled set must be brought to the “base line” state before “devolution” can proceed. This action necessitates the addition of the “tail” for the adjacent gum drop pairs that are needed. Although easily accomplished in a computer environment, within the biological environment, the needed DNA tails are plucked off, snippets at a time, from an inventory of DNA pairs in the DNA tails. When these are exhausted, the cell can no longer perform its function and dies.

In a sense, the model presented herein may be a validation of the concept of the evolution of life. DNA mutations may follow the model described herein. For example, a known sequence of droplets in the input stream through manipulation may be assembled into sequences having precedence relationships and be converted into a summarized set known as the super cooled set, i.e., the stem cell set. Devolution is the process by which this known set is unraveled so as to preserve and reproduce the ordering of the original input stream resulting in a biological entity.

In a natural selection process, it is possible for devolution to occur where all of the elements of the original input stream are present, or are added to and/or the ordering of the individual loops are changed. This alters the functioning of the organism and may be regarded as one form of “mutation” resulting in an evolutionary sequence.

For adjacent gum drop pairs, the mutation must occur at the loop level in order to preserve the precedence relationship of the adjacent elements. This is shown by an example in FIG. 26 through sloping arrows showing the precedence relationships. The ‘x’ and the ‘check’ symbols to the right of each adjacent gum drop pairs show invalid and valid precedence relationships.

In the valid, as well as the invalid mutated sequences, the functioning of the entity is altered from its original intent. This phenomenon is referred to as a “devolutionary mutation.” This concept of mutation is described in terms of the adjacent gum drop pairs, but also apply equally to gum drop pairs and associated duets. In the sequencing of gum drop pairs, drop pairs cannot be arbitrarily replaced without taking into account the precedence relationships and what they mean at that point.

A valid mutated sequence may be referred to as a “benign” mutation that may or may not be desirable. Additionally, the benign mutation may not result in problems in the functioning of an organism. However, an invalid mutated sequence is referred to as a “malignant” mutation, and generally does lead to undesirable results in the function of the organism.

As discussed herein, in devolution, a super cooled set is expanded to reproduce the original sequencing of the input stream. Generally when the input stream is super cooled, it is separated into three components having inherent precedence relationships—Group 1 elements, Group 2, elements, and inversion pucks.

When Group 2 devolution occurs, source pucks generated are emitted form the start of the source stream towards the middle. However, when Group 1 devolution occurs, source pucks generated are from end of the source stream towards the middle. The super cooled set may therefore be considered to form a “nucleus” that is slowly is depleted as the devolution process continues. Therefore, in devolution, the regeneration of the source stream occurs form the extremities towards the middle. This process mirrors the phenomenon of cell growth.

Evolution itself may also be explained by this model. Generally, evolution is the reverse of devolution and takes on one of two forms—Relative and Absolute. In Absolute evolution, the entity to be evolved is unknown. The process begins with a set of elemental entities (similar to drops, pucks, gum drop pairs, adjacent gum drop pairs, etc.). The entity is built out of these elements preserving the precedential relationship requirement. This proceeds from the inside out (i.e. from the middle towards the extremities).

In Relative evolution, the entity (similar to the input stream) is known and is available as a super cooled set with its precedence relationship requirement. During devolution of the super cooled set, either the ordering of the elemental loops is changed or other elemental loops not part of the super cooled set are added to the devolved sequences to produce a modified output stream (entity) that resembles, but is not the same as, the original input stream (entity).

The analogies discussed herein relating to the similarities between the models discussed herein and the biological processes are by no means exhaustive as additional analogies can be made between the model and different biological processes.

The input stream shown as a string of zeros and ones in FIG. 4A is also a representation of a wave form. It is well known that where there is (are) a wave(s) there is energy. Energy systems, by inference, may therefore be modeled by a stream of zeros and ones. The concepts of supercooling, and superheating may therefore be extended to energy systems as well as any other system that may be represented by a stream of ordered zeros and ones.

One skilled in the art will readily recognize that the model discussed explaining the cell growth from the outer periphery towards the middle (the nucleus) is analogous to what takes place in energy systems such as tornados and hurricanes. Since energy is devolving from the outer periphery towards the middle, a torque is set up leading to rotation of the tornado/hurricane. Further, in a super cooled set, since the inversion pucks are not exactly centered, as the energy devolves a lateral force develops in addition to the rotational force, leading to movement of the tornado/hurricane in addition to their rotational component. There are other important derivations to be had from the super cooling/super heating process described herein, too numerous to be gone into in this patent application.

The work presented in this patent application therefore provides a template for modeling systems which may be represented by an ordered series of zeros and ones in which winding (compression) and unwinding (decompression) takes place through the creation of entities which have a precedential relationship to each other; the entities having a precedential relationship to each other being created by the stream of zeros and ones and a copy (or modifications thereof) of the stream of zeros and ones rotated in relation to each other; the entities with precedential relationship having a pairing relationship between adjacently disposed elements; the summation of pairing counts of these paired entities representing the ordered series of zeros and ones in the summarized or wound state.

The work also serves as a template for the unwinding or re-expansion of the summarized entities by using the paired relationship between adjacently disposed entities with a precedential relationship to recreate the original ordered series of zeros and ones.

This template therefore forms the basis for modeling systems which in turn may be manipulated to draw inference as to how the system would behave under varying conditions.

From the above description, it is clear that the present invention is well adapted to carry out the objects and to attain the advantages mentioned herein, as well as those inherent in the invention. Although the foregoing invention has been described in some detail by way of illustration and example for purposes of clarity of understanding, it will be apparent to those skilled in the art that certain changes and modifications may be practiced without departing from the spirit and scope of the present invention, as described herein. Thus, the present invention is not intended to be limited to the embodiment shown but is to be accorded the widest scope consistent with the principles and features described herein.

What is claimed is:

1. A computer program stored on a storage device and including computer executable logic for modeling systems represented by an ordered input stream of zeros and ones, the computer executable logic adapted to cause a computer to summarize and store the ordered input stream into unordered summarized entities representing the ordered input stream (compression) and re-expand (decompression) the stored unordered summarized entities into the ordered input stream.

2. The computer program of claim 1, further comprising computer executable logic for making a copy of the input stream and rotating the input stream and the copy of the input stream relative to each other, the computer program further comprising computer executable logic for manipulating and encoding the rotated input stream and the copy of the input stream to form the unordered summarized entities having a precedential relationship to each other such that the summarized entities lead to a reduction in size of the input stream in a substantially un-ordered condition.

3. The computer program of claim 2 in which the computer executable logic for manipulation consists of computer executable logic for inserting zeros, ones and/or zeros and ones in a predetermined fashion, reversing one of the streams in relation to the other, adding zeros, ones and/or zeros and ones at the end of the streams so as to make the streams an even or odd multiple of the number 4 so that the entities that result from the encoding are suitably formed.

4. The computer program of claim 2 in which the summarizations are carried out by type of precedential entities and pairings of consecutively disposed precedential entities by type representing the input stream in an un-ordered form.

5. The computer program of claim 4 in which pairing of consecutively disposed precedential entities is represented in at least one of an alphabetic form and a digital form to include at least one digital representation in which the digital form consists of zeros and ones representing a rippling component and a data component, the data component being formed to reflect the precedential relationship between two consecutively disposed precedential entities.

6. The computer program of claim 5 in which the digital representation of the rippling part and data part are treated separately; sub entities of the data part being swapped; the rippling part and the data part being rotated taken as a whole and sub-entities of the data part being re-swapped to yield double helix pairs, the data part reflecting the pairings between consecutively disposed precedential entities and the rippling part being indicative of odd/even pairing cycle.

7. The computer program of claim 1 in which re-expansion of the summarized entities uses the precedential relationships and pairing counts between consecutively disposed precedential entities in the summarizations to re-order the un-ordered summarizations in an expanded form and decode the precedential entities to reproduce at least one representation of the ordered input stream from which the original ordered stream of zeros and ones is reconstructed.

8. The computer program of claim 7 in which the unordered summarizations are expanded and re-ordered by considering the first known precedential entity as the reference entity in the sequence and deducing one of two possible alternatives as the precedential entity following it by the use of tails appended to the summarizations and the use of standard devolution tables; tagging the following precedential entity as the current precedential entity and repeating the process until all the unordered summarized entities are re-expanded in an ordered state.

9. The computer program of claim 8 in which tails include a base component and two alternative icicle components, the combination of which yielding two appended sets for evaluation of the alternatives.

10. The computer program of claim 8 in which standard devolution tables are defined for each possible reference entity; each table being composed of a standard tail of odd/even pairing counts and a non-standard tail of odd/even pairing counts and the steps to be gone through in computing pairing differences between standard tail pairing counts and non-standard tail pairing counts and to decide which alternative to pick as the one following the reference precedential entity based on the pairing count differences.

11. The computer program of claim 9 in which the base tail consists of precedential entities appended to the remaining un-reordered set of summarized precedential entities such that the first precedential entity (tagged the reference) and the last precedential entity in the appended set are the same.

12. The computer program of claim 11 in which the icicle tails consist of icicle 1 and icicle 2 appended to the base line set.

13. The computer program of claim 12 in which icicle 1 consists of an elemental loop, such loop comprising the smallest set of valid precedential entities containing one of the alternatives being evaluated such that the last precedential entity of the elemental loop is the same as the reference precedential entity of the entire appended set and yielding the standard tail set.

14. The computer program of claim 12 in which icicle 2 consists of an elemental loop, such loop comprising the smallest set of valid precedential entities containing the other alternative being evaluated such that the last precedential entity of the elemental loop is different to the reference precedential entity of the entire appended set and yielding the non-standard tail set.

15. The computer program of claim 8 in which definitions provided in the standard devolution table consist of odd/even pairing counts of consecutively disposed precedential entities with the standard tail representing the correct loop pairing count when the reference precedential entity is removed; the odd/even pairing counts of consecutively disposed precedential entities with the non-standard tail representing the incorrect loop pairing count when the reference entity is removed and the counts to be adjusted by pairing types such that the non-standard tail pairing counts correctly reflects the loop pairing counts; steps to compute difference between standard and non-standard pairing counts thus derived and the criteria for selecting the correct alternative as the next precedential entity following the reference entity.

16. A method comprising the step of using the computer program of claim 1 to model and predict the behavior of any system that lends itself to representation as an ordered series of zeros and ones.

17. The method of claim 16 wherein the system is a biological system.

18. The method of claim 16 wherein the system is an energy system.
